(19) United States
(12) Patent Application Publication
(10) Pub. No.: US 2025/0185508 A1
(43) Pub. Date: Jun. 5, 2025

(54) ORGANIC ELECTROLUMINESCENT DEVICES AND POLYMERS, FORMULATIONS, MIXTURES, AND ORGANIC COMPOUNDS FOR PREPARING SAME

(71) Applicant: Zhejiang Brilliant Optoelectronic Technology Co.,Ltd., Taizhou (CN)

(72) Inventors: Jiahui TAN, Taizhou (CN); Dizheng LIU, Taizhou (CN); Junyou PAN, Taizhou (CN)

(73) Assignee: Zhejiang Brilliant Optoelectronic Technology Co.,Ltd., Taizhou (CN)

(21) Appl. No.: 19/051,167

(22) Filed: Feb. 12, 2025

Related U.S. Application Data
(63) Continuation of application No. PCT/CN2023/112652, filed on Aug. 11, 2023.

(30) Foreign Application Priority Data
Aug. 12, 2022 (CN) 202210968302.2

(51) Int. Cl. H10K 85/60; H10K 50/15; H10K 50/16

(52) U.S. Cl. CPC H10K 85/6572; H10K 50/15; H10K 50/16; H10K 85/636

(57) ABSTRACT

Disclosed are organic electroluminescent devices including a substrate, a first electrode, a second electrode, and at least one functional layer, the at least one functional layer includes a compound of formula (I). Also provided are mixtures containing the compound of formula (I), and at least one other organic functional material. Further provided are organic compounds containing a structure of formula (I). The compound contained in the organic electroluminescent device of the present disclosure has relatively high thermal stability, so that the luminous efficiency and the service life of the device can be improved.

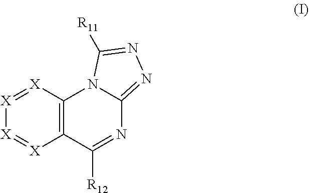

### CROSS-REFERENCE TO RELATED APPLICATIONS

The present application is a continuation of International Application No. PCT/CN2023/112652, filed on Aug. 11, 2023, which claims priority to Chinese Patent Application No. 202210968302.2, filed on Aug. 12, 2022. All of the aforementioned applications are incorporated herein by reference in their entireties.

### TECHNICAL FIELD

The present disclosure relates to the field of organic electronic material and device technology, and in particular to an organic electroluminescent device, as well as a mixture, and an organic compound for the preparation thereof.

### BACKGROUND

Due to the low manufacturing cost, the excellent optical and electrical properties, while the material properties can be regulated by organic synthetic methods, the organic light-emitting diodes show great potential for optoelectronic device applications, such as flat-panel displays and lighting.

The organic electroluminescent phenomenon refers to a phenomenon of converting electrical energy to photonic energy with organic substances. An organic electroluminescent element utilizing the organic electroluminescent phenomenon usually has a structure comprising an anode, a cathode, and at least one organic layer therebetween. In order to improve the efficiency and lifetime of the organic electroluminescent element, the organic layer has a multi-layer structure, and each layer comprises different organic substances. Specifically, the organic layer can be a hole-injection layer, a hole-transport layer, a light-emitting layer, a hole-blocking layer, an electron-transport layer, an electron-injection layer, etc. When a voltage is applied between the two electrodes of such an organic electroluminescent element, holes are injected into the organic layer from the anode, and electrons are injected into the organic layer from the cathode; and an exciton is formed when an injected hole and an injected electron recombine in the emission layer. The exciton emits light when it transitions back to the ground state. The organic electroluminescent element has characteristics of self-emission, high luminance, high efficiency, low driving voltage, wide viewing angle, high contrast, high responsivity, etc.

Although a large number of electron-transport materials have been reported in the prior art, for example in CN103579528A, CN107210374A, CN107750404A, CN101009364A, CN104109532A, CN105399749A, CN110551154A, CN113402498A, CN113264871A. CN104529870A, and WO2018230969A1, but the device efficiency or lifetime is still insufficient. Therefore, it is necessary to further develop the novel electron-transport materials to decrease the device voltage, improve the device efficiency, and prolong the device lifetime.

### SUMMARY

In one aspect, the present disclosure provides an organic electroluminescent device comprising a substrate, a first electrode, a second electrode, and at least one functional layer, the at least one functional layer comprises a compound of formula (I):

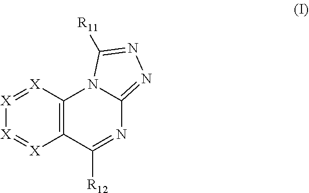

Where each of R₁₁ and R₁₂ is a substituent and independently selected from −D, a substituted/unsubstituted C₁-C₂₀ linear alkyl group, a substituted/unsubstituted C₁-C₂₀ linear alkoxy group, a substituted/unsubstituted C₁-C₂₀ linear thioalkoxy group, substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a substituted/unsubstituted C₁-C₂₀ ketone group, a substituted/unsubstituted C₂-C₂₀ alkoxycarbonyl group, a substituted/unsubstituted C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted C₅-C₆₀ aromatic or heteroaromatic group, a substituted/unsubstituted C₅-C₆₀ aryloxy or heteroaryloxy group, or any combination thereof, where one or more R₁₁-R₁₂ form a monocyclic or polycyclic aliphatic or aromatic ring system with each other and/or with the rings bonded thereto;
X at each occurrence is independently N or CR₁;
R₁ at each occurrence is independently selected from −H, −D, a halogen group, a substituted/unsubstituted C₁-C₂₀ linear alkyl group, a substituted/unsubstituted C₃-C₂₀ cycloalkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a C₁-C₂₀ ketone group, a C₂-C₂₀ alkoxycarbonyl group, a C₇-C₂₀ aryloxycarbonyl group, a carbamoyl group, a haloformyl group, a formyl group, an isocyano group, an isocyanate group, a thiocyanate group, an isothiocyanate group, a hydroxyl group, a cross-linkable group, a substituted/unsubstituted C₆-C₆₀ aryl group, a substituted/unsubstituted C₅-C₆₀ heteroaryl group, a substituted/unsubstituted C₅-C₆₀ aryloxy group, a substituted/unsubstituted C₅-C₆₀ heteroaryloxy group, a substituted/unsubstituted C₆-C₃₀ arylamino group, a substituted/unsubstituted C₅-C₃₀ heteroarylamino group, or any combination thereof.

In addition or alternatively, R₁, R₁₁, and R₁₂ of the organic electroluminescent device as described herein are each independently selected from a substituted/unsubstituted C₆-C₆₀ aryl group or a substituted/unsubstituted C₅-C₆₀ heteroaryl group.

In another aspect, the present disclosure also provides a polymer comprising at least one repeating unit, the at least one repeating unit comprises at least one structure of formula (I). Further, the polymer is used in the organic electroluminescent device.

In yet another aspect, the present disclosure further provides a mixture comprising a compound of formula (I) or a polymer as described herein, and at least one other organic functional material, the at least one other organic functional material is selected from one or more of the following: a hole-injection material, a hole-transport material, an electron-transport material, an electron-injection material, an electron-blocking material, a hole-blocking material, a light-emitting material, a host material, an organic dye. Further, the mixture is used in the organic electroluminescent device.

In yet another aspect, the present disclosure further provides a formulation comprising at least one compound of formula (I) or polymer or mixture as described herein, and at least one organic solvent. Further, the formulation is used in the organic electroluminescent device.

In yet another aspect, the present disclosure further provides an organic compound comprising a structure of formula (I), where R₁₁ and R₁₂ are each independently selected from a substituted/unsubstituted C₆-C₆₀ aryl group or a substituted/unsubstituted C₅-C₆₀ heteroaryl group, and at least one of R₁₁ or R₁₂ comprises an electron-withdrawing group. Further, the organic compound is used in the organic electroluminescent device.

Beneficial effect: the compound contained in the organic electroluminescent device contains large conjugated electron-deficient core structure combined with electron-withdrawing groups, which provides the molecules with increased electron affinity and more appropriate molecular dipole moments, thus improving their electron injection and migration ability, while making them have a high glass transition temperature and good thermal stability, so that the functional layer materials contained in the organic electroluminescent device exhibit good electron-transport properties, and the device has a low driving voltage, improved luminescence efficiency and lifetime. In addition, the compound contained in the organic electroluminescent device has a simple preparation process, readily available raw materials, and is suitable for mass production.

### DETAILED DESCRIPTION OF THE EMBODIMENTS

The present disclosure provides an organic electroluminescent device, as well as a mixture, and an organic compound for the preparation thereof, aiming to solve the problems of low efficiency and short lifetime in the existing organic electronic devices. In order to make the objects, the technical solutions and the effects of the present disclosure more clear and definite, the present disclosure is further described in detail below. It should be understood that the embodiments described herein are only intended to explain the present disclosure and are not intended to limit the present disclosure.

As used herein, the terms “formulation”, “printing ink”, and “ink” have the same meaning, and they are interchangeable with each other.

As used herein, the terms “aromatic group”, “aromatics”, and “aromatic ring system” have the same meaning, and they are interchangeable with each other.

As used herein, the terms “heteroaromatic group”, “heteroaromatics”, and “heteroaromatic ring system” have the same meaning, and they are interchangeable with each other.

As used herein, the term “substituted” means that a hydrogen atom of the compound is substituted.

As used herein, “the number of ring atoms” means that the number of atoms constituting the ring itself of a structural compound (e.g., a monocyclic compound, a fused ring compound, a cross-linked compound, a carbocyclic compound, and a heterocyclic compound) by covalent bonding. When the ring is substituted with a substituent, the atoms contained in the substituent are not included in the ring atoms. The above rule applies for all cases without further specific description. For example, the number of ring atoms of a benzene ring is 6, the number of ring atoms of a naphthalene ring is 10, and the number of ring atoms of a thienyl group is 5.

As used herein, the term “aromatic ring system” or “aromatic group” refers to a hydrocarbon group containing an aromatic ring, including monocyclic groups and polycyclic ring systems. The term “heteroaromatic ring system” or “heteroaromatic group” refers to a hydrocarbon group (containing heteroatoms) consisting of at least one heteroaromatic ring, including monocyclic groups and polycyclic ring systems. The heteroatoms are preferably selected from Si, N, P, O, S and/or Ge, particularly preferably selected from Si, N, P, O and/or S. The polycyclic rings contain two or more rings, in which two carbon atoms are shared by the adjacent two rings, i.e., fused rings. Specifically, at least one of the rings in the polycyclic rings are aromatic or heteroaromatic. For the purposes of the present disclosure, the aromatic or heteroaromatic groups contain not only aromatic or heteroaromatic systems, but also have a plurality of aryl or heteroaryl groups linked by short non-aromatic units (<10% of non-H atoms, preferably <5% of non-H atoms, such as C, N or O atoms). Therefore, a system such as 9,9′-spirobifluorene, 9,9-diarylfluorene, triarylamine, diaryl ether, and the like is also considered to be aromatic groups for the purposes of this invention.

Specifically, examples of aromatic groups include, but not limited to, benzene, naphthalene, anthracene, phenanthrene, perylene, tetracene, pyrene, benzopyrene, triphenylene, acenaphthylene, fluorene, and derivatives thereof.

Specifically, examples of heteroaromatic groups include, but not limited to, furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, o-diazonaphthalene, quinoxaline, phenanthridine, perimidine, quinazoline, quinazolinone, and derivatives thereof.

As used herein, the term “alkyl group” may refer to a linear, branched and/or cyclic alkyl group. The carbon number of the alkyl group may be 1 to 20, 1 to 10, or 1 to 6. Non-limiting examples of alkyl groups include, but not limited to, a methyl group, an ethyl group, a n-propyl group, an iso-propyl group, a n-butyl group, a sec-butyl group, a tert-butyl group, an iso-butyl group, a 2-ethylbutyl group, a 3,3-dimethylbutyl group, a n-pentyl group, an iso-pentyl group, a neo-pentyl group, a tert-pentyl group, a cyclopentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, a cyclohexyl group, a 4-methylcyclohexyl group, a 4-tert-butylcyclohexyl group, a n-heptyl group, a 1-methylheptyl group, a 2,2-dimethylheptyl group, a 2-ethylheptyl group, a 2-butylheptyl group, a n-octyl group, a tert-octyl group, a 2-ethyloctyl group, a 2-butyloctyl group, a 2-hexyloctyl group, a 3,7-dimethyloctyl group, a cyclooctyl group, a n-nonyl group, a n-decyl group, an adamantyl group, a 2-ethyldecyl group, a 2-butyldecyl group, a 2-hexyldecyl group, a 2-octyldecyl group, a n-undecyl group, a n-dodecyl group, a 2-ethyldodecyl group, a 2-butyldodecyl group, a 2-hexyldodecyl group, a 2-octyldodecyl group, a n-tridecyl group, a n-tetradecyl group, a n-pentadecyl group, a n-hexadecyl group, a 2-ethylhexadecyl group, a 2-butylhexadecyl group, a n-heptadecyl group, a n-octadecyl group, a n-nonadecyl group, a n-eicosyl group, etc.

As used herein, the terms “electron-withdrawing group” and “electron-deficient group” have the same meaning, and they are interchangeable with each other.

Specifically, the terms “electron-withdrawing group” refers to a group having a reduced electron cloud density on a benzene ring after the group is substituted with hydrogen on the benzene ring. Such groups may include, but are not limited to, a triazinyl group, a pyrimidinyl group, a benzopyrimidinyl group, a benzopyridinyl group, a diazanaphthyl group, a diazaphenanthryl group, a pyrazinyl group, a quinolinyl group, an isoquinolinyl group, a quinazolinyl group, a quinoxalinyl group, a pyridazinyl group, and the foregoing groups substituted with alkyl or aryl groups.

In embodiments of the present disclosure, the energy level structure of the organic materials, singlet energy level (E_{S1}), triplet energy level (E_{T1}), highest occupied molecular orbital (HOMO), and lowest unoccupied molecular orbital (LUMO) play key roles. The determination of these energy levels is introduced as follows.

HOMO and LUMO energy levels can be measured by optoelectronic effect, for example, by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT), are becoming effective methods for calculating the molecular orbital energy levels.

The singlet energy level E_{S1} of the organic materials can be determined by the emission spectrum. The triplet energy level E_{T1} of the organic materials can be measured by low-temperature time-resolved spectroscopy. E_{S1} and E_{T1} can also be calculated by quantum simulation (for example, by time-dependent DFT), for instance with the commercial software Gaussian 09W (Gaussian Inc.), the specific simulation method can be found in WO2011141110 or as described in the following embodiments. ΔE_{ST} is defined as (E_{S1}−E_{T1}).

It should be noted that the absolute values of HOMO, LUMO, E_{S1} and E_{T1} may depend on the measurement method or calculation method used. Even for the same method, different ways of evaluation, for example, using either the onset or peak value of a CV curve as reference, may result in different HOMO/LUMO values. Therefore, reasonable and meaningful comparison should be carried out by employing the same measurement and evaluation methods. In the embodiments of the present disclosure, the values of HOMO, LUMO, E_{S1} and E_{T1} are based on the time-dependent DFT simulation, which however should not exclude the applications of other measurement or calculation methods.

In the invention, (HOMO-1) is defined as the energy level of the second highest occupied molecular orbital, (HOMO-2) is defined as the energy level of the third highest occupied molecular orbital, and so on. (LUMO+1) is defined as the energy level of the second lowest unoccupied molecular orbital, (LUMO+2) is defined as the energy level of the third lowest occupied molecular orbital, and so on.

In one aspect, the present disclosure provides an organic electroluminescent device comprising a substrate, a first electrode, a second electrode, and at least one functional layer, the at least one functional layer comprises a compound of formula (I):

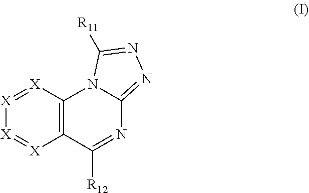

Where each of R₁₁ and R₁₂ is a substituent and independently selected from −D, a substituted/unsubstituted C₁-C₂₀ linear alkyl group, a substituted/unsubstituted C₁-C₂₀ linear alkoxy group, a substituted/unsubstituted C₁-C₂₀ linear thioalkoxy group, substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a substituted/unsubstituted C₁-C₂₀ ketone group, a substituted/unsubstituted C₂-C₂₀ alkoxycarbonyl group, a substituted/unsubstituted C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, −CF₃, —Cl, —Br, —F, a cross-linkable group, a substituted/unsubstituted C₅-C₆₀ aromatic or heteroaromatic group, a substituted/unsubstituted C₅-C₆₀ aryloxy or heteroaryloxy group, or any combination thereof, where one or more R₁₁-R₁₂ may form a monocyclic or polycyclic aliphatic or aromatic ring system with each other and/or with the rings bonded thereto.

X at each occurrence is independently N or CR₁; R₁ at each occurrence is independently selected from −H, −D, a halogen group, a substituted/unsubstituted C₁-C₂₀ linear alkyl group, a substituted/unsubstituted C₃-C₂₀ cycloalkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a C₁-C₂₀ ketone group, a C₂-C₂₀ alkoxycarbonyl group, a C₇-C₂₀ aryloxycarbonyl group, a carbamoyl group, a haloformyl group, a formyl group, an isocyano group, an isocyanate group, a thiocyanate group, an isothiocyanate group, a hydroxyl group, a cross-linkable group, a substituted/unsubstituted C₆-C₆₀ aryl group, a substituted/unsubstituted C₅-C₆₀ heteroaryl group, a substituted/unsubstituted C₅-C₆₀ aryloxy group, a substituted/unsubstituted C₅-C₆₀ heteroaryloxy group, a substituted/unsubstituted C₅-C₃₀ substituted/unsubstituted C₆-C₃₀ arylamino group, as heteroarylamino group, or any combination thereof.

In some embodiments, each of R₁₁ and R₁₂ is a substituent and independently selected from −D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a substituted C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted C₅-C₆₀ aromatic or heteroaromatic group, a substituted/unsubstituted C₅-C₆₀ aryloxy or heteroaryloxy group, or any combination thereof, where one or more R₁₁-R₁₂ may form a monocyclic or polycyclic aliphatic or aromatic ring system with each other and/or with the rings bonded thereto.

In some embodiments, the organic electroluminescent device is selected from an organic light-emitting diode (OLED), an organic light emitting electrochemical cell (OLEEC), or an organic light emitting field effect transistor (OLET). In some embodiments, the organic electroluminescent device is an organic light-emitting diode (OLED).

In the organic electroluminescent device as described herein, the at least one functional layer includes, but not limited to: a hole-injection layer (HIL), a hole-transport layer (HTL), an electron-blocking layer (EBL), an exciton-blocking layer, a light-emitting layer (EML), a charge generation layer (CGL), an electron-injection layer (EIL), an electron-transport layer (ETL), and a hole-blocking layer (HBL), and a capping layer (CPL). Materials suitable for use in these functional layers are described in detail in WO2010135519A1, US20090134784A1 and WO2011110277A1. The entire contents of these three documents are hereby incorporated herein for reference.

Preferably, the at least one functional layer is selected from an electron-transport layer, a hole-blocking layer, a light-emitting layer, or a capping layer; in some embodiments, the at least one functional layer is a hole-blocking layer; in some embodiments, the at least one functional layer is a light-emitting layer; in some embodiments, the at least one functional layer is a capping layer. Where the CPL material generally requires a high refractive index (n), such as n≥1.95@460 nm, n≥1.90@520 nm, n≥1.85@620 nm. Examples of the CPL materials include:

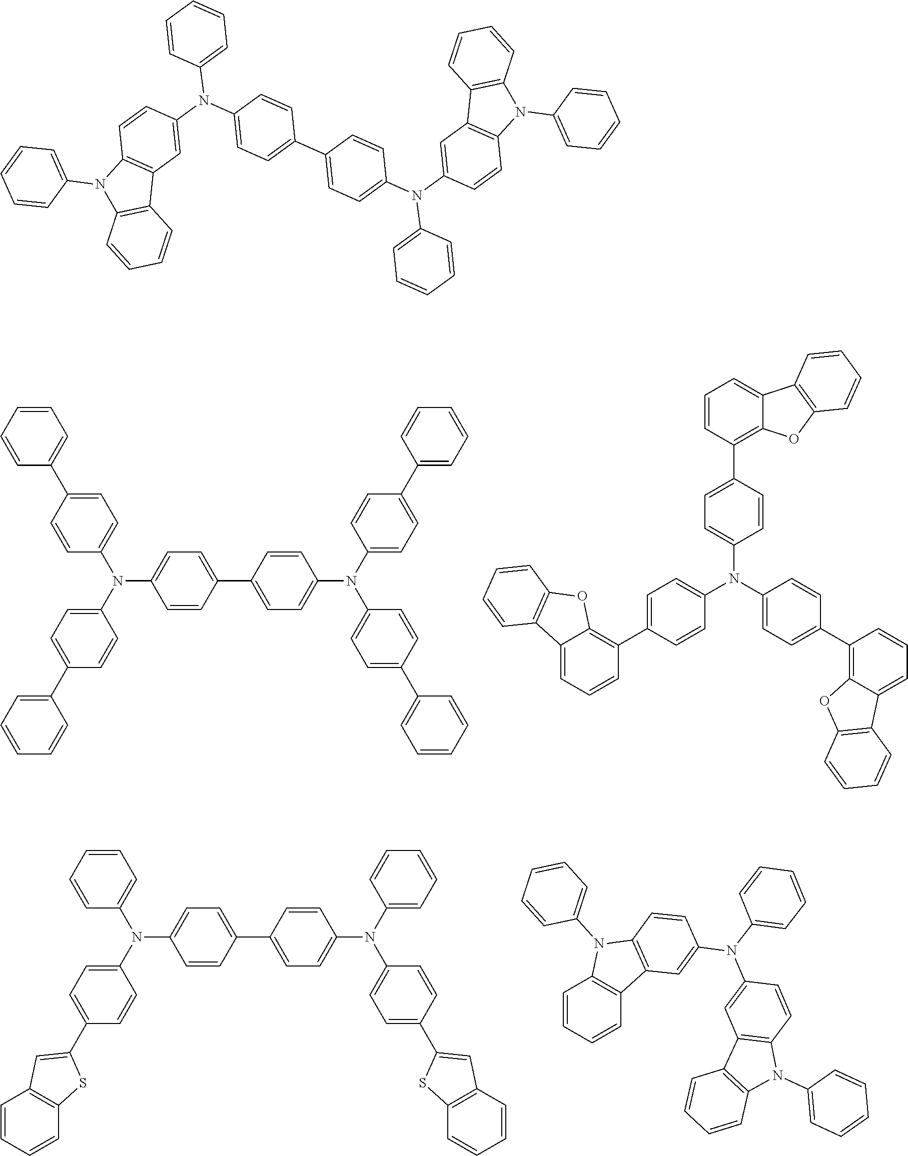 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(N(c2ccc(-c3ccc(N(c4ccccc4)c4ccc(-c5cc6ccccc6s5)cc4)cc3)cc2)c2ccc(-c3cc4ccccc4s3)cc2)cc1 ; c1ccc(N(c2ccc3c(c2)c2ccccc2n3-c2ccccc2)c2ccc3c(c2)c2ccccc2n3-c2ccccc2)cc1]

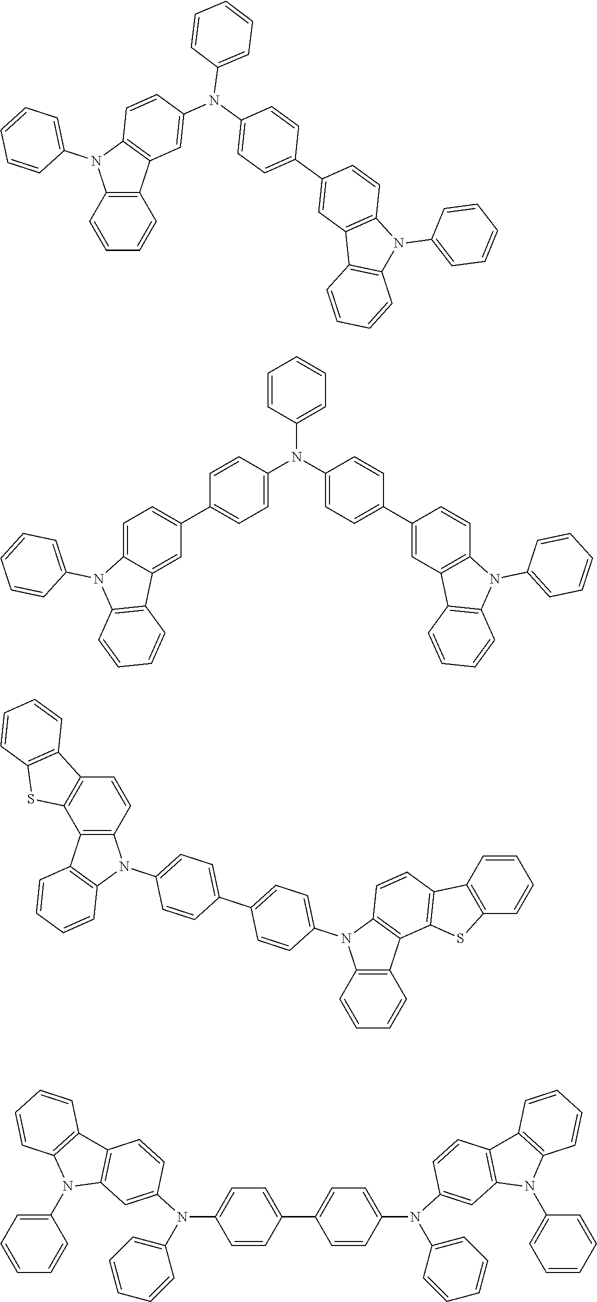 [SMILES: c1ccc(N(c2ccc(-c3ccc4c(c3)c3ccccc3n4-c3ccccc3)cc2)c2ccc3c(c2)c2ccccc2n3-c2ccccc2)cc1 ; c1ccc(N(c2ccc(-c3ccc4c(c3)c3ccccc3n4-c3ccccc3)cc2)c2ccc(-c3ccc4c(c3)c3ccccc3n4-c3ccccc3)cc2)cc1 ; c1ccc2c(c1)sc1c2ccc2c1c1ccccc1n2-c1ccc(-c2ccc(-n3c4ccccc4c4c5sc6ccccc6c5ccc43)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

More further examples of the CPL materials can be found in the following patents: KR20140128653A, KR20140137231A, KR20140142021A, KR20140142923A, KR20140143618A, KR20140145370A, KR20150004099A, KR20150012835A, U.S. Pat. No. 9,496,520B2, US2015069350A1, CN103828485B, CN104380842B, CN105576143A, TW201506128A, CN103996794A, CN103996795A, CN104744450A, CN104752619A, CN101944570A, US2016308162A1, U.S. Pat. No. 9,095,033B2, US2014034942A1, WO2017014357A1. The above patent documents are incorporated herein by reference in their entireties.

In some embodiments, the organic electroluminescent device is a tandem OLED device comprising at least two light-emitting units, where the two light-emitting units are linked by a linking layer (or a charge generation layer), and the charge generation layer comprises a compound as described herein. In some embodiments, the charge generation layer comprises a N-type charge generation layer and a P-type charge generation layer. In some embodiments, the N-type charge generation layer comprises a compound as described herein.

In the organic electroluminescent device as described herein, the first electrode and the second electrode can respectively correspond to an anode and a cathode. The anode may be a conductive metal, or a metal oxide, or a conductive polymer. The anode should be able to easily inject holes into a hole-injection layer (HIL), a hole-transport layer (HTL), or a light-emitting layer. In some embodiments, the absolute value of the difference between the work function of the anode and the HOMO energy level/valence band energy level of the emitter of the light-emitting layer or the p-type semiconductor materials of the hole-injection layer (HIL)/hole-transport layer (HTL)/electron-blocking layer (EBL)<0.5 eV, preferably <0.3 eV, and most preferably <0.2 eV. Examples of anode materials may include, but not limited to: Al, Cu, Au, Ag, Mg, Fe, Co, Ni, Mn, Pd, Pt, indium tin oxide (ITO), aluminum-doped zinc oxide (AZO), etc. Other suitable anode materials are known and can be readily selected for use by the general technicians in this field. The anode materials can be deposited using any suitable technique, such as a suitable physical vapor deposition method including RF magnetron sputtering, vacuum thermal evaporation, e-beam, etc. In some embodiments, the anode is patterned. Patterned conductive ITO substrates are commercially available and can be used to produce the devices as described herein.

The cathode may be a conductive metal or a metal oxide. The cathode should be able to easily inject electrons into the electron-injection layer (EIL), the electron-transport layer (ETL), or the directly into the light-emitting layer. In some embodiments, the absolute value of the difference between the work function of the cathode and the LUMO energy level/conduction band energy level of the emitter of the light-emitting layer, or the n-type semiconductor materials of the electron-injection layer (EIL)/electron-transport layer (ETL)/hole-blocking layer (HBL) <0.5 eV, preferably <0.3 eV, and most preferably <0.2 eV. In principle, all materials those can be used as cathodes for OLEDs may be applied as cathode materials for the devices as described herein. Examples of cathode materials include, but not limited to: Al, Au, Ag, Ca, Ba, Mg, LiF/Al, MgAg alloy, BaF₂/Al, Cu, Fe, Co, Ni, Mn, Pd, Pt, ITO, etc. The cathode materials can be deposited using any suitable technique, such as the suitable physical vapor deposition method including RF magnetron sputtering, vacuum thermal evaporation, e-beam, etc.

In some embodiments, R₁₁, R₁₂, and R₁ of the compounds are each independently selected from a substituted/unsubstituted C₆-C₆₀ aryl group or a substituted/unsubstituted C₅-C₆₀ heteroaryl group. In some embodiments, R₁₁, R₁₂, and R₁ are each independently selected from a substituted/unsubstituted C₆-C₅₀ aryl group or a substituted/unsubstituted C₅-C₅₀ heteroaryl group. In some embodiments, R₁₁, R₁₂, and R₁ are each independently selected from a substituted/unsubstituted C₆-C₄₀ aryl group or a substituted/unsubstituted C₅-C₄₀ heteroaryl group. In some embodiments, R₁₁, R₁₂, and R₁ are each independently selected from a substituted/unsubstituted C₆-C₃₀ aryl group or a substituted/unsubstituted C₅-C₃₀ heteroaryl group. In some embodiments, R₁₁, R₁₂, and R₁ are each independently selected from a substituted/unsubstituted C₆-C₂₀ aryl group or a substituted/unsubstituted C₅-C₂₀ heteroaryl group.

Further, at least one of R₁₁ or R₁₂ comprises an electron-withdrawing group.

In some embodiments, R₁₁ and R₁₂ of the compound respectively correspond to the groups represented by formula (I-1) and formula (I-2):

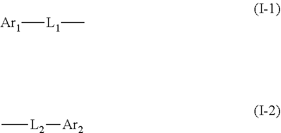

At this point, the compound comprises a structure of formula (II):

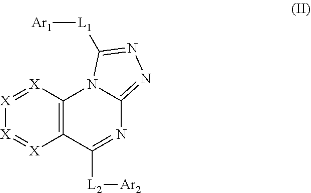

Where L₁ and L₂ are each independently selected from any one of a single bond, a substituted/unsubstituted C₆-C₃₀ arylene group, or a substituted/unsubstituted C₅-C₃₀ heteroarylene group; Ar₁ and Ar₂ are each independently selected from a substituted/unsubstituted C₆-C₃₀ aryl group or a substituted/unsubstituted C₅-C₃₀ heteroaryl group, and at least one of Ar₁ or Ar₂ is an electron-withdrawing group or is substituted with an electron-withdrawing group; each dotted line independently represents a bonding position of a group; X is identically defined as described herein.

In some embodiments, each X in formula (II) is independently CR₁, in which case the compound comprises a structure of formula (III):

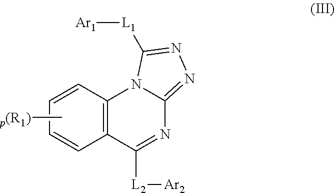

Where p is an integer from 0 to 4; L₁, L₂, Ar₁, Ar₂, and R₁ are identically defined as described herein.

Preferably, R₁, in multiple occurrences, is independently selected from one or a combination of at least two of the following: a halogen group, a nitro group, a trifluoromethyl group, a C₁-C₁₂ linear alkyl group, a C₃-C₁₂ branched alkyl group, a C₃-C₂₀ cycloalkyl group, a C₁-C₆ alkoxy group, a C₁-C₆ thioalkoxy group, a C₃-C₃₀ arylamino group, a C₃-C₃₀ heteroarylamino group, a C₆-C₃₀ monocyclic aryl group, a C₁₀-C₃₀ fused-ring aryl group, a C₃-C₃₀ monocyclic heteroaryl group, or a C₆-C₃₀ fused-ring heteroaryl group.

In some embodiments, Ar₁ and Ar₂ in formula (I-1), formula (I-2), formula (II), and formula (III) are the same or different, and at each occurrence are independently selected from one or combinations of more than one of the following structural groups:

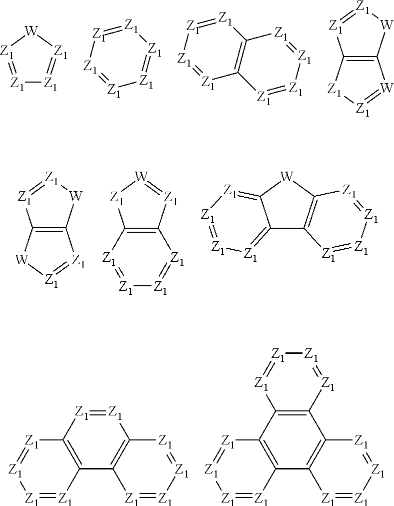

Where Z₁, in multiple occurrences, is independently CR₂ or N; W is selected from CR₃R₄, SiR₅R₆, NR₇, C(═O), S, or O; R₂-R₇ are identically defined as the above-mentioned R₁, and at least one of Ar₁ or Ar₂ is an electron-withdrawing group or is substituted with an electron-withdrawing group.

Preferably, Ar₁ and Ar₂ in formula (I-1), formula (I-2), formula (II), and formula (III) are the same or different, and at each occurrence are independently selected from the following groups:

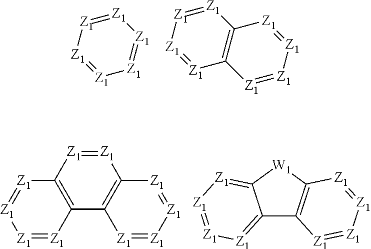

Where Z₁ and W are identically defined as described herein.

More preferably, Ar₁ and Ar₂ in formula (I-1), formula (I-2), formula (II), and formula (III) are the same or different, and at each occurrence are independently selected from the following groups:

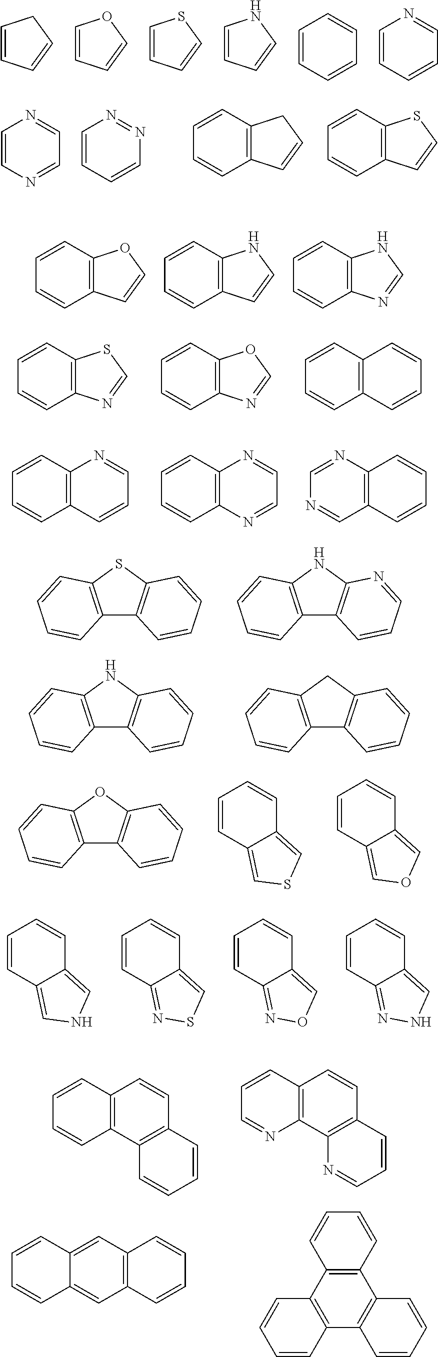

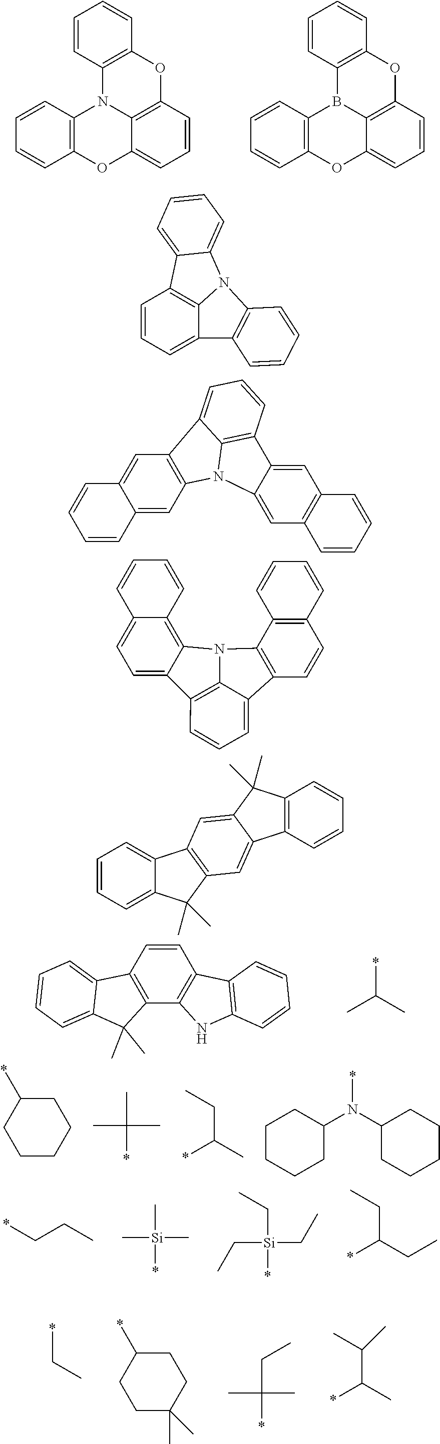

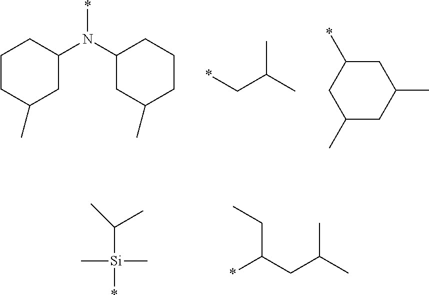

Where H atoms on the ring may be further substituted.

In some embodiments, Ar₁ and Ar₂ are each independently selected from a deuterated/undeuterated C₆-C₃₀ aryl group or a deuterated/undeuterated C₅-C₃₀ heteroaryl group, and at least one of Ar₁ or Ar₂ is an electron-withdrawing group or is substituted with an electron-withdrawing group; in some embodiments, Ar₁ and Ar₂ are each independently selected from a deuterated/undeuterated C₆-C₂₀ aryl group or a deuterated/undeuterated C₅-C₂₀ heteroaryl group, and at least one of Ar₁ or Ar₂ is an electron-withdrawing group or is substituted with an electron-withdrawing group; in some embodiments, Ar₁ and Ar₂ are each independently selected from a deuterated/undeuterated C₆-C₁₅ aryl group or a deuterated/undeuterated C₅-C₁₅ heteroaryl group, and at least one of Ar₁ or Ar₂ is an electron-withdrawing group or is substituted with an electron-withdrawing group; in some embodiments, Ar₁ and Ar₂ are each independently selected from a deuterated/undeuterated C₆-C₁₀ aryl group or a deuterated/undeuterated C₅-C₁₀ heteroaryl group, and at least one of Ar₁ or Ar₂ is an electron-withdrawing group or is substituted with an electron-withdrawing group.

For the purposes of the present disclosure, the electron-withdrawing group contained in R₁₁/R₁₂/Ar₁/Ar₂ at each occurrence is independently selected from a fluorine group, a cyano group, or one of the following groups:

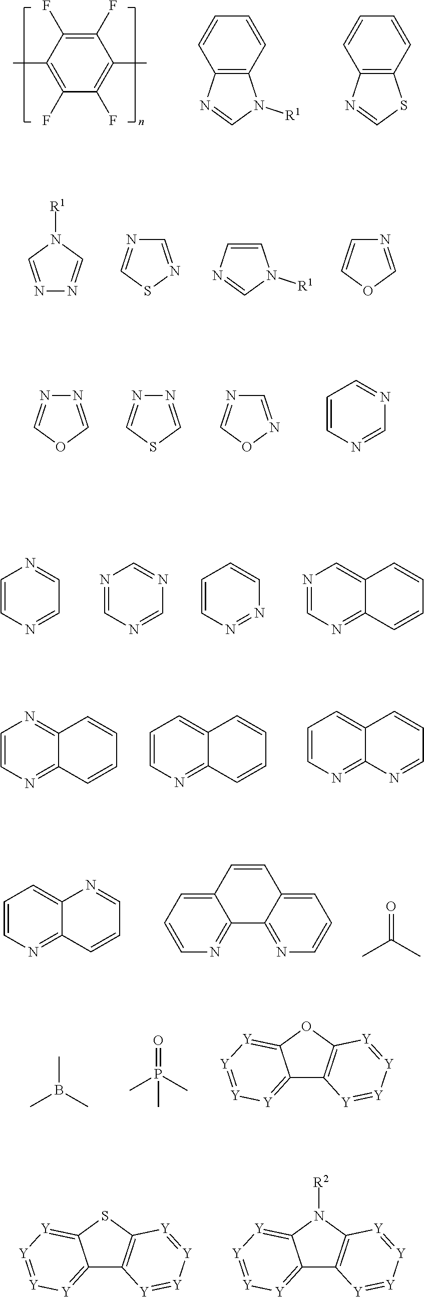

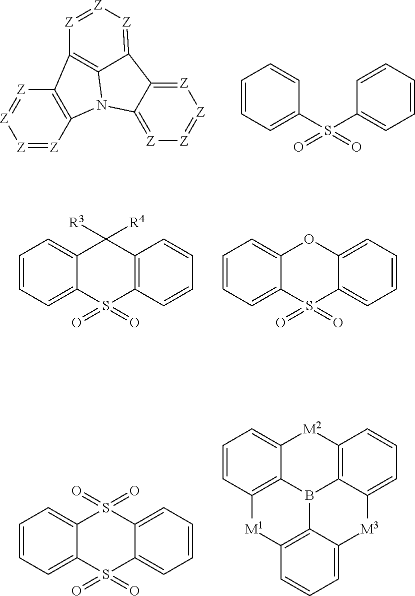

Where n is an integer from 1 to 3; Y at each occurrence is independently CR⁵ or N, and at least one of them is N; Z at each occurrence is independently CR⁶ or N; meanwhile any two adjacent positions may form a monocyclic or polycyclic aliphatic or aromatic ring system; M¹, M², and M³ are each independently selected from NR⁷, CR⁸R⁹, SiR⁹R¹⁰, O, PR¹¹, P(═O)R¹², S, S═O, SO₂, or null; R¹-R¹² are identically defined as the above-mentioned R₁. In some embodiments, the electron-withdrawing group is directly linked to the core structure.

In some embodiments, L₁ and L₂ in formula (I-1), formula (I-2), formula (II), and formula (III) are the same or different, and at each occurrence are independently selected from a single bond, one or combinations of more than one of the following groups:

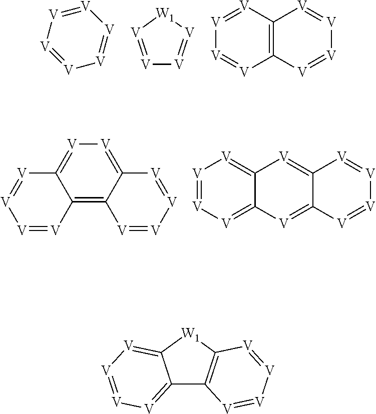

Where V at each occurrence is independently CR¹³ or N; W₁ at each occurrence is independently selected from NR¹⁴, CR¹⁵R¹⁶, SiR¹⁷R¹⁸, O, PR¹⁹, P(═O)R²⁰, S, S═O, or SO₂; each of R¹³ to R²⁰ is independently selected from −H, −D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 60 ring atoms, an aryloxy or heteroaryloxy group containing 5 to 60 ring atoms, or any combination thereof.

In some embodiments, each of L₁ and L₂ in formula (I-1), formula (I-2), formula (II), and formula (III) at each occurrence is independently selected from a single bond, one or combinations of more than one of the following groups:

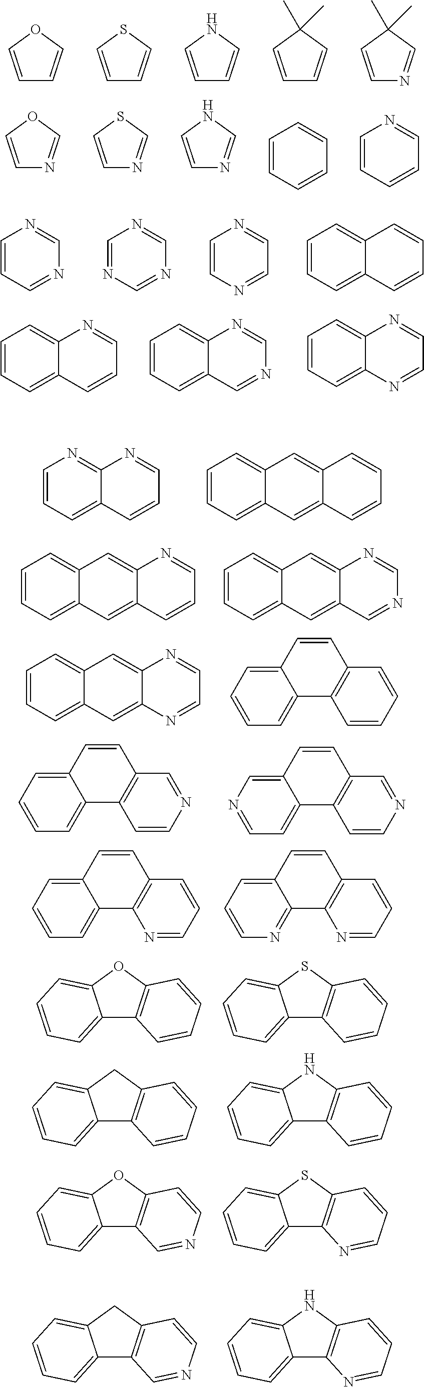

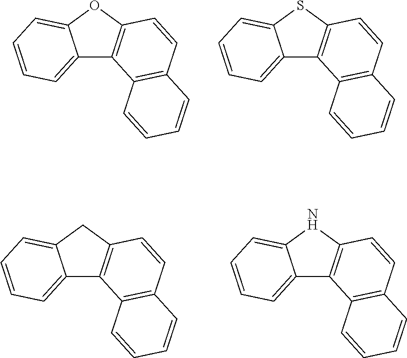

Where the hydrogen atoms on the group may optionally substituted with 0, 1, 2, or 3 substituents, and the substituents are independently selected from −D, a halogen group (F, Cl, Br, I), a cyano group, a C₁-C₄ alkyl group, a C₁-C₃ haloalkyl group, a phenyl group, a naphthyl group, a fluorene group, a spirofluorene group, or a C₃-C₁₀ cycloalkyl group.

In some embodiments, the compound of formula (I) is preferably selected from, but not limited to, the following structures:

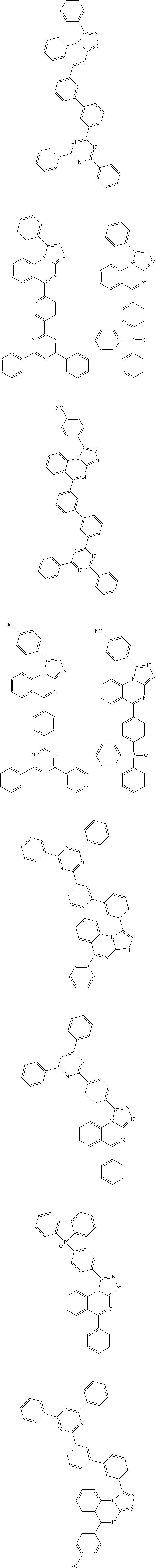

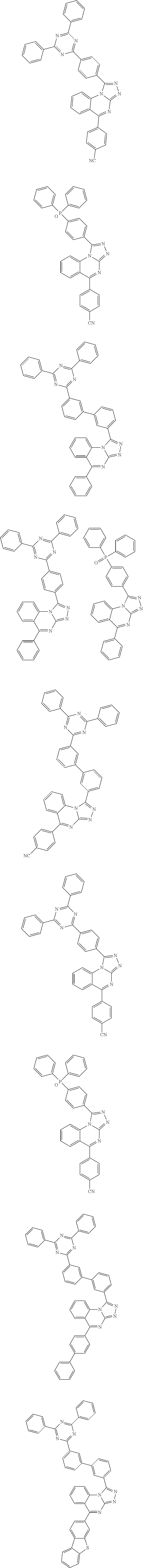

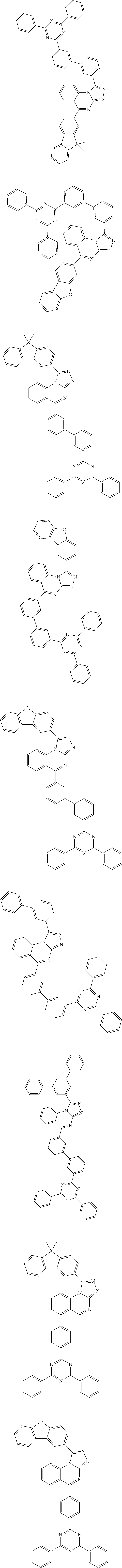

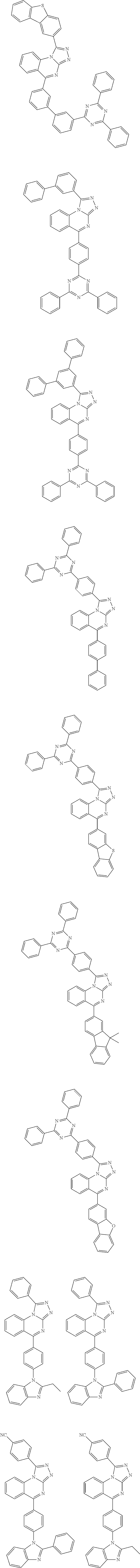

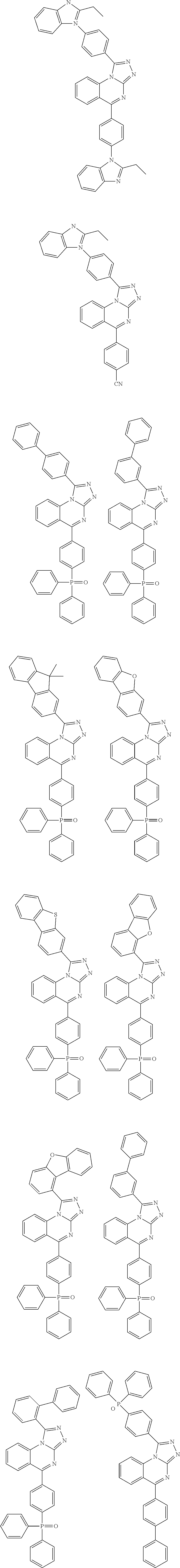

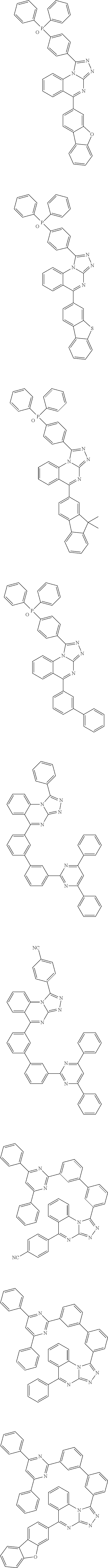

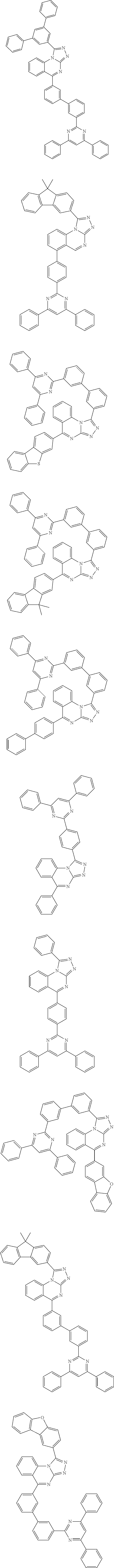

[chemical structure]

[chemical structure]

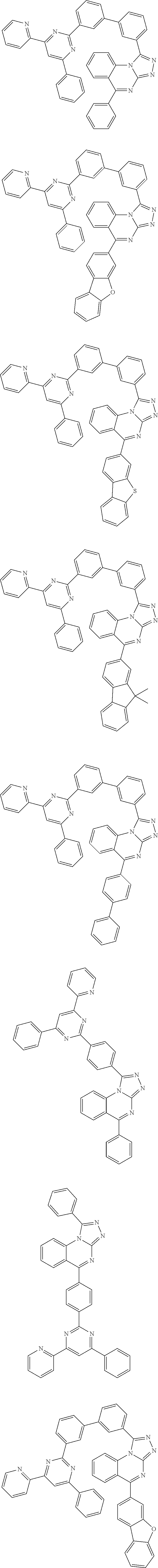

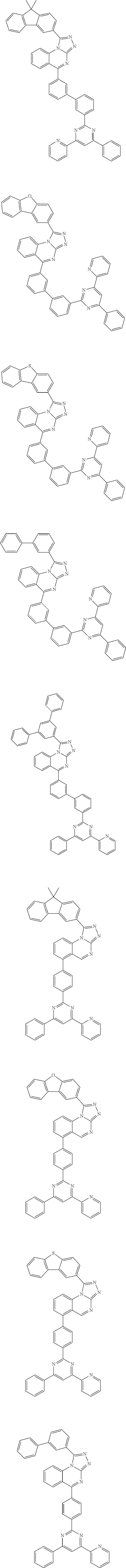

[chemical structure]

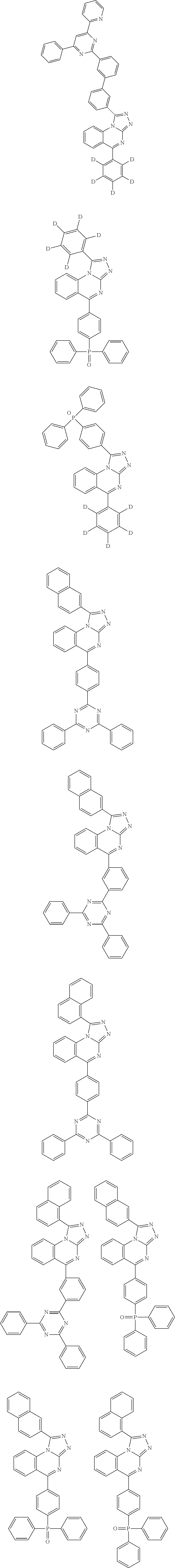

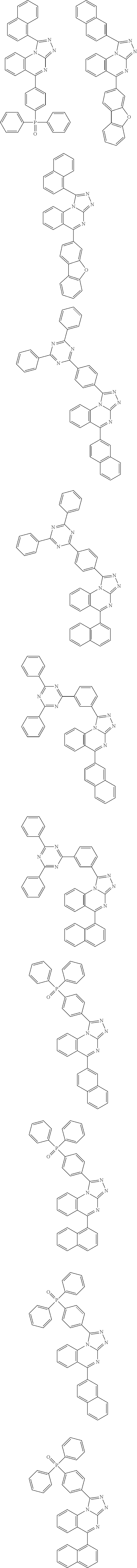

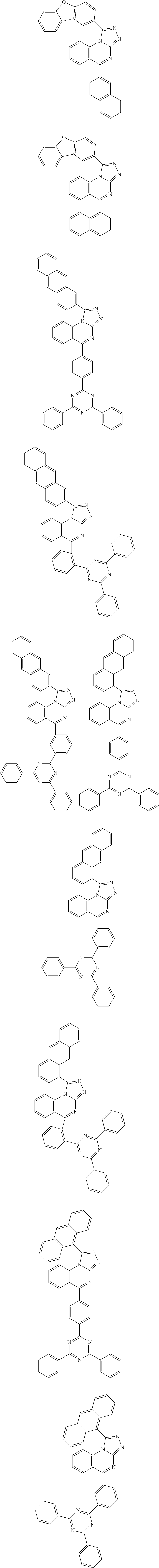

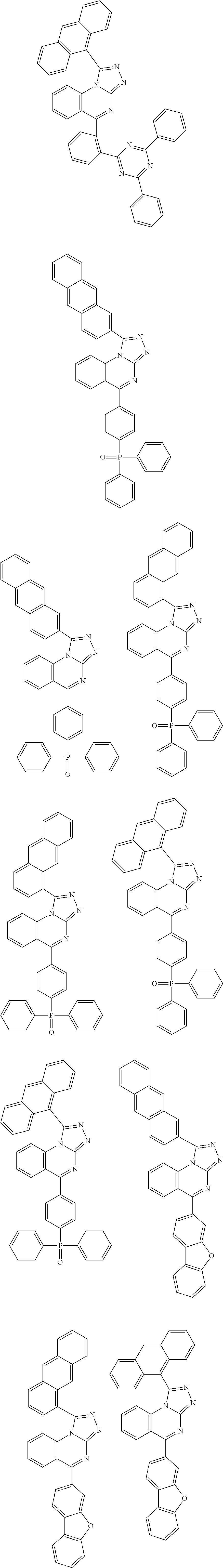

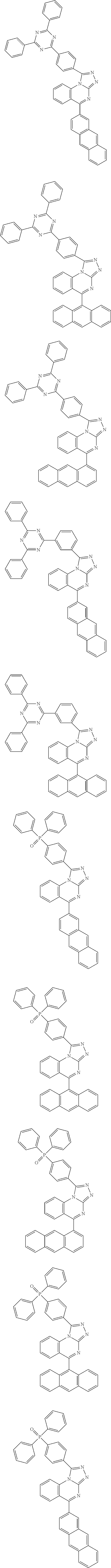

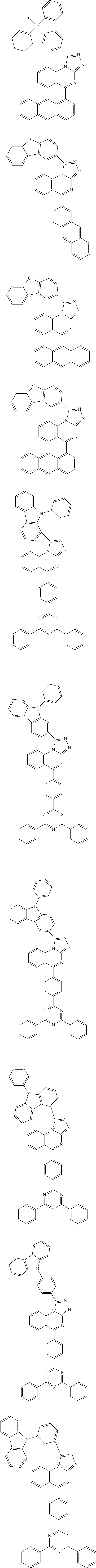

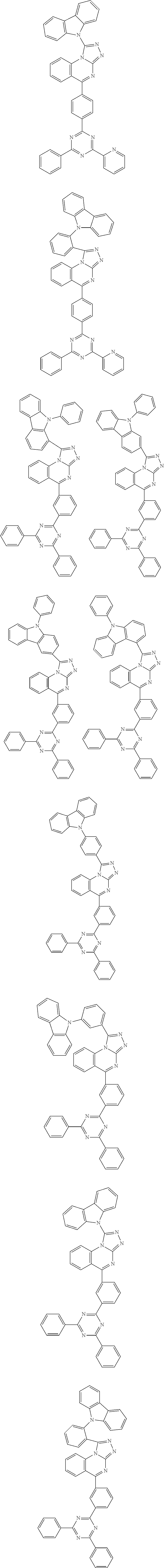

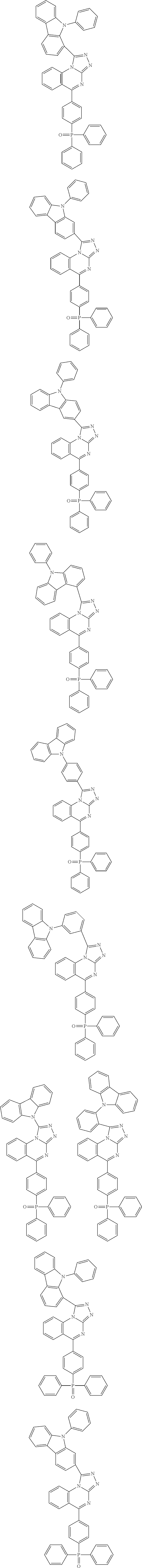

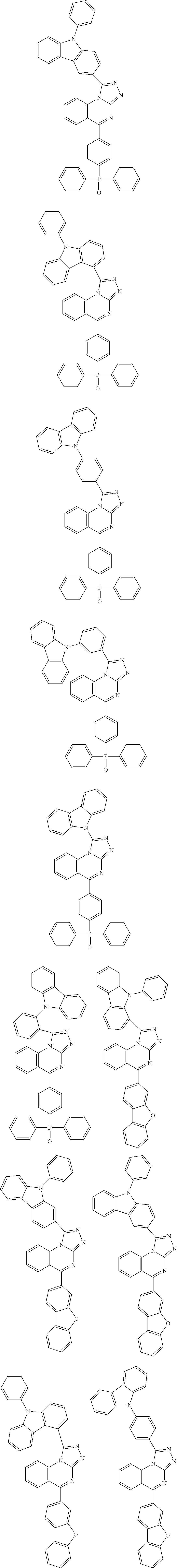

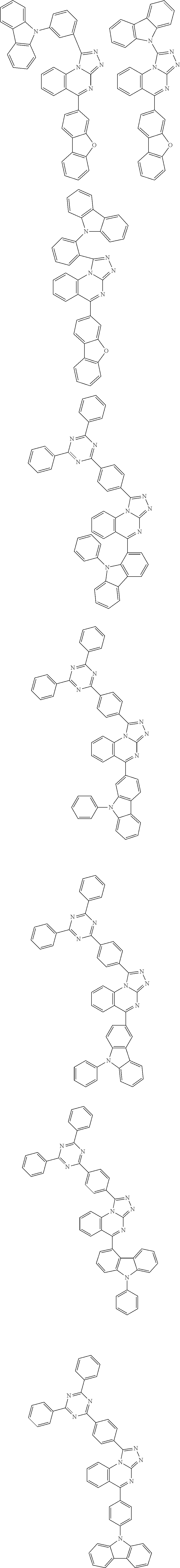

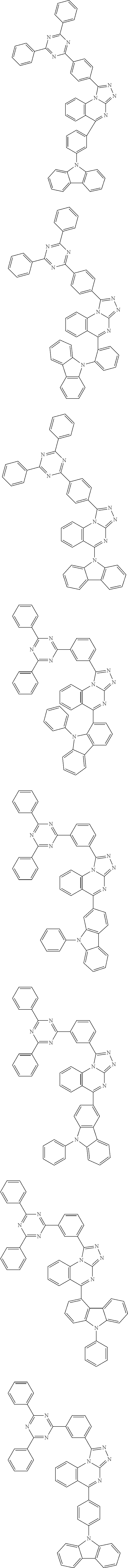

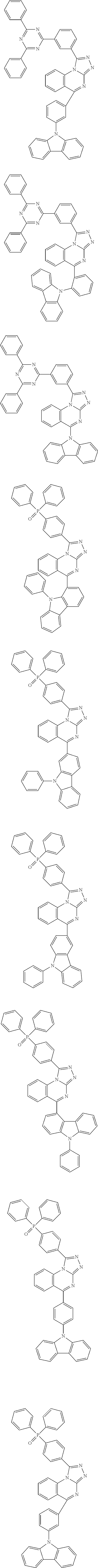

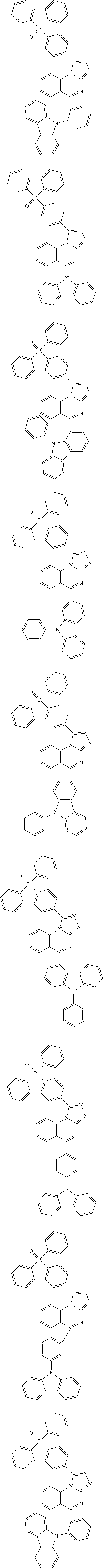

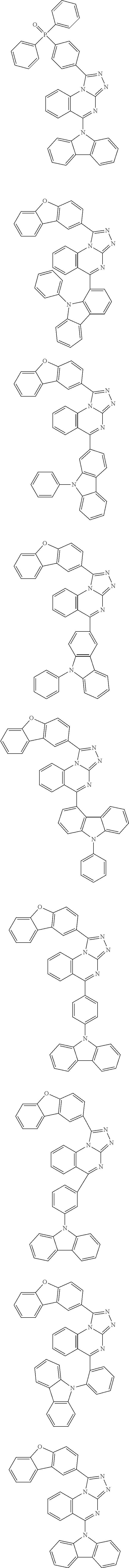

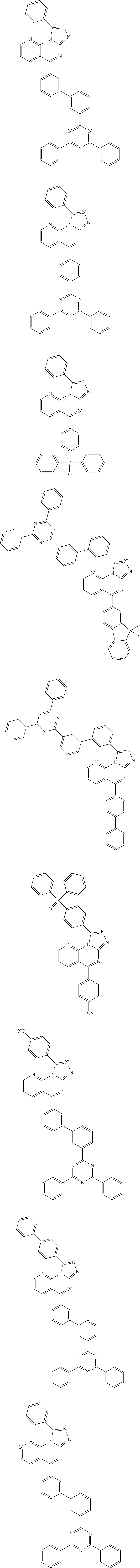

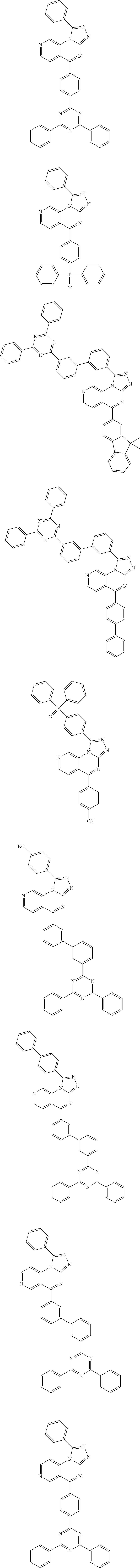

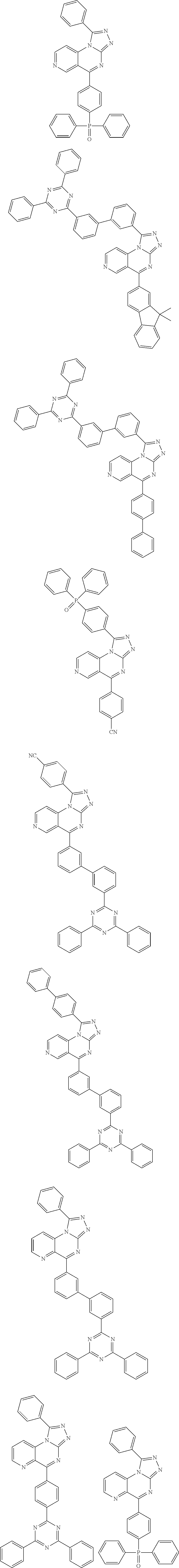

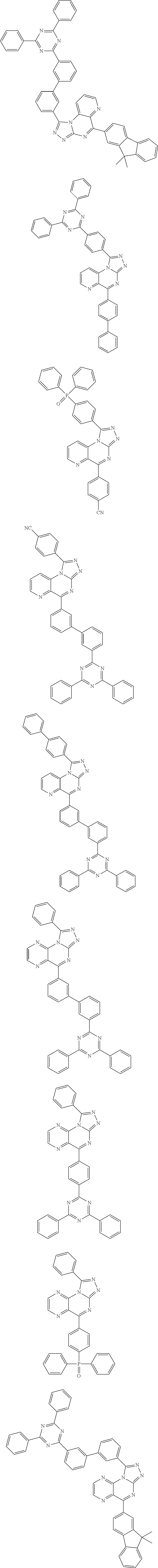

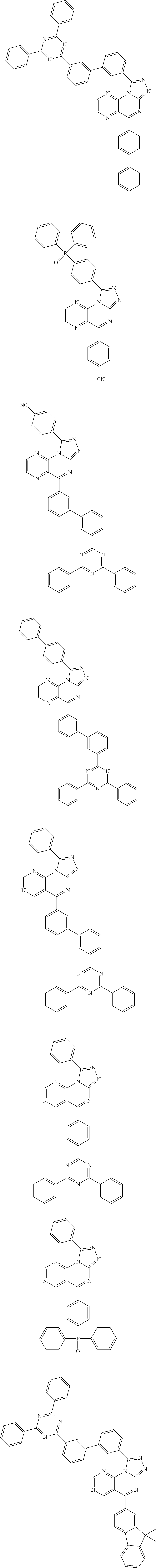

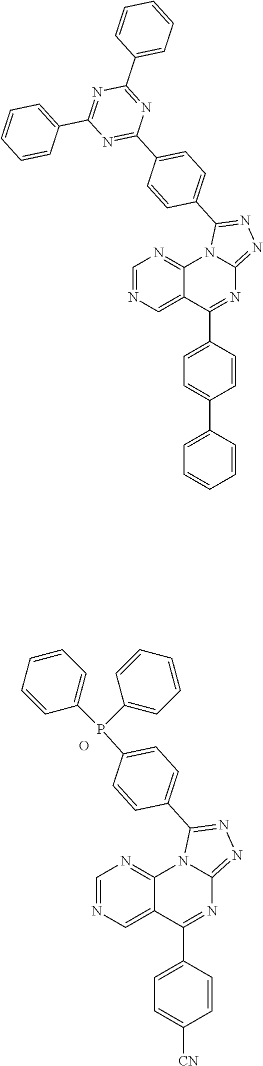

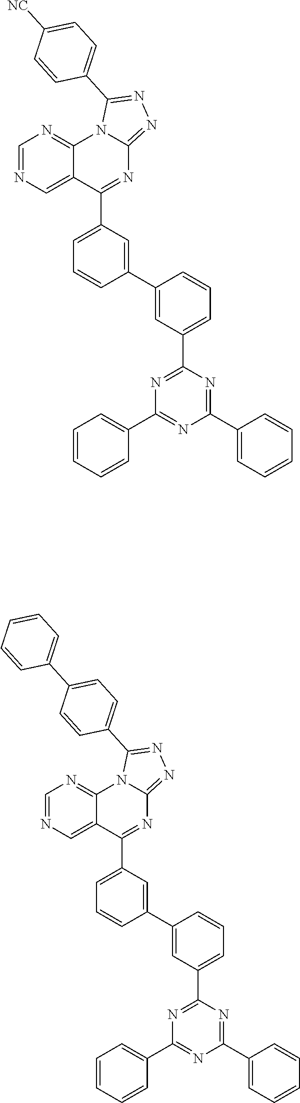 [SMILES: N#Cc1ccc(-c2nnc3nc(-c4cccc(-c5cccc(-c6nc(-c7ccccc7)nc(-c7ccccc7)n6)c5)c4)c4cncnc4n23)cc1 ; c1ccc(-c2ccc(-c3nnc4nc(-c5cccc(-c6cccc(-c7nc(-c8ccccc8)nc(-c8ccccc8)n7)c6)c5)c5cncnc5n34)cc2)cc1]

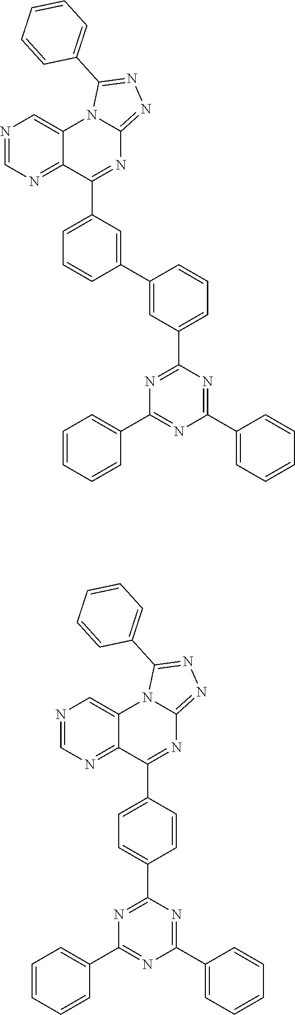 [SMILES: c1ccc(-c2nc(-c3ccccc3)nc(-c3cccc(-c4cccc(-c5nc6nnc(-c7ccccc7)n6c6cncnc56)c4)c3)n2)cc1 ; c1ccc(-c2nc(-c3ccccc3)nc(-c3ccc(-c4nc5nnc(-c6ccccc6)n5c5cncnc45)cc3)n2)cc1]

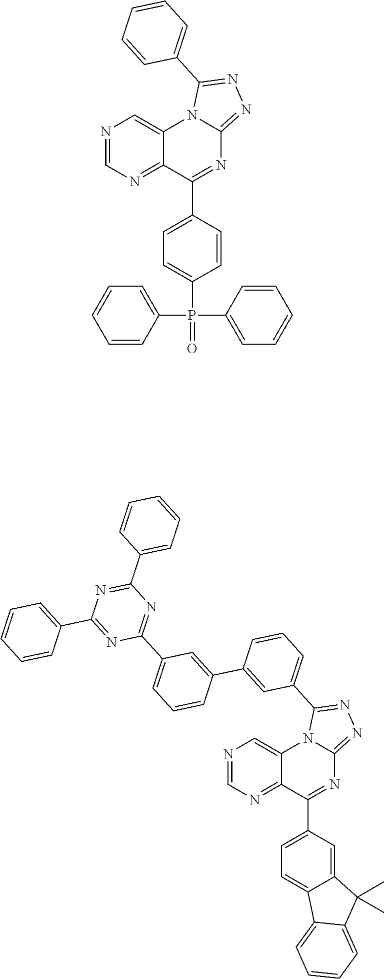 [SMILES: O=P(c1ccccc1)(c1ccccc1)c1ccc(-c2nc3nnc(-c4ccccc4)n3c3cncnc23)cc1 ; CC1(C)c2ccccc2-c2ccc(-c3nc4nnc(-c5cccc(-c6cccc(-c7nc(-c8ccccc8)nc(-c8ccccc8)n7)c6)c5)n4c4cncnc34)cc21]

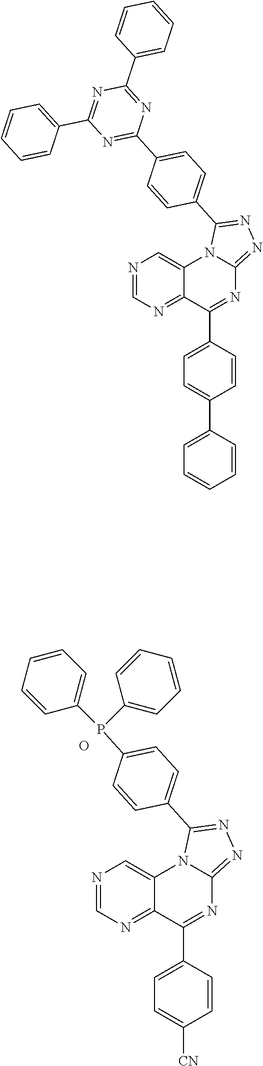

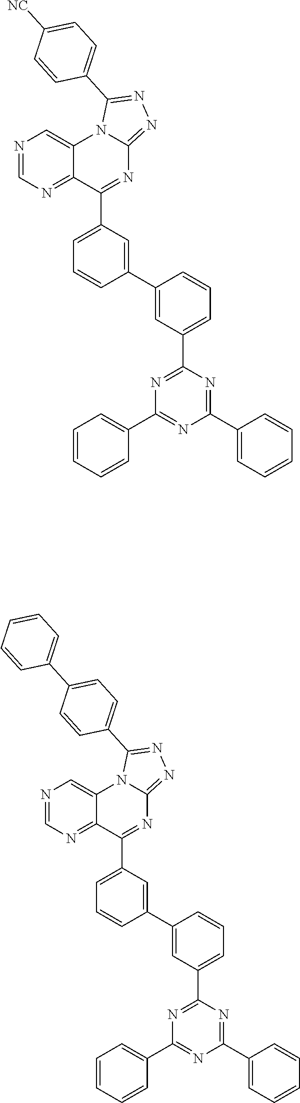 [SMILES: N#Cc1ccc(-c2nnc3nc(-c4cccc(-c5cccc(-c6nc(-c7ccccc7)nc(-c7ccccc7)n6)c5)c4)c4ncncc4n23)cc1 ; c1ccc(-c2ccc(-c3nnc4nc(-c5cccc(-c6cccc(-c7nc(-c8ccccc8)nc(-c8ccccc8)n7)c6)c5)c5ncncc5n34)cc2)cc1]

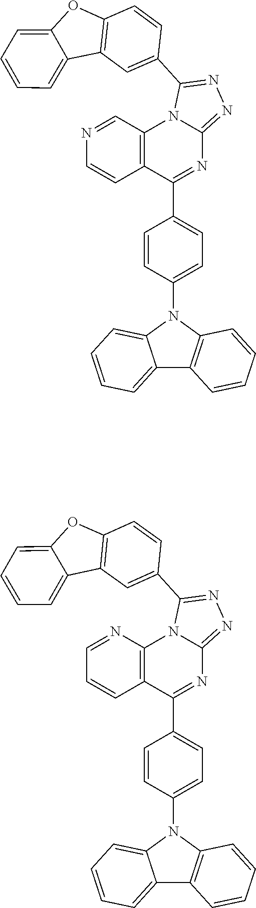 [SMILES: c1ccc2c(c1)oc1ccc(-c3nnc4nc(-c5ccc(-n6c7ccccc7c7ccccc76)cc5)c5ccncc5n34)cc12 ; c1ccc2c(c1)oc1ccc(-c3nnc4nc(-c5ccc(-n6c7ccccc7c7ccccc76)cc5)c5cccnc5n34)cc12]

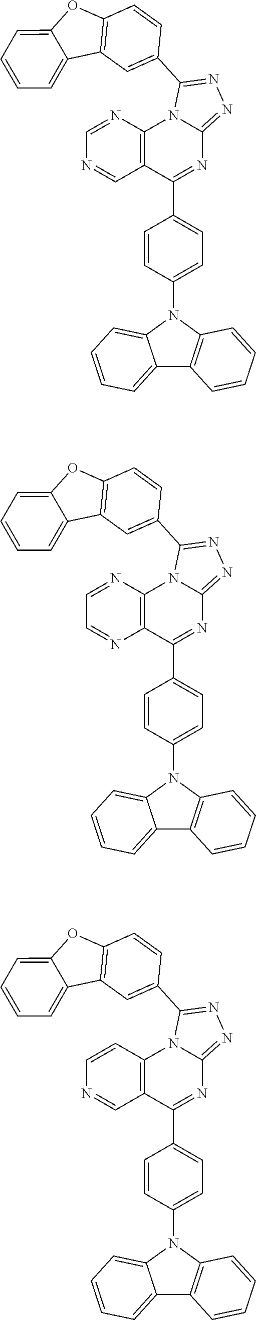 [SMILES: c1ccc2c(c1)oc1ccc(-c3nnc4nc(-c5ccc(-n6c7ccccc7c7ccccc76)cc5)c5cncnc5n34)cc12 ; c1ccc2c(c1)oc1ccc(-c3nnc4nc(-c5ccc(-n6c7ccccc7c7ccccc76)cc5)c5nccnc5n34)cc12 ; c1ccc2c(c1)oc1ccc(-c3nnc4nc(-c5ccc(-n6c7ccccc7c7ccccc76)cc5)c5cnccc5n34)cc12]

In some embodiments, in the compound of formula (I) as described herein, the singlet-triplet energy level difference ΔE_{ST}≤0.25 eV, preferably ≤0.20 eV, more preferably ≤0.15 eV, and most preferably ≤0.10 eV.

In some embodiments, in the compound of formula (I) as described herein, the ((LUMO+1)−LUMO)≥0.2 eV, preferably ≥0.25 eV, more preferably ≥0.3 eV, evern more preferably ≥0.35 eV, further preferably ≥0.4 eV, and most preferably ≥0.45 eV.

In some embodiments, in the compound of formula (I) as described herein, the glass transition temperature (Tg)≥100° C.; in some embodiments, Tg≥120° C.; in some embodiments, Tg≥140° C.; in some embodiments, Tg≥160° C.; in some embodiments, Tg≥180° C.

In some embodiments, the compound of formula (I) is partially deuterated; preferably 10% or more of total H, more preferably 20% or more of total H, further preferably 30% or more of total H, and most preferably 40% or more of total H, are deuterated.

In some embodiments, the compound of formula (I) is a small molecular material.

In some embodiments, the compound of formula (I) is used for evaporation-based OLEDs. For this purpose, the molecular weight of the compound≤1000 g/mol, preferably ≤900 g/mol, more preferably ≤850 g/mol, further preferably ≤800 g/mol, and most preferably ≤700 g/mol.

The present disclosure also relates to a synthetic method of the compound of formula (I) using the reagents with active groups. These active reagents comprise at least one leaving group, such as a bromine, an iodine, a boronic acid, or a boronic ester. The appropriate C—C coupling reactions are familiar to the persons skilled in the art and are described in the literature, particularly appropriate and preferred coupling reactions are the SUZUKI, STILLE, and HECK coupling reactions.

In another aspect, the present disclosure also provides a polymer comprising at least one repeating unit, where the at least one repeating unit comprises a structure of formula (I). In some embodiments, the polymer is a non-conjugated polymer in which the structural unit of formula (I) is on a side chain. In some embodiments, the polymer is a conjugated polymer. The term “small molecule” herein refers to a molecule that is no one of following: a polymer, an oligomer, a dendrimer, or a blend. In particular, there are no repeating structures in the small molecule. The molecular weight of the small molecule≤3000 g/mol, preferably ≤2000 g/mol, and most preferably ≤1500 g/mol.

The term “polymer” comprises homopolymer, copolymer, and block copolymer. Also in the present disclosure, the term “polymer” comprises dendrimer. For the synthesis and application of the dendrimers please refer to [Dendrimers and Dendrons, Wiley-VCH Verlag GmbH & Co. KGaA, 2002, Ed. George R. Newkome, Charles N. Moorefield, Fritz Vogtle.].

The term “conjugated polymer” refers to a polymer with backbone mainly comprising sp² hybrid orbitals of carbon atoms, well-known examples are polyacetylene and poly(phenylene vinylene). The carbon atoms on the backbones can also be substituted with other non-carbon atoms. Moreover, the above-mentioned structure should still be considered as a conjugated polymer when the sp² hybridization on the backbone is interrupted by natural defects. Also in the present disclosure, the backbone of conjugated polymer comprises aryl amines, aryl phosphines and other heteroarmotics, organometallic complexes, etc.

In some embodiments, the synthetic method of the polymer is selected from the group consisting of SUZUKI-, YAMAMOTO-, STILLE-, NIGESHI-, KUMADA-, HECK-, SONOGASHIRA-, HIYAMA-, FUKUYAMA-, HARTWIG-BUCHWALD-, and ULLMAN-.

In some embodiments, the glass transition temperature (Tg) of the polymer ≥100° C., preferably ≥120° C., more preferably ≥140° C., further preferably ≥160° C., and most preferably ≥180° C.

In some embodiments, the polydispersity index (PDI) of the polymer is preferably from 1 to 5, more preferably 1 to 4; even more preferably 1 to 3, further preferably 1 to 2, and most preferably 1 to 1.5.

In some embodiments, the weight-average molecular weight (M_{w}) of the polymer is preferably from 10k to 1 million, more preferably 50k to 500k, even more preferably 100k to 400k, further preferably 150k to 300k, and most preferably 200k to 250k.

In yet another aspect, the present disclosure further provides a mixture comprising a compound of formula (I) or a polymer as described herein, and at least one other organic functional material, the at least one other organic functional material is selected from one or more of the following: a hole-injection material (HIM), a hole-transport material (HTM), an electron-transport material (ETM), an electron-injection material (EIM), an electron-blocking material (EBM), a hole-blocking material (HBM), a light-emitting material (Emitter), a host material (Host), an organic dye. These organic functional materials are described in detail, for example, in WO2010135519A1, US20090134784A1, and WO2011110277A1. The entire contents of these three documents are hereby incorporated into this document for reference. The at least one other organic functional material can be a small molecule and a polymer.

In some embodiments, the mixture comprises a compound of formula (I), and a phosphorescent emitter. Herein, the compound as described herein can be used as a host, and the weight percentage of the phosphorescent emitter≤20 wt %, preferably ≤15 wt %, more preferably ≤10 wt %.

In some embodiments, the mixture comprises a compound of formula (I), another host material, and a phosphorescent emitter. Herein, the compound of formula (I) as described herein is used as a co-host material, and the weight percentage thereof ≥10 wt %, preferably ≥20 wt %, more preferably ≥30 wt %, and most preferably ≥40 wt %.

In some embodiments, the mixture comprises a compound of formula (I), a phosphorescent emitter, and a host material. In some embodiments, the compound of formula (I) as described herein can be used as an auxiliary emitting material, and the weight ratio of the compound and the phosphorescent emitter ranges from 1:2 to 2:1. In some embodiments, the triplet energy level of the compound represented by formula (I) is higher than that of the phosphorescent emitter.

In some embodiments, the mixture comprises a compound of formula (I) as described herein, and another TADF material.

In some embodiments, the mixture comprises an organic functional material (H1) selected from a compound as described herein, and at least one other organic functional material (H2) selected from a hole-injection material (HIM), a hole-transport material (HTM), or an organic host material (Host).

In some embodiments, in the mixture as described herein, at least one of the organic functional material (H1) and the at least one other organic functional material (H2) has ((LUMO+1)−LUMO)≥0.2 eV, preferably ≥0.25 eV, more preferably ≥0.3 eV, even more preferably ≥0.35 eV, further preferably ≥0.4 eV, and most preferably ≥0.45 eV.

In some embodiments, the organic functional material (H1) of the mixture as described herein has ((LUMO+1)−LUMO)≥0.2 eV, preferably ≥0.25 eV, more preferably ≥0.3 eV, even more preferably ≥0.35 eV, further preferably ≥0.4 eV, and most preferably ≥0.45 eV.

In some embodiments, in the mixture as described herein, at least one of the organic functional material (H1) and the at least one other organic functional material (H2) has (HOMO−(HOMO−1))≥0.2 eV, preferably ≥0.25 eV, more preferably ≥0.3 eV, even more preferably ≥0.35 eV, further preferably ≥0.4 eV, and most preferably ≥0.45 eV.

In some embodiments, the at least one other organic functional material (H2) of the mixture as described herein has (HOMO−(HOMO−1))≥0.2 eV, preferably ≥0.25 eV, more preferably ≥0.3 eV, even more preferably ≥0.35 eV, further preferably ≥0.4 eV, and most preferably ≥0.45 eV.

In some embodiments, in the mixture as described herein, 1) the singlet-triplet energy level difference ΔE_{ST} of the organic functional material H1≤0.30 eV, preferably ≤0.25 eV, more preferably ≤0.20 eV, and most preferably ≤0.10 eV, and/or 2) the LUMO of H2 is higher than that of H1, and the HOMO of H2 is lower than that of H1.

In some embodiments, in the mixture as described herein, the organic functional material (H1) and the at least one other organic functional material (H2) can form type II heterojunction energy structure, and min (LUMO(H1)−HOMO (H2), LUMO(H2)−HOMO(H1))≤min(ET(H1), ET(H2))+0.1 eV, where LUMO(H1), HOMO(H1), and ET(H1) respectively represent the lowest unoccupied orbital energy level, the highest occupied orbital energy level, and the triplet energy level of the organic functional material (H1); LUMO(H2), HOMO(H2), and ET(H2) respectively represent the lowest unoccupied orbital energy level, the highest occupied orbital energy level, and the triplet energy level of the at least one other organic functional material (H2). More referably, min(LUMO(H1)−HOMO(H2), LUMO(H2)−HOMO(H1))≤min(ET(H1), ET(H2)); and most preferably, min(LUMO(H1)−HOMO(H2), LUMO(H2)−HOMO(H1))≤min(ET(H1), ET(H2))−0.1 eV.

In some embodiments, in the mixture as described herein, the organic functional material (H1) and the at least one other organic functional material (H2) can form type I heterojunction energy structure, and the singlet-triplet energy level difference ΔE_{ST} of the organic functional material (H1) or the at least one other organic functional material (H2)≤0.25 eV, preferably ≤0.20 eV, more preferably ≤0.15 eV, and most preferably ≤0.10 eV.

In some embodiments, in the mixture as described herein, the molar ratio of the organic functional material (H1) to the at least one other organic functional material (H2) is from 1:9 to 9:1, preferably from 2:8 to 8:2, more preferably from 3:7 to 7:3, further preferably from 4:6 to 6:4, and most preferably from 4.5:5.5 to 5.5:4.5.

In some embodiments, in the mixture as described herein, the molecular weight difference between the organic functional material (H1) and the at least one other organic functional material (H2)≤100 Dalton, preferably ≤80 Dalton, more preferably ≤70 Dalton, even more preferably ≤60 Dalton, further preferably ≤40 Dalton, and most preferably ≤30 Dalton.

In some embodiments, in the mixture as described herein, the sublimation temperature difference between the organic functional material (H1) and the at least one other organic functional material (H2)≤50 K, preferably ≤30 K, more preferably ≤20 K, and most preferably ≤10 K.

In some embodiments, in the mixture as described herein, at least one of the organic functional material (H1) and the at least one other organic functional material (H2) has a glass transition temperature (Tg)≥100° C.; in some embodiments, at least one of them has a Tg≥120° C.; in some embodiments, at least one of them has a Tg≥140° C.; in some embodiments, at least one of them has a Tg≥160° C.; in some embodiments, at least one of them has a Tg≥180° C.

The triplet host, triplet emitter, TADF material, and EIM/ETM are described in detail below (but not limited thereto).

### 1. Triplet Host

Examples of triplet host materials are not specially limited, and any metal complex or organic compound may be used as the host material as long as its triplet energy is higher than that of the emitter, especially higher than that of the triplet emitter or a phosphorescent emitter. Examples of metal complexes that may be used as a triplet host (Host) include (but not limited to) the following general structures.

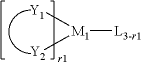

Where M₁ is a metal; (Y₁-Y₂) is a bidentate ligand; Y₁ and Y₂ are each independently selected from C, N, O, P, or S; L is an auxiliary ligand; r1 is an integer with the value from 1 to the maximum coordination number of this metal.

In some embodiments, M₁ may be selected from Al or Zn, the metal complexes that can be used as the triplet hosts have the following forms:

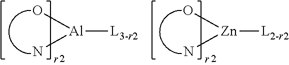

(O—N) is a bidentate ligand in which the metal is coordinated to the O atoms and the N atoms. r2 is an integer with a value from 1 to the maximum coordination number of this metal.

In some embodiments, M₁ may be selected from Ir or Pt.

Examples of organic compounds that can be used as the triplet hosts are selected from: compounds containing cyclic aromatic hydrocarbon groups such as benzene, biphenyl, triphenylbenzene, benzofluorene; compounds containing aromatic heterocyclic groups such as dibenzothiophene, dibenzofuran, dibenzoselenophene, furan, thiophene, benzofuran, benzothiophene, benzoselenophene, carbazole, dibenzocarbazole, indole carbazole, pyridine indole, pyrrole dipyridine, pyrazole, imidazole, triazole, oxazole, thiazole, oxadiazole, oxatriazole, dioxazole, thiadiazole, pyridine, pyridazine, pyrimidine, pyrazine, triazines, oxazine, oxothiazine, oxadiazine, indole, benzimidazole, indazole, oxazole, dibenzoxazole, benzisoxazole, benzothiazole, quinoline, isoquinoline, cinnoline, quinazoline, quinoxaline, naphthalene, phthalide, pteridine, xanthene, acridine, phenazine, phenothiazine, Phenoxazine, benzofuranopyridine, furanopyridine, benzothienopyridine, thienopyridine, benzoselenophene pyridine or selenophene benzodipyridine; and groups containing 2 to 10 ring structures, which may be the same or different types of cyclic aromatic hydrocarbon groups or aromatic heterocyclic groups, linked to each other directly or by at least one of the following groups, such as oxygen atoms, nitrogen atoms, sulfur atoms, silicon atoms, phosphorus atoms, boron atoms, chain structural units and aliphatic ring groups, where each aromatic ring or aromatic heterocyclic ring can be further substituted and the substituents may selected from hydrogen, deuterium, cyano, halogen, alkyl, alkoxy, amino, alkene, alkyne, aryl, heteroalkyl, aryl or heteroaryl.

In some embodiments, the triplet host material may be selected from a compound comprising at least one of the following groups.

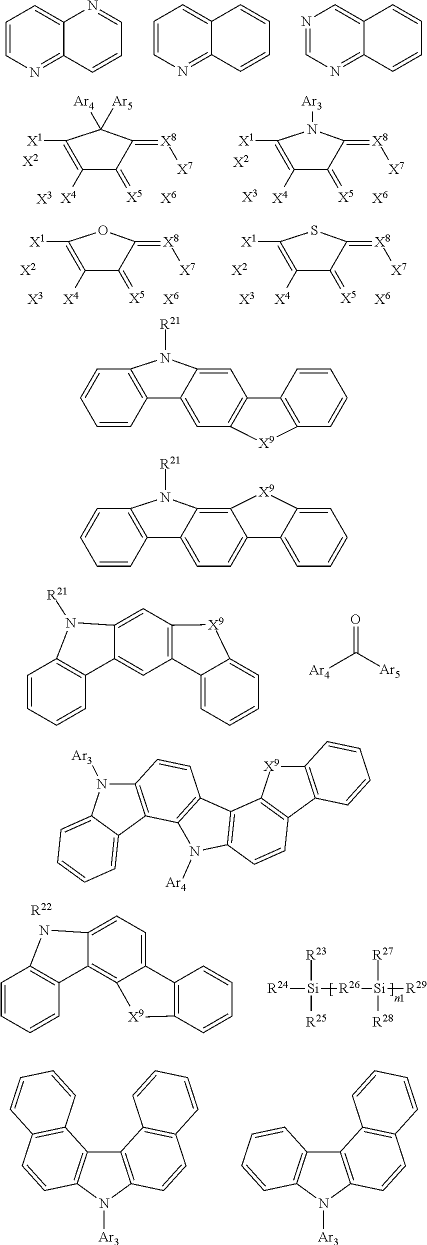

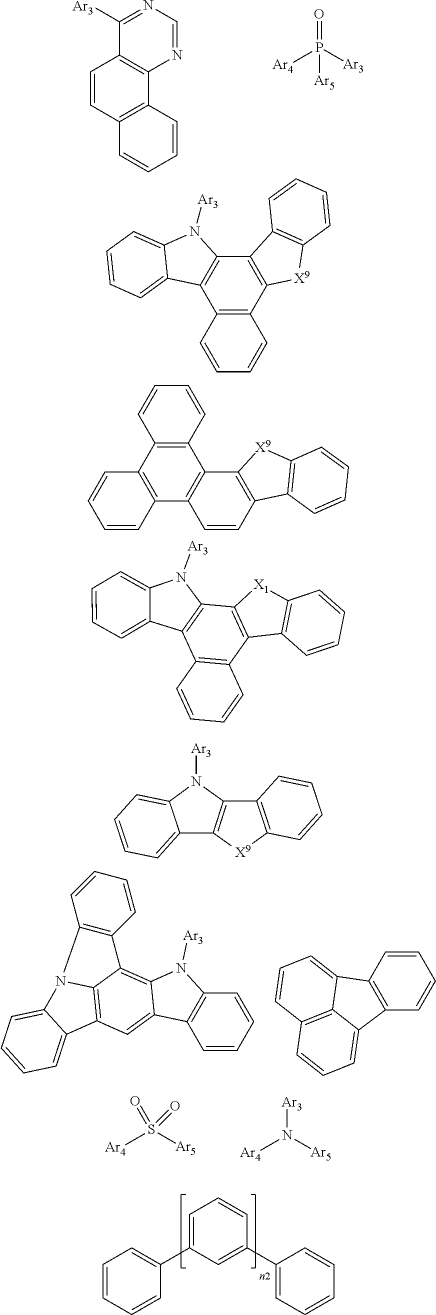

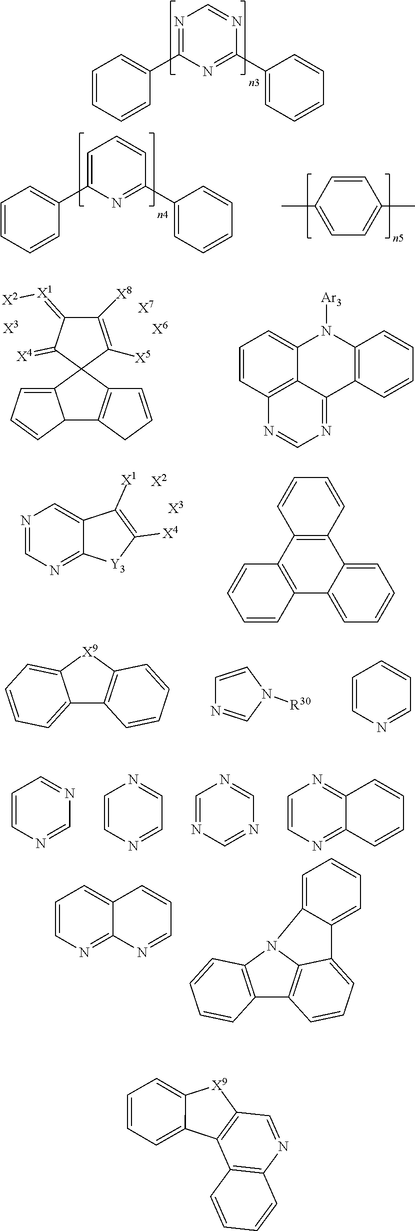

Where X¹ to X⁹ are each independently selected from CR³¹R³² or NR³³; each Y₃ is independently selected from CR³⁴R³⁵, NR³⁶, O, or S; each of Ar₃ to Ar₅ is independently selected from a substituted/unsubstituted C₆-C₃₀ aryl group or a substituted/unsubstituted C₅-C₃₀ heteroaryl group; n1-n5 are integers from 1 to 20; R²¹-R³⁶ are identically defined as the above-mentioned R₁.

Examples of suitable triplet host materials are listed below, but not limited to:

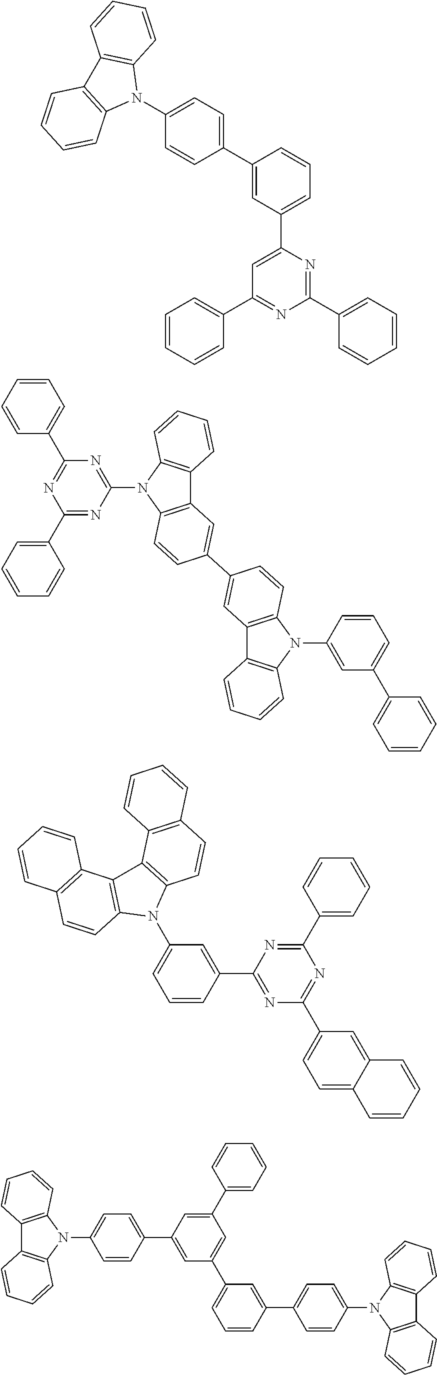 [SMILES: c1ccc(-c2cc(-c3cccc(-c4ccc(-n5c6ccccc6c6ccccc65)cc4)c3)nc(-c3ccccc3)n2)cc1 ; c1ccc(-c2cccc(-n3c4ccccc4c4cc(-c5ccc6c(c5)c5ccccc5n6-c5nc(-c6ccccc6)nc(-c6ccccc6)n5)ccc43)c2)cc1 ; c1ccc(-c2nc(-c3cccc(-n4c5ccc6ccccc6c5c5c6ccccc6ccc54)c3)nc(-c3ccc4ccccc4c3)n2)cc1 ; c1ccc(-c2cc(-c3ccc(-n4c5ccccc5c5ccccc54)cc3)cc(-c3cccc(-c4ccc(-n5c6ccccc6c6ccccc65)cc4)c3)c2)cc1]

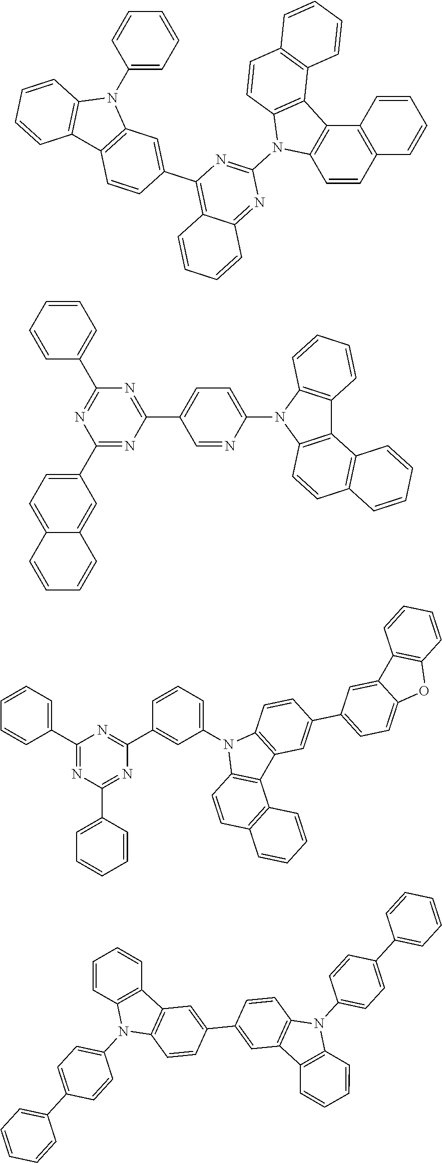 [SMILES: c1ccc(-n2c3ccccc3c3ccc(-c4nc(-n5c6ccc7ccccc7c6c6c7ccccc7ccc65)nc5ccccc45)cc32)cc1 ; c1ccc(-c2nc(-c3ccc(-n4c5ccccc5c5c6ccccc6ccc54)nc3)nc(-c3ccc4ccccc4c3)n2)cc1 ; c1ccc(-c2nc(-c3ccccc3)nc(-c3cccc(-n4c5ccc(-c6ccc7oc8ccccc8c7c6)cc5c5c6ccccc6ccc54)c3)n2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

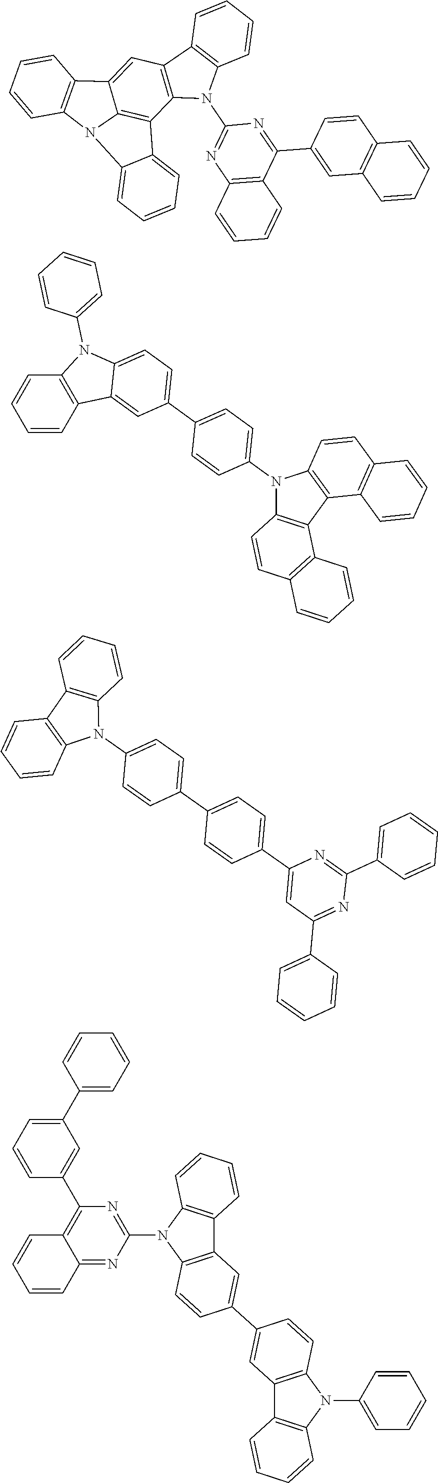 [SMILES: c1ccc2cc(-c3nc(-n4c5ccccc5c5cc6c7ccccc7n7c8ccccc8c(c54)c67)nc4ccccc34)ccc2c1 ; c1ccc(-n2c3ccccc3c3cc(-c4ccc(-n5c6ccc7ccccc7c6c6c7ccccc7ccc65)cc4)ccc32)cc1 ; c1ccc(-c2cc(-c3ccc(-c4ccc(-n5c6ccccc6c6ccccc65)cc4)cc3)nc(-c3ccccc3)n2)cc1 ; c1ccc(-c2cccc(-c3nc(-n4c5ccccc5c5cc(-c6ccc7c(c6)c6ccccc6n7-c6ccccc6)ccc54)nc4ccccc34)c2)cc1]

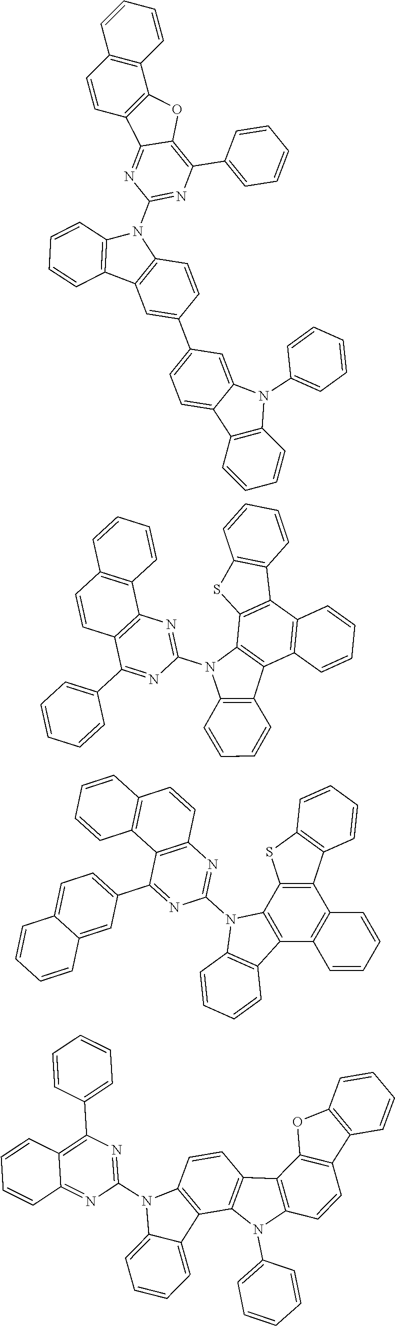

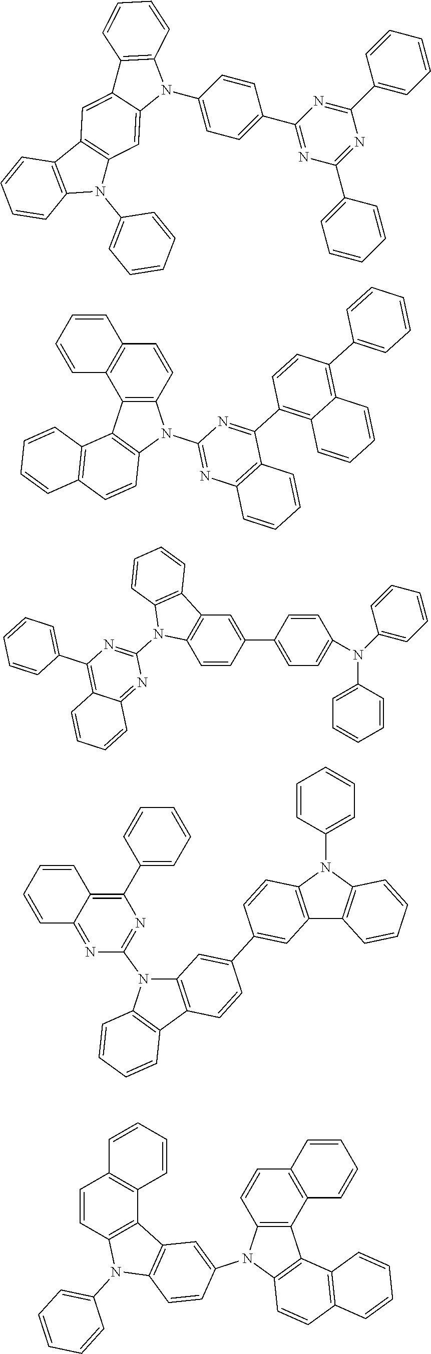

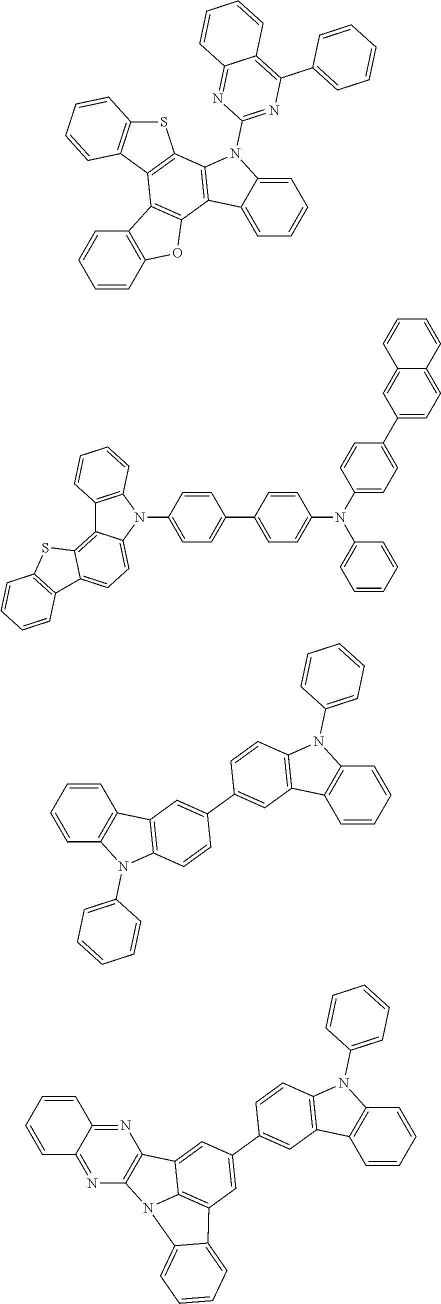 [SMILES: c1ccc(-c2nc(-n3c4ccccc4c4c5oc6ccccc6c5c5c6ccccc6sc5c43)nc3ccccc23)cc1 ; c1ccc(N(c2ccc(-c3ccc(-n4c5ccccc5c5c6sc7ccccc7c6ccc54)cc3)cc2)c2ccc(-c3ccc4ccccc4c3)cc2)cc1 ; c1ccc(-n2c3ccccc3c3cc(-c4ccc5c(c4)c4ccccc4n5-c4ccccc4)ccc32)cc1 ; c1ccc(-n2c3ccccc3c3cc(-c4cc5c6ccccc6n6c7nc8ccccc8nc7c(c4)c56)ccc32)cc1]

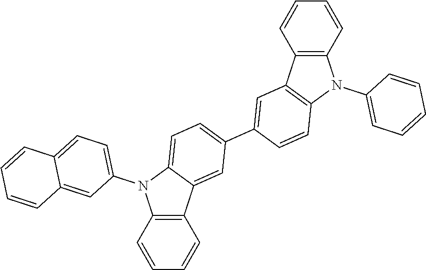 [SMILES: c1ccc(-n2c3ccccc3c3cc(-c4ccc5c(c4)c4ccccc4n5-c4ccc5ccccc5c4)ccc32)cc1]

### 2. Triplet Emitter

The triplet emitter is also called a phosphorescent emitter. In some embodiments, the triplet emitter is a metal complex of formula M(L′)ₙ₀, where M may be a metal atom; L′ may be a same or different organic ligand at each occurrence, and may be bonded or coordinated to the metal atom M at one or more positions; n0 is an integer greater than 1, preferably is 1, 2, 3, 4, 5, or 6. Alternatively, these metal complexes may be attached to a polymer by one or more positions, most preferably through an organic ligand.

In some embodiments, the metal atom M may be selected from the group consisting of transition metal elements or lanthanides or actinides, preferably Ir, Pt, Pd, Au, Rh, Ru, Os, Sm, Eu, Gd, Tb, Dy, Re, Cu, or Ag, and particularly preferably Os, Ir, Ru, Rh, Re, Pd, Au, or Pt.

Preferably, the triplet emitter comprises a chelating ligand (i.e., a ligand) coordinating to the metal via at least two bonding sites, and it is particularly preferred that the triplet emitter comprises two or three identical or different bidentate or multidentate ligand. Chelating ligands help to improve stability of metal complexes.

Examples of organic ligands may be selected from the group consisting of phenylpyridine derivatives, 7,8-benzoquinoline derivatives, 2-(2-thienyl) pyridine derivatives, 2-(1-naphthyl) pyridine derivatives, or 2-phenylquinoline derivatives. All of these organic ligands may be substituted, for example, substituted with fluoromethyl or trifluoromethyl. The auxiliary ligand may be preferably selected from acetylacetonate or picric acid.

In some embodiments, the metal complex which may be used as the triplet emitter may have the following form:

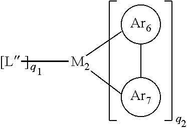

Where M₂ is a metal selected from the group consisting of transition metal elements or lanthanides or actinides, and particularly preferably Ir, Pt, Au.

Ar₆ at each occurrence may be the same or different cyclic group comprising a donor atom, that is an atom with a lone pair of electrons such as N or P, through which the cyclic group is coordinated with the metal; Ar₇ at each occurrence may be the same or different cyclic group comprising a carbon atom, through which the cyclic group is coordinated with the metal; Ar₆ and Ar₇ are covalently bonded together, where each of them may contain one or more substituents which may also be joined together; L″ may be the same or different at each occurrence and is a bidentate chelating ligand, and most preferably a monoanionic bidentate chelating ligand; q₁ is 0, 1, 2, or 3, preferably is 2 or 3; q2 is 0, 1, 2, or 3, preferably is 0 or 1.

Examples of triplet emitter materials those are extremely useful may be found in the following patent documents and references: WO200215645, US20050258742, U.S. Pat. No. 6,835,469, WO2007095118A1, etc. The patent documents listed above are specially incorporated herein by reference in their entirety.

Examples of some suitable triplet emitters are listed below:

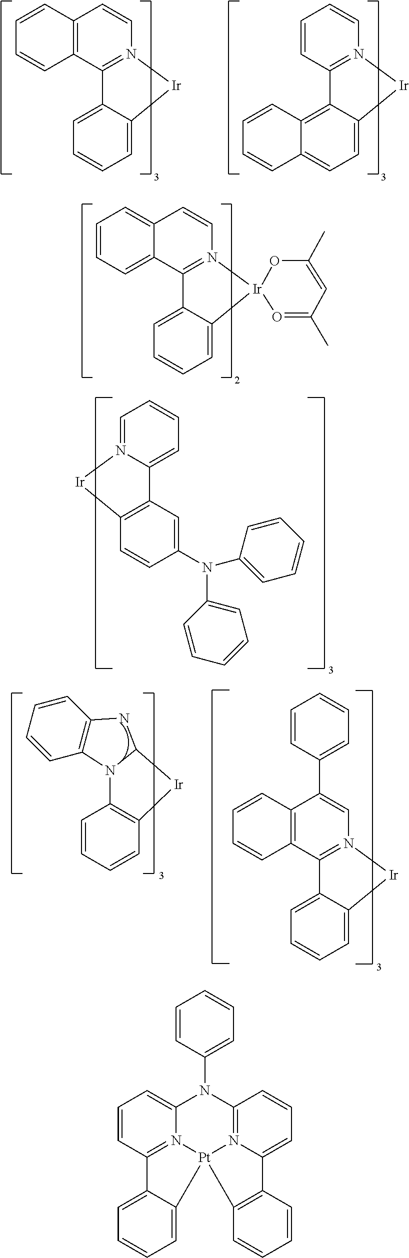

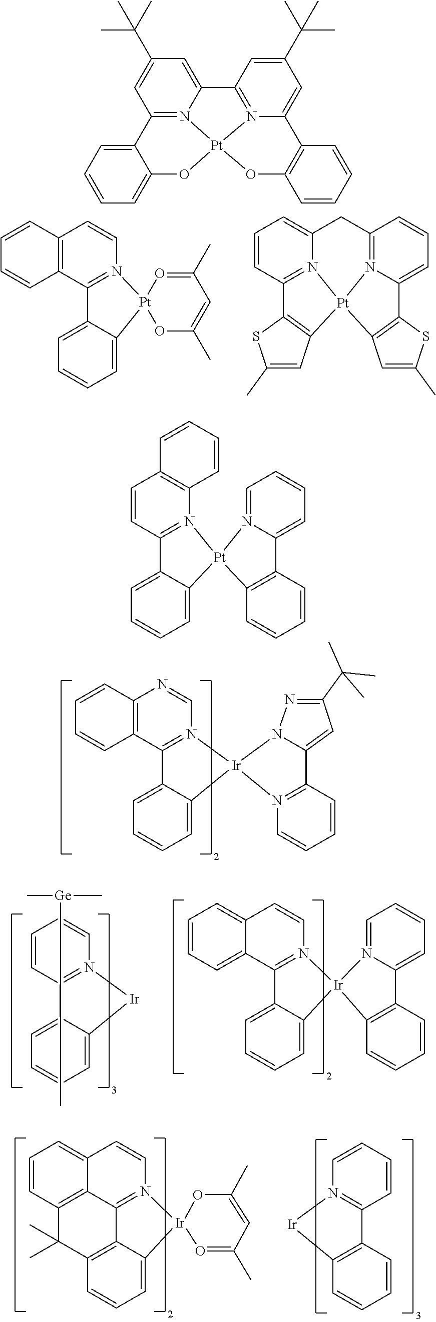

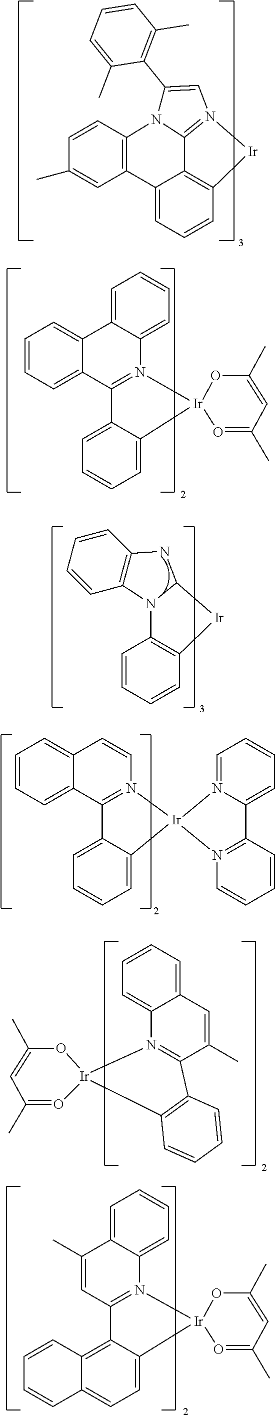

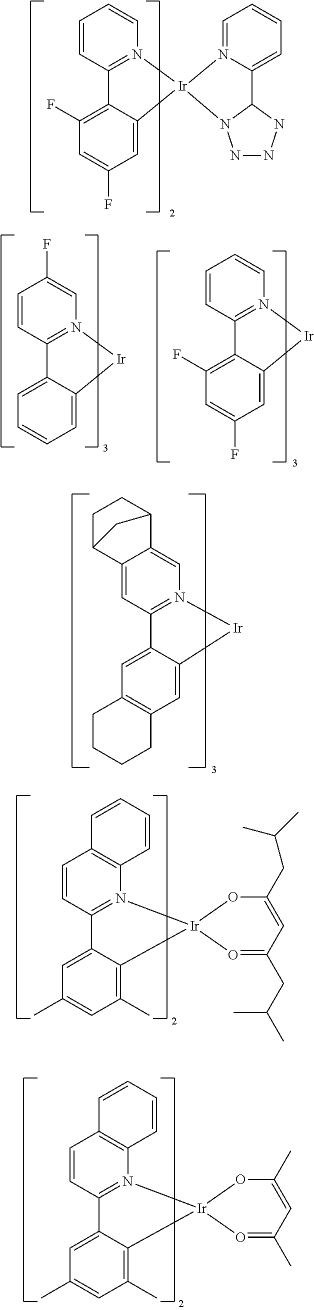

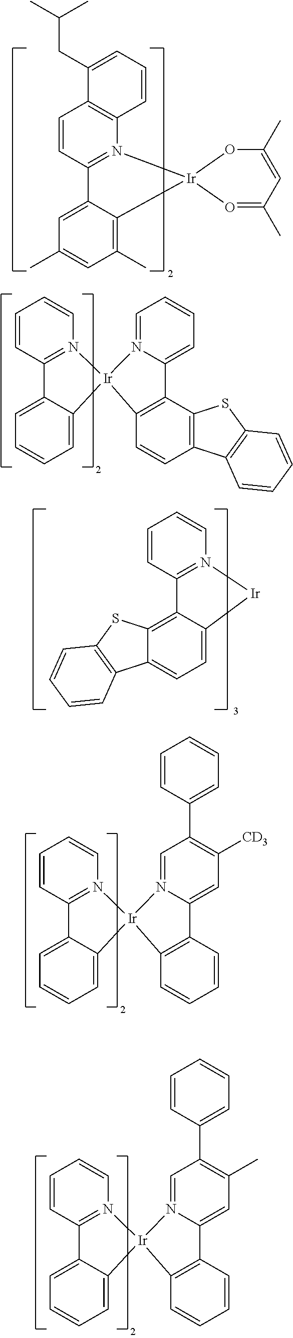

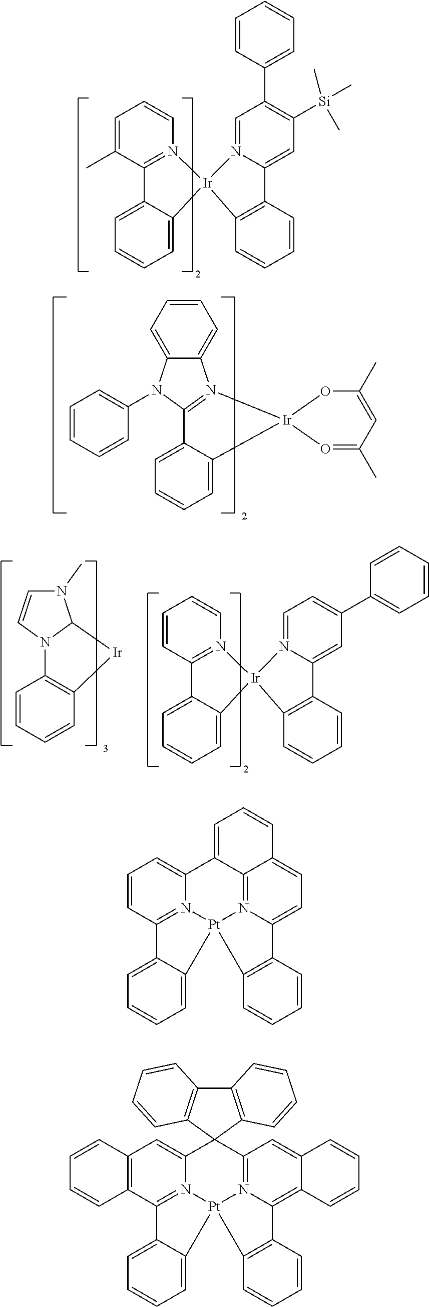

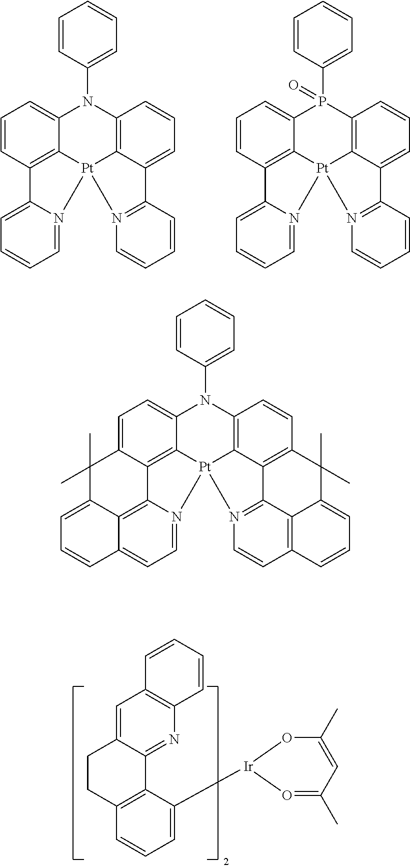

### 3. TADF Material

Conventional organic fluorescent materials can only emit light using 25% singlet excitons formed by electrical excitation, therefore, the devices have relatively low internal quantum efficiency (up to 25%). The phosphorescent materials enhance the intersystem crossing due to the strong spin-orbit coupling of the heavy atom center, the singlet excitons and the triplet excitons formed by the electric excitation can be effectively utilized, so that the internal quantum efficiency of the devices can reach 100%. However, the phosphorescent materials are expensive, the material stability is poor, and the device efficiency roll-off is serious. These problems limit its application in OLED. Thermally-activated delayed fluorescent (TADF) materials are the third generation of organic emitting materials developed after organic fluorescent materials and organic phosphorescent materials. This type of materials generally has a small singlet-triplet energy level difference (ΔE_{ST}), and triplet excitons can be converted to singlet excitons through intersystem crossing. This can make full use of the singlet excitons and triplet excitons formed by the electric excitation. The devices can achieve 100% internal quantum efficiency. Meanwhile, due to the controllable structure, stable property, low cost, TADF materials without precious metals have a wide application prospect in the OLED field.

TADF materials need to have a small singlet-triplet energy level difference (ΔE_{ST}), preferably ΔE_{ST}<0.3 eV, more preferably ΔE_{ST}<0.2 eV, and most preferably ΔE_{ST}<0.1 eV. In some embodiments, the TADF material has a relatively small ΔE_{ST}. In some embodiments, the TADF material has a high fluorescence quantum efficiency. Some TADF materials can be found in CN103483332A and TW201350558A. The entire contents of the above listed patents are hereby incorporated by reference.

Examples of some suitable TADF materials are listed below:

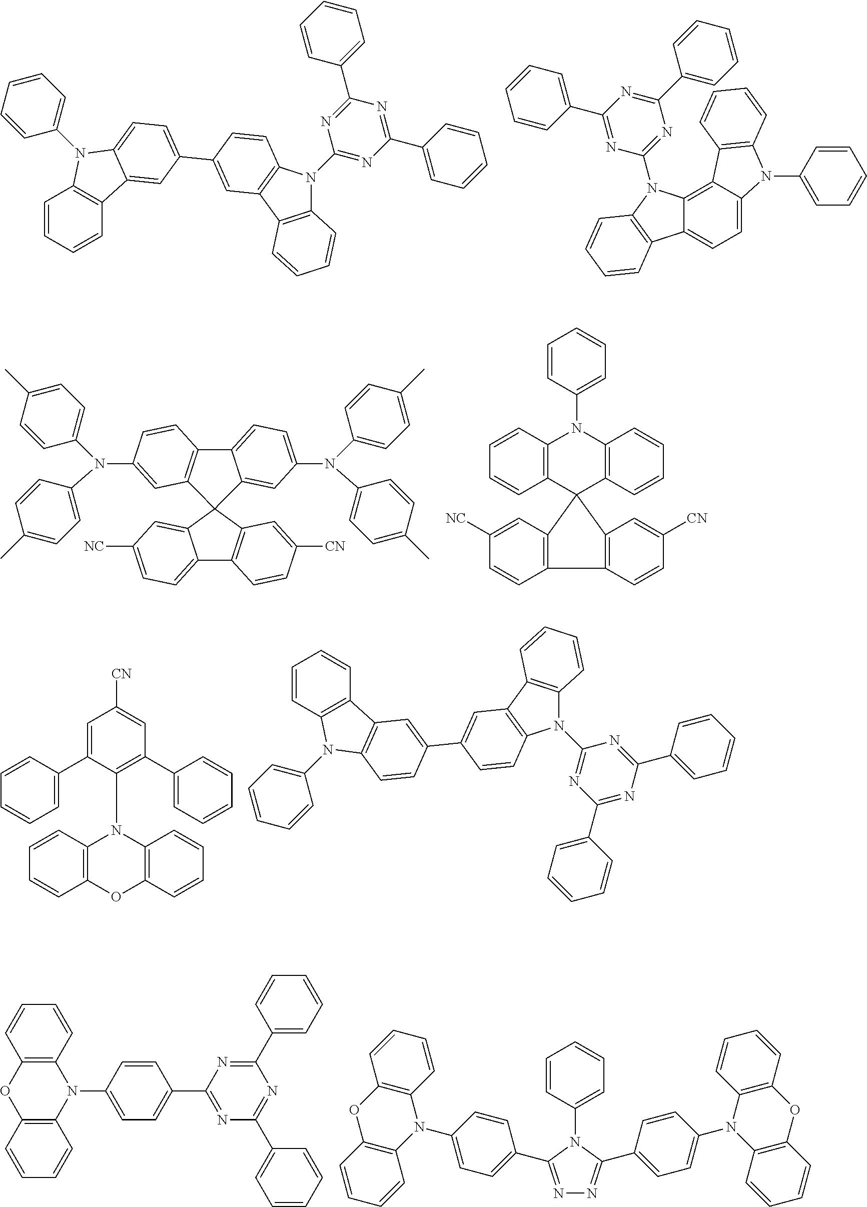

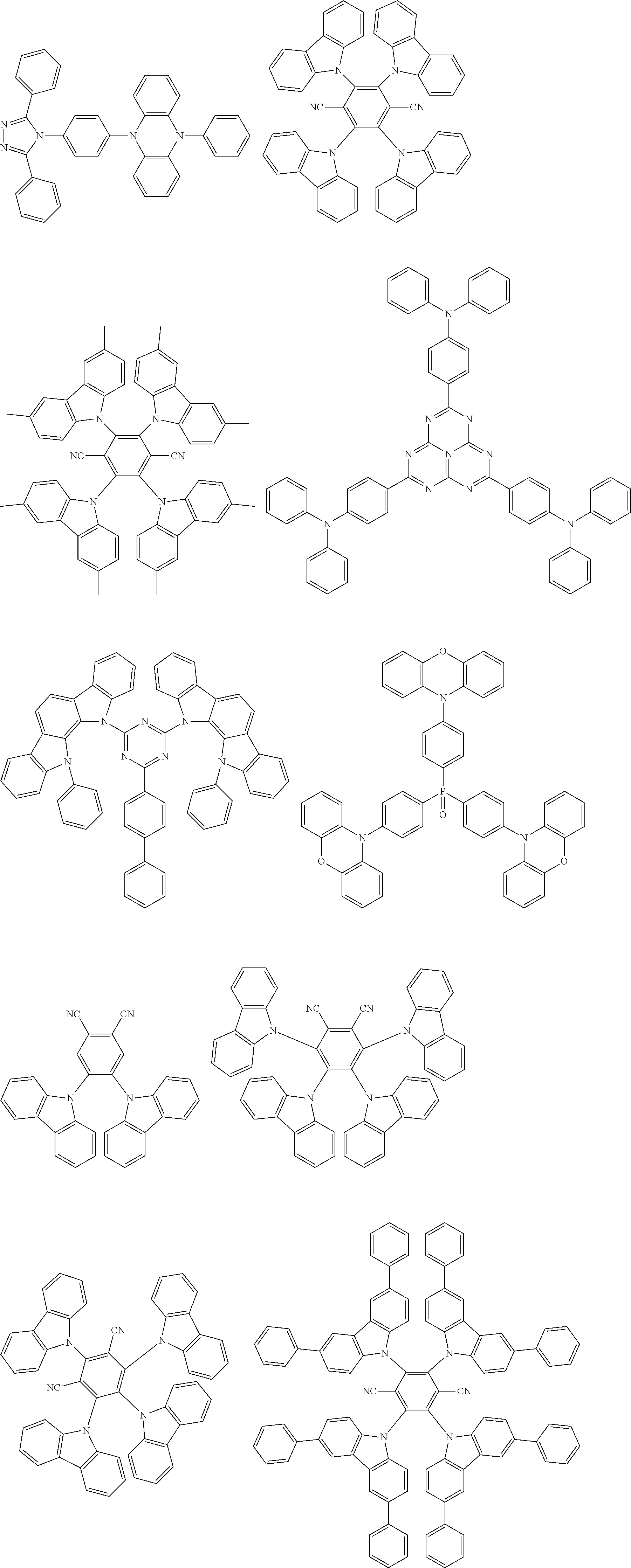

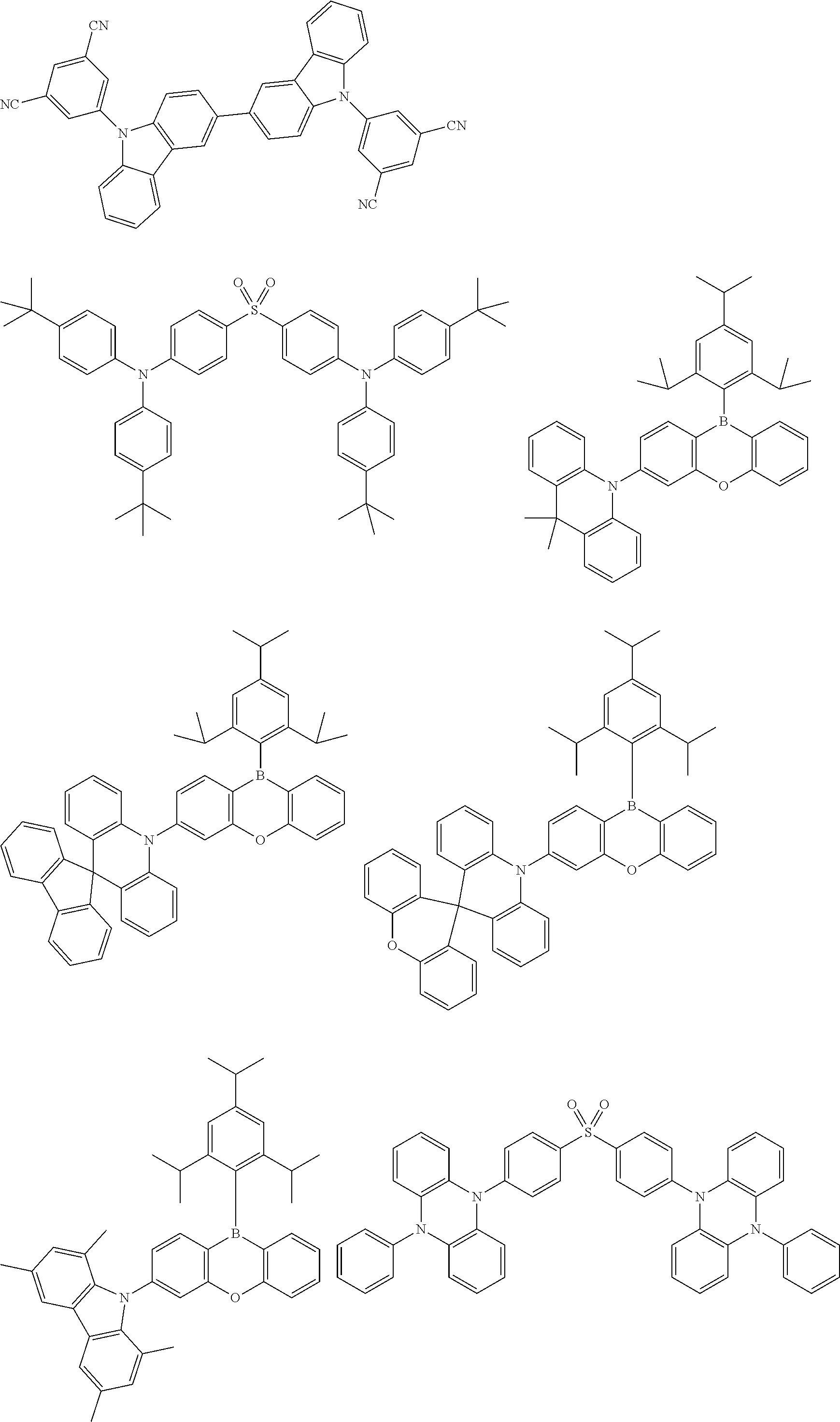

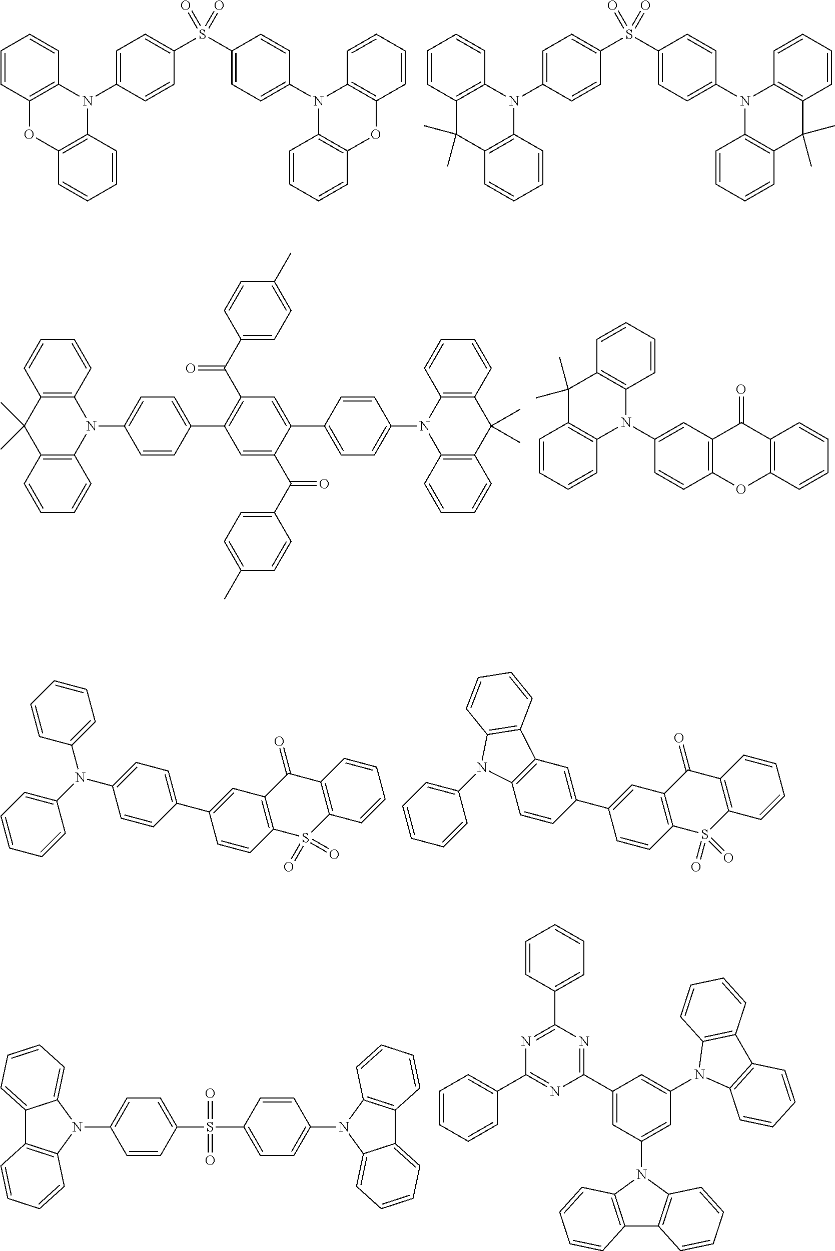

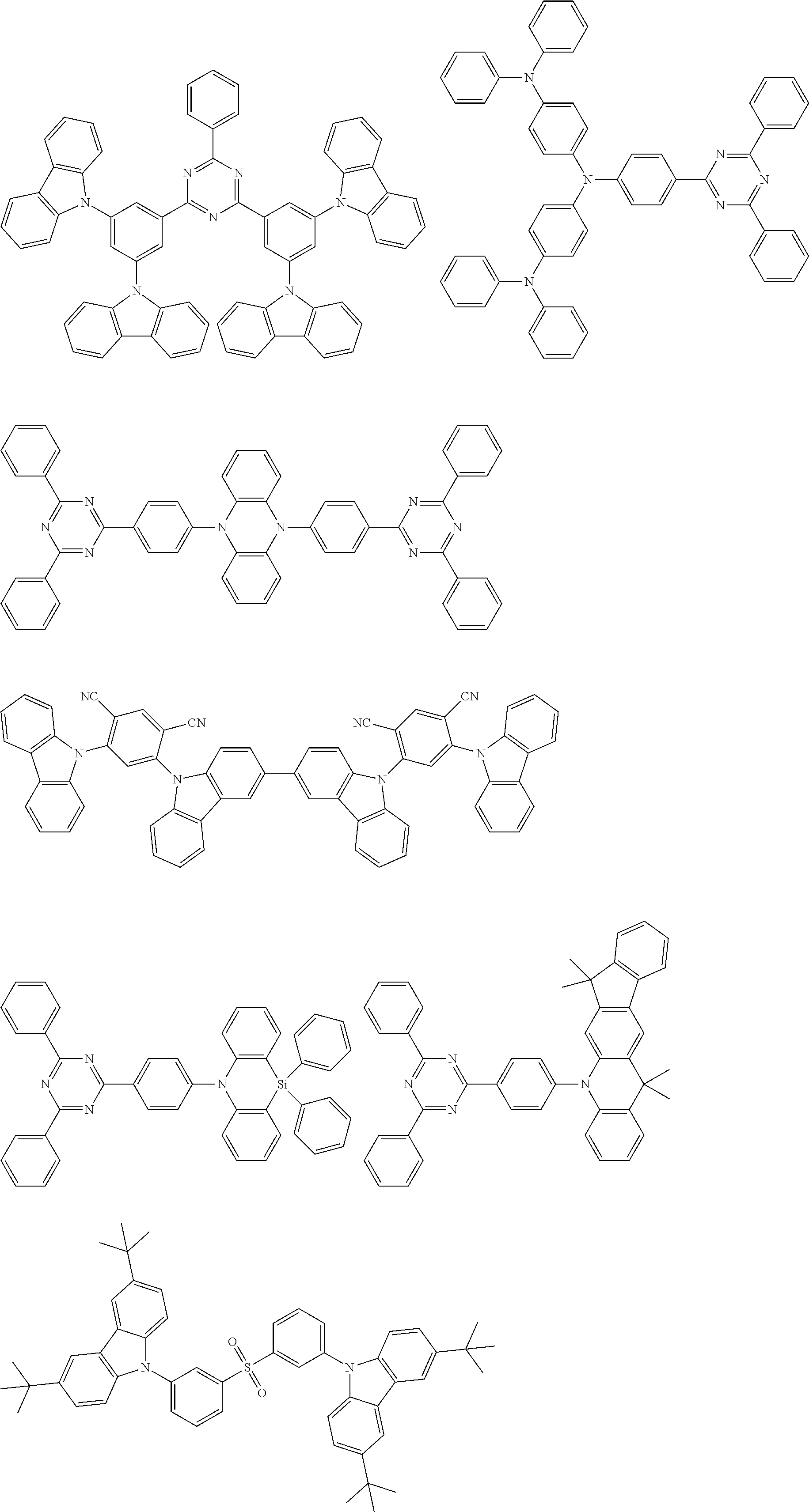

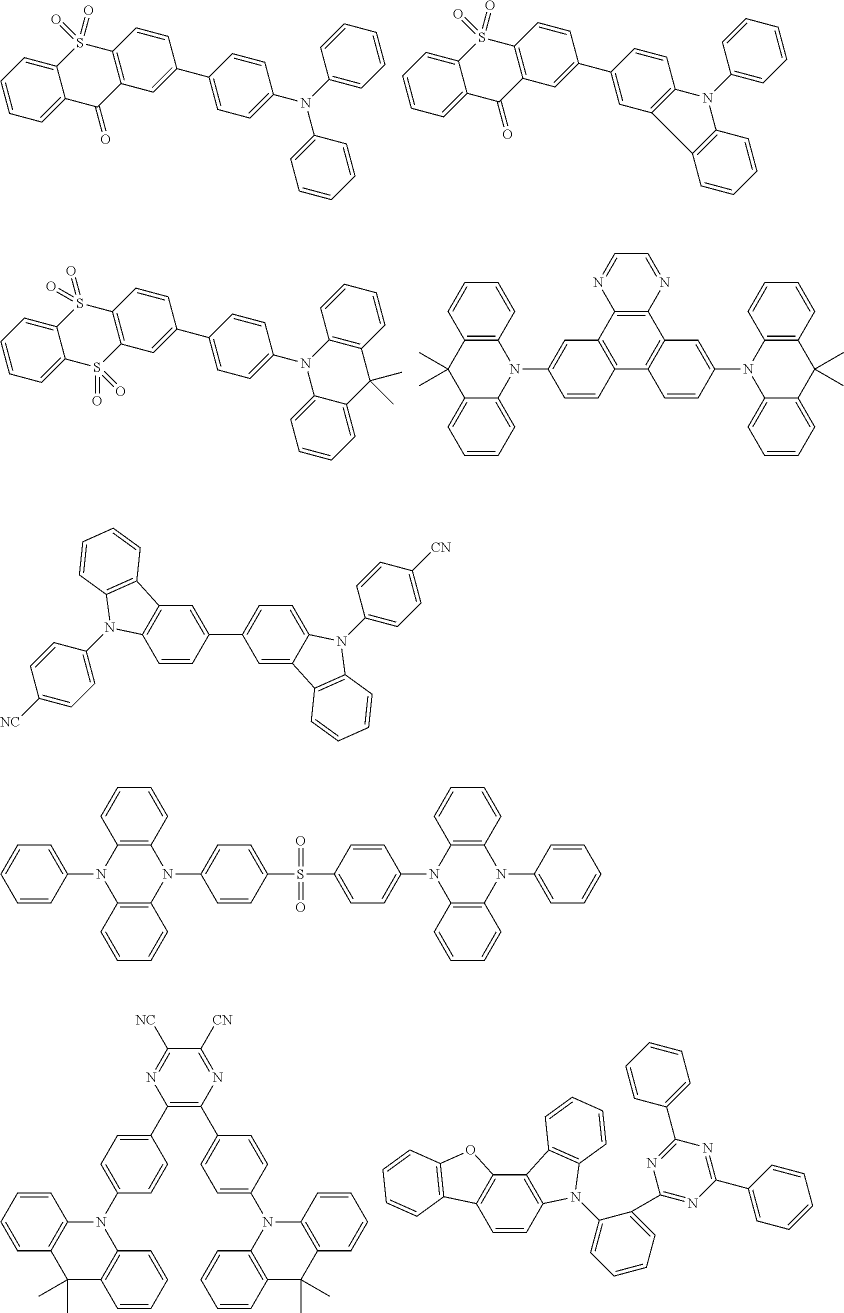

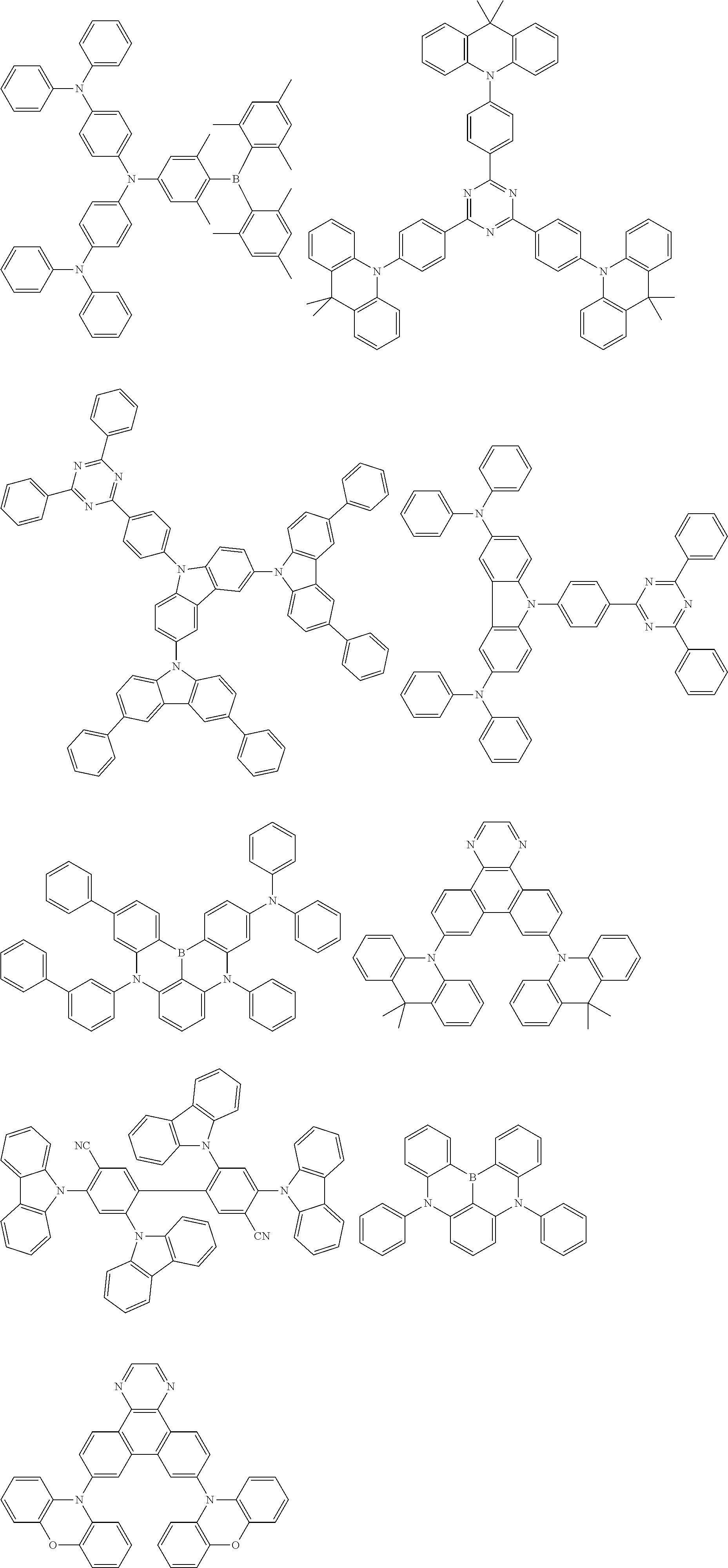

### 4. EIM/ETM

Examples of EIM/ETM materials are not particularly limited, and any metal complex or organic compound may be used as EIM/ETM as long as they can transfer electrons. Preferred organic EIM/ETM materials may be selected from the group consisting of tris(8-quinolinolato) aluminum (AlQ3), phenazine, phenanthroline, anthracene, phenanthrene, fluorene, bifluorene, spiro-bifluorene, p-phenylacetylene, pyridazine, pyrazine, triazine, triazole, imidazole, quinoline, isoquinoline, quinazoline, oxazole, isoxazole, oxadiazole, thiadiazole, pyridine, pyrazole, pyrrole, pyrimidine, acridine, pyrene, perylene, trans-indenofluorene, cis-indenonfluorene, dibenzol-indenofluorene, indenonaphthalene, benzanthracene, azaphosphole, azaborole, aromatic ketones, lactams, and derivatives thereof.

The hole-blocking layer (HBL) is typically used to block holes from the adjacent functional layers, particularly the light-emitting layers. In contrast to a light-emitting device without a blocking layer, the presence of HBL usually results in an increase in luminescence efficiency. The hole-blocking material (HBM) of the hole-blocking layer (HBL) requires a lower HOMO than the adjacent functional layer, such as the light-emitting layer. In some embodiments, the HBM has a greater energy level of excited state than the adjacent light-emitting layer, such as a singlet or triplet energy level, depending on the emitter. In some embodiments, the HBM has an electron-transport function. Typically, EIMs/ETMs with deep HOMO energy levels may be used as HBMs.

In one aspect, the compounds used as EIM/ETM/HBM may comprise at least one of the following groups.

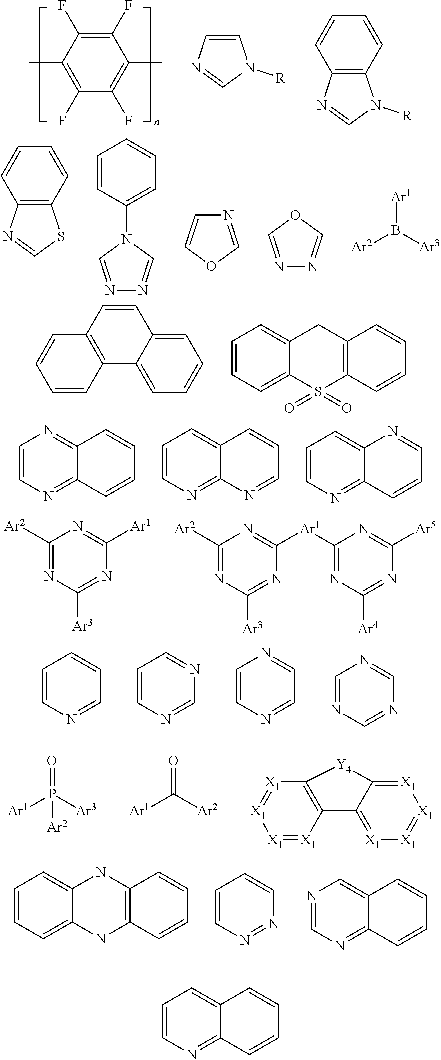

Where Y₄ at each occurrence is independently selected from C(R)₂, NR, O, or S; X₁ at each occurrence is independently selected from CR or N; each of Ar¹ to Ar⁵ at each occurrence is independently selected from an aryl group or a heteroaryl group; R at each occurrence is independently selected from: hydrogen, deuterium, halogen atoms (F, Cl, Br, I), cyano, alkyl, alkoxy, amino, alkenyl, alkynyl, aralkyl, heteroalkyl, aryl, or heteroaryl; n₆ is an integer from 1 to 20.

In another aspect, examples of metal complexes those may be used as EIM/ETM include, but not limited to, the general structures as follows:

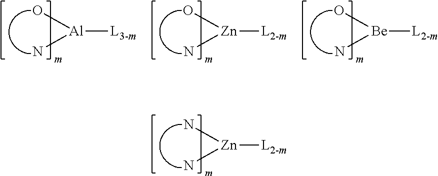

(O—N) or (N—N) is a bidentate ligand in which the metal is coordinated to O, N, or N, N; L is an auxiliary ligand; m is an integer from 1 to the maximum coordination number of the metal.

Suitable examples of EIM/ETM/HBM compounds are listed below:

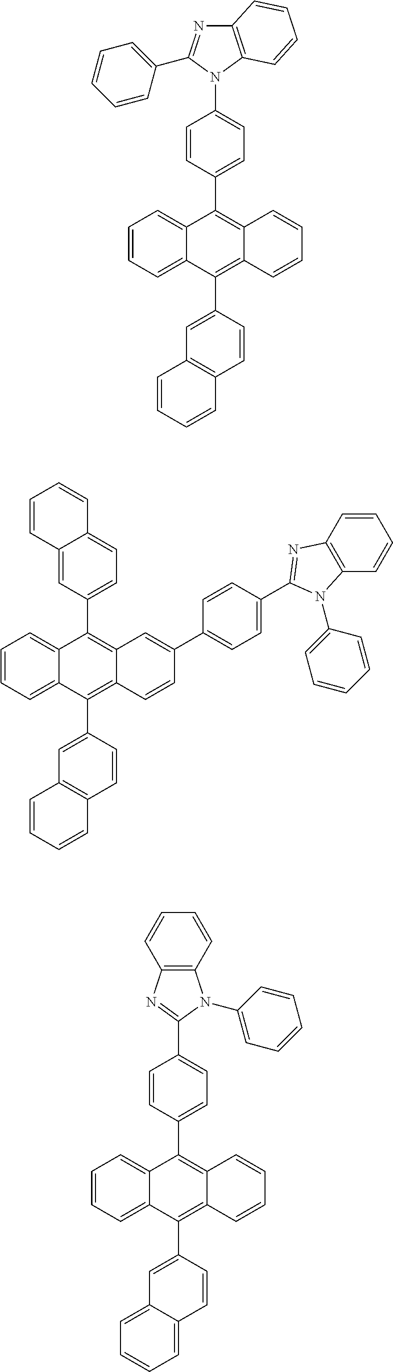 [SMILES: c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-n2c(-c3ccc(-c4c5ccccc5c(-c5ccc6ccccc6c5)c5ccccc45)cc3)nc3ccccc32)cc1]

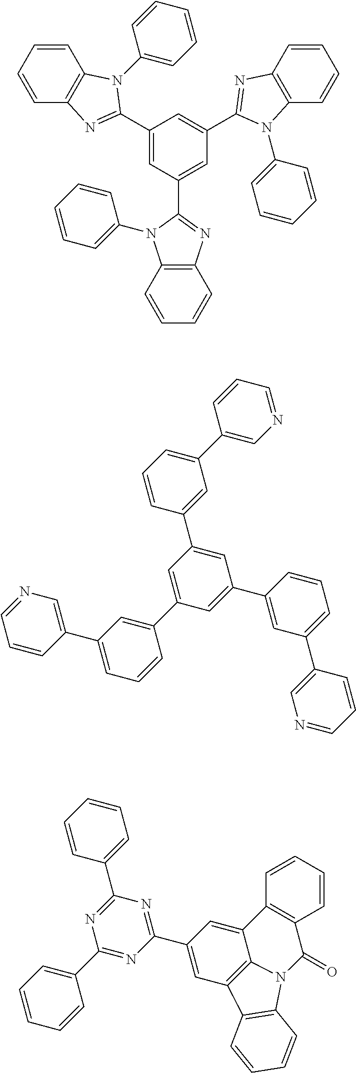 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1cncc(-c2cccc(-c3cc(-c4cccc(-c5cccnc5)c4)cc(-c4cccc(-c5cccnc5)c4)c3)c2)c1 ; O=c1c2ccccc2c2cc(-c3nc(-c4ccccc4)nc(-c4ccccc4)n3)cc3c4ccccc4n1c23]

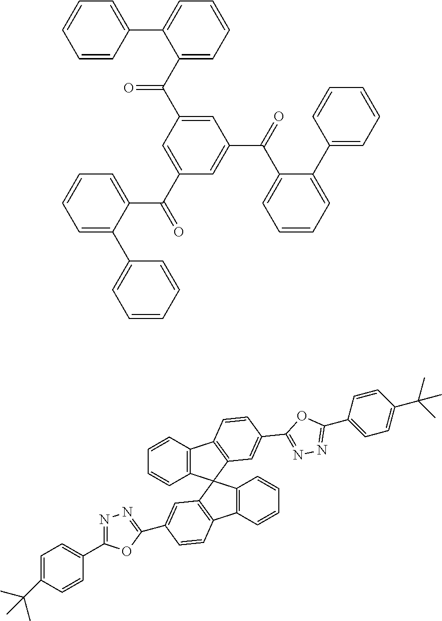 [SMILES: O=C(c1cc(C(=O)c2ccccc2-c2ccccc2)cc(C(=O)c2ccccc2-c2ccccc2)c1)c1ccccc1-c1ccccc1 ; CC(C)(C)c1ccc(-c2nnc(-c3ccc4c(c3)C3(c5ccccc5-4)c4ccccc4-c4ccc(-c5nnc(-c6ccc(C(C)(C)C)cc6)o5)cc43)o2)cc1]

In some embodiments, an organic alkali metal compound may be used as an EIM. As used herein, the organic alkali metal compound is understood to be a compound comprising at least one alkali metal (i.e., Li, Na, K, Rb, Cs) and further comprising at least one organic ligand.

The organic alkali metal compound is preferably selected from the group consisting of:

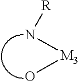

Where R is identically defined as described herein; the arc represents two or three atoms and the bonds, so as to form a five- or six-membered ring with the metal M₃ when necessary, where the atoms may also be substituted with one or more Rs, and M₃ is an alkali metal selected from Li, Na, K, Rb, or Cs.

The organic alkali metal compounds may be in the form of monomers, or aggregates according to the above-mentioned, e.g., two alkali metal ions and two ligands, four alkali metal ions and four ligands, six alkali metal ions and six ligands, or other forms.

Preferred organic alkali metal compounds are compounds of the following formulas:

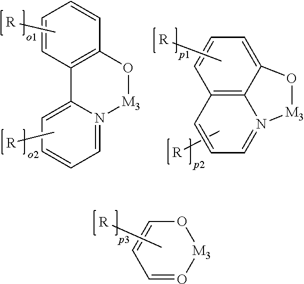

Where the symbols are identically defined as described herein, in addition:
o1 and o2 are the same or different, and at each occurrence are integers from 0 to 4;
p1, p2, and p3 are the same or different, and at each occurrence are integers from 0 to 3.

In some embodiments, each alkali metal M₃ is independently selected from Li, Na, or K, preferably selected from Li or Na, and most preferably selected from Li.

In some embodiments, the electron-injection layer comprises an organic alkali metal compound. More preferably, the electron-injection layer is composed of the organic alkali metal compounds.

In some embodiments, the organic alkali metal compound is doped into the other ETM to form an electron-transport layer or an electron-injection layer, better to form an electron-transport layer.

Suitable examples of organic alkali metal compounds are listed below:

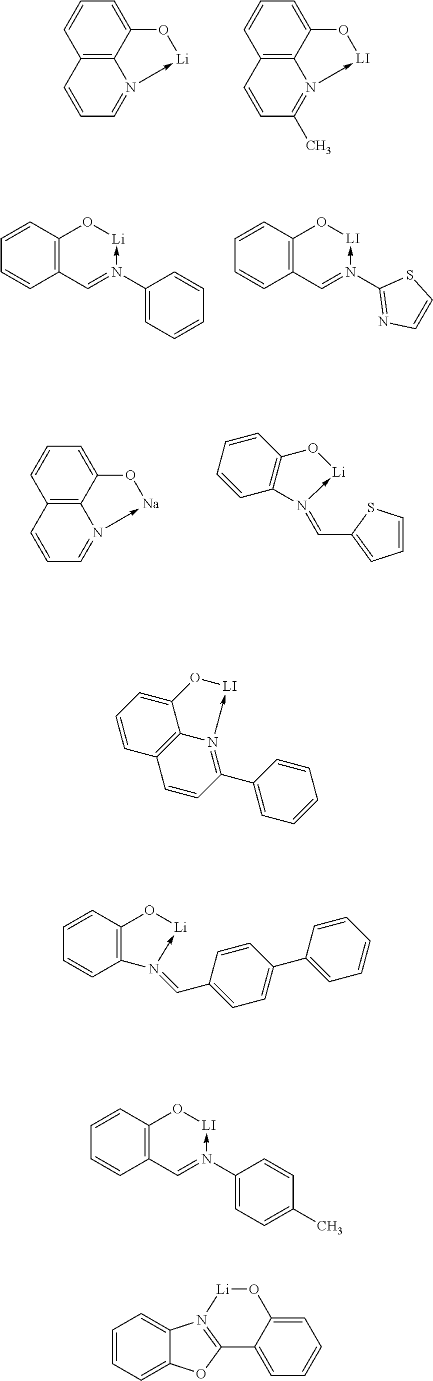

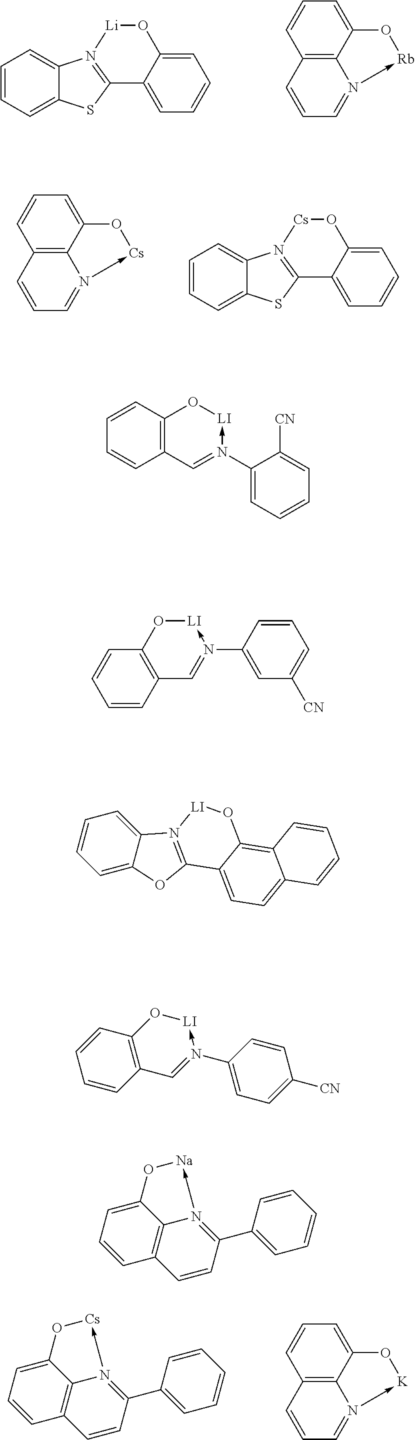

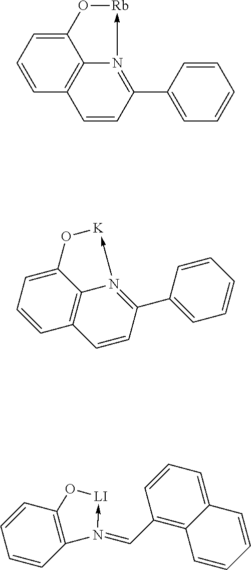

In yet another aspect, the present disclosure further provides a formulation comprising at least one compound of formula (I) or polymer or mixture as described herein, and at least one organic solvent; the at least one organic solvent is selected from aromatic, heteroaromatic, ester, aromatic ketone, aromatic ether, aliphatic ketone, aliphatic ether, cycloaliphatic, alicyclic or olefin compounds, borate, phosphorate, or mixtures of two or more of them.

In some embodiments, the at least one organic solvent of the formulation is an aromatic or heteroaromatic-based solvent.

Examples of aromatic-based or heteroaromatic-based solvents suitable for the present disclosure include, but not limited to: diisopropylbenzene, phenylpentane, tetraline, cyclohexylbenzene, 1-chloronaphthalene, 1,4-dimethylnaphthalene, 3-isopropylbiphenyl,
p-methyl cumene, dipentylbenzene, tripentylbenzene, pentyltoluene, 1,2-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, cyclohexylbenzene, benzylbutylbenzene, dimethylnaphthalene, 3-isopropylbiphenyl, 1-methylnaphthalene, 1,2,4-trichlorobenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl) ethane, 2-isopropylnaphthalene, quinoline, isoquinoline, methyl 2-furoate, ethyl 2-furoate, etc.

Examples of aromatic ketone-based solvents suitable for the present disclosure include, but not limited to: 1-tetrahydronaphthalone, 2-tetrahydronaphthalone, 2-(phenylepoxy)tetrahydronaphthalone, 6-(methoxy)tetrahydronaphthalone, acetophenone,
propiophenone, benzophenone, and derivatives thereof such as 4-methylacetophenone,
3-methylacetophenone, 2-methylacetophenone, 4-methylphenylacetone, 3-methylphenylacetone, 2-methylphenylacetone, etc.

Examples of aromatic ether-based solvents suitable for the present disclosure include, but not limited to: 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-anethole, 1,2-dimethoxybenzene, 1-methoxynaphthalene, diphenyl ether, 2-phenoxymethyl ether, 2-phenoxytetrahydrofuran, ethyl-2-naphthyl ether.

In some embodiments, in the formulation as described herein, the at least one organic solvent can be selected from aliphatic ketones, such as, 2-nonanone, 3-nonanone, 5-nonanone, 2-decanone, 2,5-hexanedione, 2,6,8-trimethyl-4-nonanone, fenchone, phoron, isophorone, di-n-amyl ketone, etc; and the at least one organic solvent as described herein can be selected from aliphatic ethers, such as, dipentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc.

In some embodiments, in the formulation as described herein, the at least one organic solvent can be selected from: ester-based solvents including alkyl octanoate, alkyl sebacate, alkyl stearate, alkyl benzoate, alkyl phenylacetate, alkyl cinnamate, alkyl oxalate, alkyl maleate, alkyl lactone, alkyl oleate, etc. Particularly preferred are octyl octanoate, diethyl sebacate, diallyl phthalate and isononyl isononanoate.

The organic solvent may be used alone or as mixtures of two or more organic solvents.

In some embodiments, in the formulation as described herein, the at least one organic solvent include, but not limited to: methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetraline, decalin, indene, and/or any combination thereof.

In some embodiments, the particularly suitable solvent for the present disclosure is a solvent having Hansen solubility parameters in the following ranges:

δ_{d} (dispersion force) is in the range of 17.0 MPa^{1/2} to 23.2 MPa^{1/2}, especially in the range of 18.5 MPa^{1/2} to 21.0 MPa^{1/2}.

δₚ (polarity force) is in the range of 0.2 MPa^{1/2} to 12.5 MPa^{1/2}, especially in the range of 2.0 MPa^{1/2} to 6.0 MPa^{1/2}.

δₕ (hydrogen bonding force) is in the range of 0.9 MPa^{1/2} to 14.2 MPa^{1/2}, especially in the range of 2.0 MPa^{1/2} to 6.0 MPa^{1/2}.

In the formulation as described herein, the boiling point parameter should be taken into account when selecting the organic solvents. In the present disclosure, the boiling points of the organic solvents ≥150° C.; preferably ≥180° C.; more preferably ≥200° C.; further preferably ≥250° C.; and most preferably ≥275° C. or ≥300° C. The boiling points in these ranges are beneficial in terms for preventing nozzle clogging of the inkjet printhead. The organic solvent can be evaporated from solution system to form a functional film.

In some embodiments, the formulation as described herein is a solution.

In some embodiments, the formulation as described herein is a dispersion.

The formulation in the embodiments of the present disclosure may comprise the compound of formula (I) or the polymer or the mixture of 0.01 wt % to 15 wt %, preferably 0.1 wt % to 10 wt %, more preferably 0.2 wt % to 5 wt %, and most preferably 0.25 wt % to 3 wt %.

The present disclosure further provides the use of the formulation as coatings or printing inks in the preparation of organic electronic devices, particularly preferably by printing or coating processing methods.

Where suitable printing or coating techniques include, but not limited to, gravure printing, ink-jet printing, nozzle printing, typographic printing, screen printing, dip coating, spin coating, blade coating, roller printing, torsion roll printing, planographic printing, flexographic printing, rotary printing, spray coating, brush coating, pad printing, slit die coating, and so on. Preferred techniques are gravure printing, nozzle printing, and ink-jet printing. The solution or dispersion may additionally comprise one or more components, such as surface active compounds, lubricants, wetting agents, dispersing agents, hydrophobic agents, binders, etc., which are used to adjust the viscosity and film forming properties, or to improve adhesion, etc. For more information about printing technologies and their requirements for solutions, such as solvent, concentration, and viscosity, and the like, please refer to Handbook of Print Media: Technologies and Production Methods, edited by Helmut Kipphan, ISBN 3-540-67326-1.

The emission wavelength of the organic electroluminescent device as described herein is between 300 nm and 1200 nm, preferably between 350 nm and 1000 nm, more preferably between 400 nm and 900 nm.

The present disclosure further provides the applications of organic electroluminescent devices in various electronic equipment, including, but not limited to, display devices, lighting equipment, light sources, sensors, etc.

In yet another aspect, the present disclosure further provides an organic compound comprising a structure of formula (I), where R₁₁ and R₁₂ are each independently selected from a substituted/unsubstituted C₆-C₆₀ aryl group or a substituted/unsubstituted C₅-C₆₀ heteroaryl group, and at least one of R₁₁ or R₁₂ comprises an electron-withdrawing group.

In some embodiments, R₁₁ and R₁₂ are each independently selected from a substituted/unsubstituted C₆-C₅₀ aryl group or a substituted/unsubstituted C₅-C₅₀ heteroaryl group. In some embodiments, R₁₁ and R₁₂ are each independently selected from a substituted/unsubstituted C₆-C₄₀ aryl group or a substituted/unsubstituted C₅-C₄₀ heteroaryl group. In some embodiments, R₁₁ and R₁₂ are each independently selected from a substituted/unsubstituted C₆-C₃₀ aryl group or a substituted/unsubstituted C₅-C₃₀ heteroaryl group. In some embodiments, R₁₁ and R₁₂ are each independently selected from a substituted/unsubstituted C₆-C₂₀ aryl group or a substituted/unsubstituted C₅-C₂₀ heteroaryl group.

In some embodiments, the electron-withdrawing groups contained in R₁₁ and R₁₂ are each independently selected from F, a cyano group, or one of the following groups:

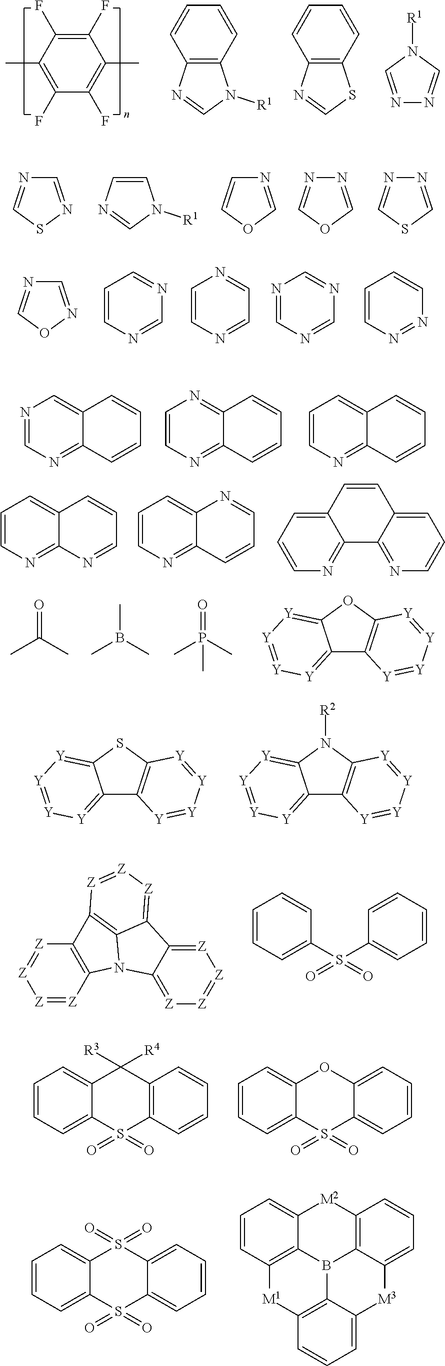

Where the symbols are identically defined as described herein.

In yet another aspect, the present disclosure further provides an application of a polymer or a mixture or a formulation or an organic compound as described herein in organic electronic devices, the organic electronic device may be selected from, but not limited to, an organic light-emitting diode (OLED), an organic photovoltaic cell (OPV), an organic light emitting electrochemical cell (OLEEC), an organic field effect transistor (OFET), an organic light emitting field effect transistor, an organic laser, an organic spintronic electronic device, a photodiode, an organic sensor, an organic plasmon emitting diode (OPED), etc., particularly preferably is an OLED. In the embodiments as described herein, it is preferred to use the organic compound for the electron-transport layer/hole-blocking layer of the OLED.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### Specific Embodiment

### 1. Synthesis of Compounds

### Synthesis of Compound 1

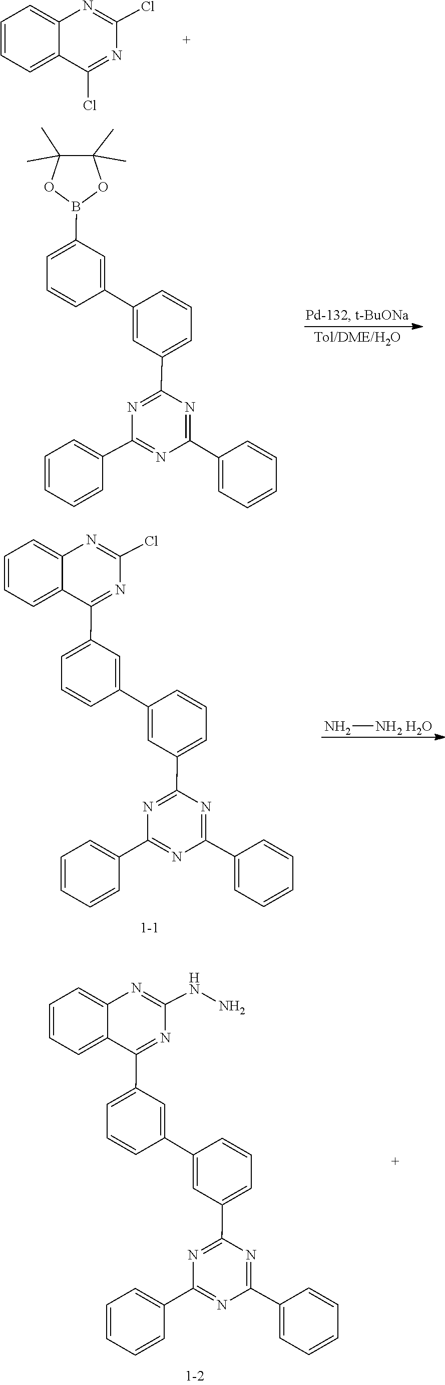

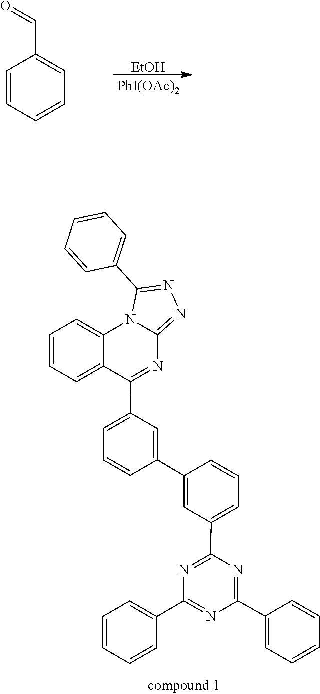 [SMILES: "EtOH" ; "PhI(OAc)2" ; O=Cc1ccccc1 ; c1ccc(-c2nc(-c3ccccc3)nc(-c3cccc(-c4cccc(-c5nc6nnc(-c7ccccc7)n6c6ccccc56)c4)c3)n2)cc1]

2,4-Dichloroquinazoline (6.0 g, 30 mmol), 2,4-diphenyl-6-(3-biphenyl-3-boronic acid pinacol ester)-1,3,5-triazine (16.1 g, 31.5 mmol), Pd-132 (1.6 g, 2.3 mmol), sodium tert-butoxide (7.21 g, 75 mmol) and S-Phos (1.28 g, 3 mmol) were added to a 500 mL three-necked flask, then 240 mL of a mixed solvent (toluene:1,2-dimethoxyethane:water=120 mL:60 mL:60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was recrystallized with N,N-dimethylformamide to yield about 9.2 g (yield: about 56%) of compound 1-1 (white solid). MS(ASAP)=548.1.

Compound 1-1 (8.8 g, 16 mmol) was dissolved in 500 mL of ethanol, hydrazine hydrate (3 g, 48 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 8.0 g (yield: about 92%) of compound 1-2 (off-white solid). MS(ASAP)=543.6.

Compound 1-2 (7.6 g, 14 mmol) was added to a flask with 500 mL of ethanol inside, then benzaldehyde (1.7 g, 15.4 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 4.5 g (yield: about 51%) of compound 1 (pale yellow solid). MS(ASAP)=629.7.

### Synthesis of Compound 2

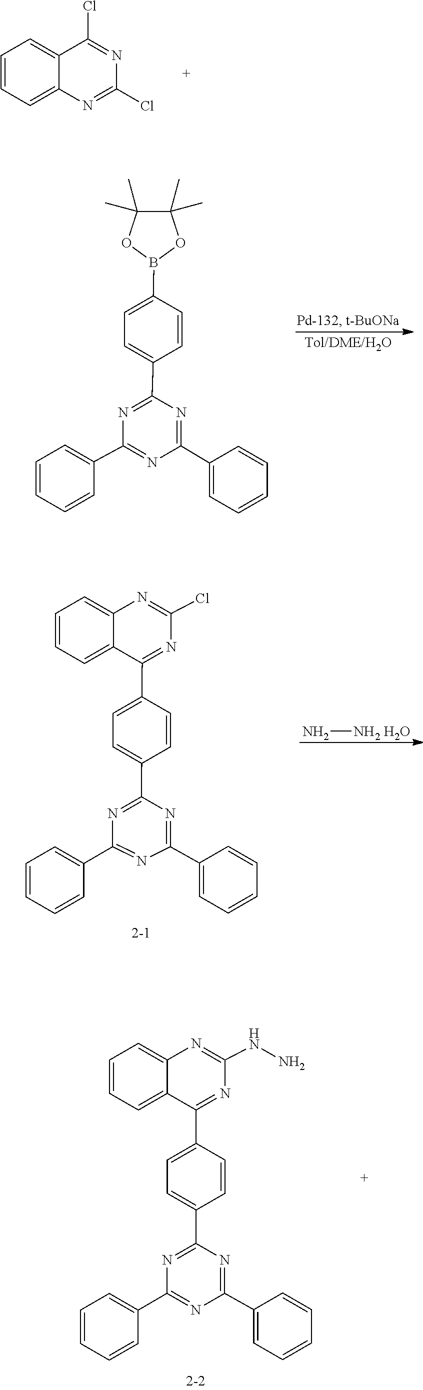

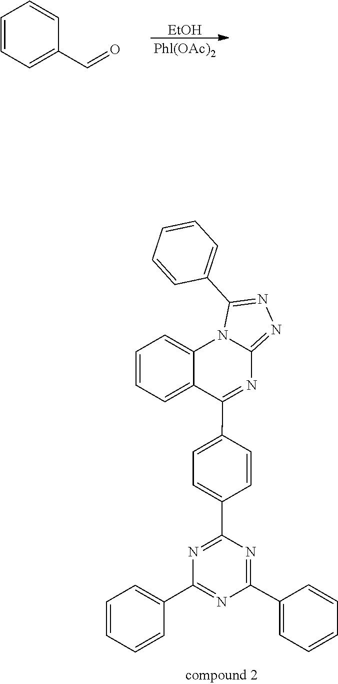 [SMILES: "EtOH" ; O=Cc1ccccc1 ; c1ccc(-c2nc(-c3ccccc3)nc(-c3ccc(-c4nc5nnc(-c6ccccc6)n5c5ccccc45)cc3)n2)cc1]

2,4-Dichloroquinazoline (6.0 g, 30 mmol), 2,4-diphenyl-6-(3-phenyl-3-boronic acid pinacol ester)-1,3,5-triazine (13.7 g, 31.5 mmol), Pd-132 (1.6 g, 2.3 mmol), sodium tert-butoxide (7.21 g, 75 mmol) and S-Phos (1.28 g, 3 mmol) were added to a 500 mL three-necked flask, then 240 mL of a mixed solvent (toluene: 1,2-dimethoxyethane:water=120 mL: 60 mL: 60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was recrystallized with N,N-dimethylformamide to yield about 8.9 g (yield: about 63%) of compound 2-1 (white solid). MS(ASAP)=472.0.

Compound 2-1 (7.6 g, 16 mmol) was dissolved in 500 mL of ethanol, hydrazine hydrate (3 g, 48 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 6.4 g (yield: about 86%) of compound 2-2 (off-white solid). MS(ASAP)=467.5.

Compound 2-2 (5.6 g, 12 mmol) was added to a flask with 500 mL of ethanol inside, then benzaldehyde (1.4 g, 13.2 mmol) was added dropwise to the above mixture with stirring at room temperature. After 30 min, (diacetoxyiodo)benzene (4.2 g, 13.2 mmol) was added in batches, and the mixture was reacted for another 1.5 h. The precipitates formed during the reaction was filtrated, and washed with n-hexane. The dried crude product was further washed with a large amount of ethanol to yield about 4.1 g (yield: about 61%) of compound 2 (white solid). MS(ASAP)=553.6.

### Synthesis of Compound 3

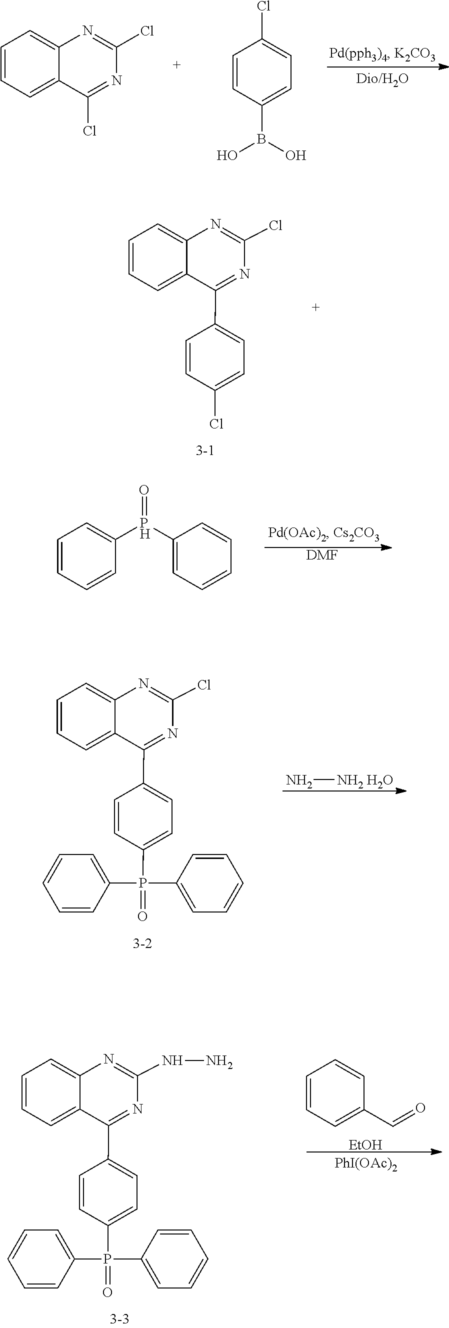

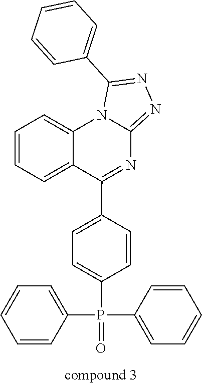 [SMILES: O=P(c1ccccc1)(c1ccccc1)c1ccc(-c2nc3nnc(-c4ccccc4)n3c3ccccc23)cc1]

2,4-Dichloroquinazoline (12.0 g, 60 mmol), 4-chlorophenylboronic acid (9.9 g, 63 mmol), tetrakis(triphenylphosphine) palladium (0.7 g, 0.6 mmol) and potassium carbonate (12.4 g, 90 mmol) were added to a 500 mL three-necked flask, then 240 mL of a mixed solvent (1,4-dioxane:water=180 mL: 60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was further purified by column chromatography (eluent: dichloromethane:petroleum ether=1:1) to yield about 14.5 g (yield: about 88%) of compound 3-1 (white solid). MS(ASAP)=275.1.

Compound 3-1 (13.8 g, 50 mmol), diphenylphosphine oxide (12.1 g, 60 mmol), palladium acetate (110 mg, 0.5 mmol) and cesium carbonate (24.4 g, 75 mmol) were added to a 500 mL three-necked flask, then 200 mL of DMF was added to dissolve the above mixture. After repeating evacuate-refill cycle three times, the mixture was reacted at reflux for 20 h. After cooling down to room temperature, the solvent and the excess diphenylphosphine oxide were removed by rotary evaporation, the obtained crude product was recrystallized in ethanol to yield about 15.4 g (yield: about 71%) of compound 3-2 (white solid). MS(ASAP)=440.9.

Compound 3-2 (7.1 g, 16 mmol) was dissolved in 500 mL of ethanol, hydrazine hydrate (3 g, 48 mmol, 80% aqueous solution) was added dropwise into the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 6.3 g (yield: about 90%) of compound 3-3 (off-white solid). MS(ASAP)=436.4.

Compound 3-3 (5.2 g, 12 mmol) was added to a flask with 500 mL of ethanol inside, then benzaldehyde (1.4 g, 13.2 mmol) was added dropwise to the above mixture with stirring at room temperature. After 30 min, (diacetoxyiodo)benzene (4.2 g, 13.2 mmol) was added in batches, and the mixture was reacted for another 1.5 h. The precipitates formed during the reaction was filtrated, and washed with n-hexane. The dried crude product was further washed with a large amount of ethanol to yield about 4 g (yield: about 64%) of compound 3 (white solid). MS(ASAP)=522.6.

### Synthesis of Compound 4

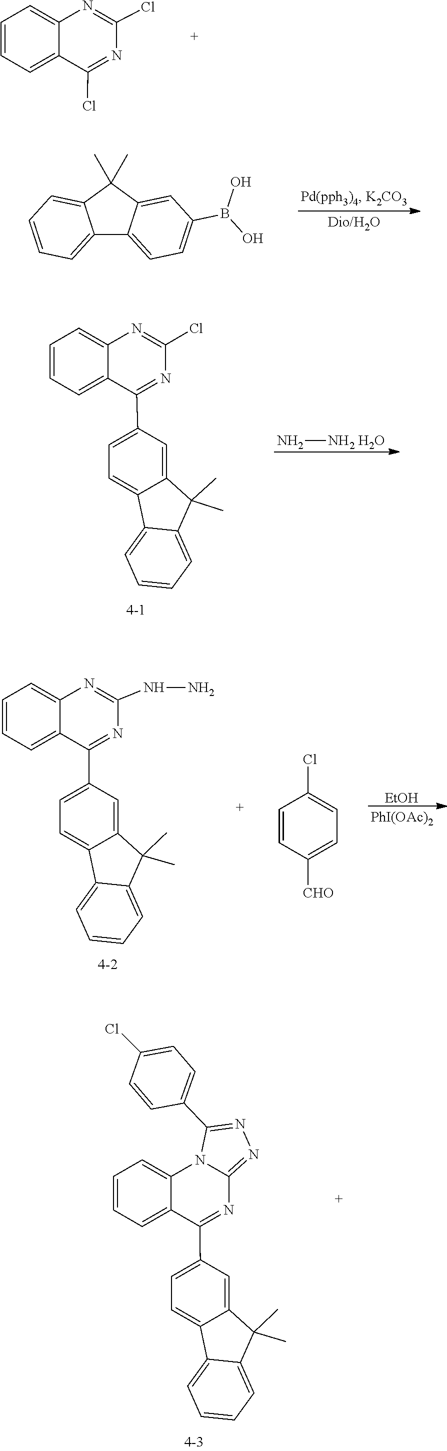

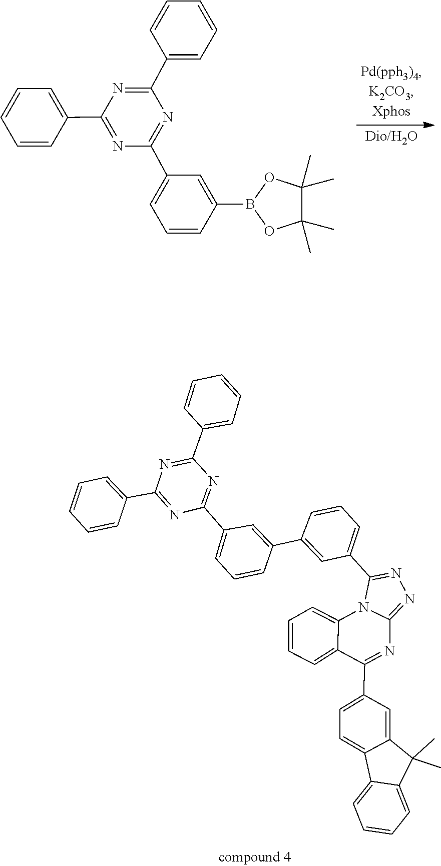 [SMILES: CC1(C)OB(c2cccc(-c3nc(-c4ccccc4)nc(-c4ccccc4)n3)c2)OC1(C)C ; CC1(C)c2ccccc2-c2ccc(-c3nc4nnc(-c5cccc(-c6cccc(-c7nc(-c8ccccc8)nc(-c8ccccc8)n7)c6)c5)n4c4ccccc34)cc21]

2,4-Dichloroquinazoline (12.0 g, 60 mmol), 9,9-dimethylfluorene-2-boronic acid (15.0 g, 63 mmol), tetrakis(triphenylphosphine) palladium (0.7 g, 0.6 mmol) and potassium carbonate (12.4 g, 90 mmol) were added to a 500 mL three-necked flask, then 240 mL of a mixed solvent (1,4-dioxane:water=180 mL:60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was further purified by column chromatography (eluent: dichloromethane:petroleum ether=1:3) to yield about 18 g (yield: about 84%) of compound 4-1 (white solid). MS(ASAP)=356.9.

Compound 4-1 (11.4 g, 32 mmol) was dissolved in 800 mL of ethanol, hydrazine hydrate (6 g, 96 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 9.9 g (yield: about 88%) of compound 4-2 (off-white solid). MS(ASAP)=352.4.

Compound 4-2 (8.5 g, 24 mmol) was added to a flask with 600 mL of ethanol inside, then 4-chlorobenzaldehyde (3.7 g, 26.4 mmol) was added dropwise to the above mixture with stirring at room temperature. After 30 min, (diacetoxyiodo)benzene (8.4 g, 26.4 mmol) was added in batches, and the mixture was reacted for another 1.5 h. The precipitates formed during the reaction was filtrated, and washed with n-hexane. The dried crude product was further washed with a large amount of ethanol to yield about 8.1 g (yield: about 71%) of compound 4-3 (white solid). MS(ASAP)=473.

Compound 4-3 (4.7 g, 10 mmol), 2,4-diphenyl-6-(2-phenyl-3-boronic acid pinacol ester)-1,3,5-triazine (4.6 g, 10.5 mmol), tetrakis(triphenylphosphine) palladium (116 mg, 0.1 mmol), Xphos (95 mg, 0.2 mmol) and potassium carbonate (20.7 g, 15 mmol) were added to a 100 mL three-necked flask, then 40 mL of a mixed solvent (1,4-dioxane:water=30 mL: 10 mL) was added to the above mixture. After repeating evacuate-refill cycle three times, the mixture was reacted at reflux for 20 h. After cooling down to room temperature, the mixture was extracted with 50 mL of dichloromethane. After the separation, the excess organic solvent was removed, the obtained crude product was further purified by column chromatography (eluent: dichloromethane:petroleum ether=1:1) to yield about 4.3 g (yield: about 57%) of compound 4 (white solid). MS(ASAP)=745.9.

### Synthesis of Compound 5

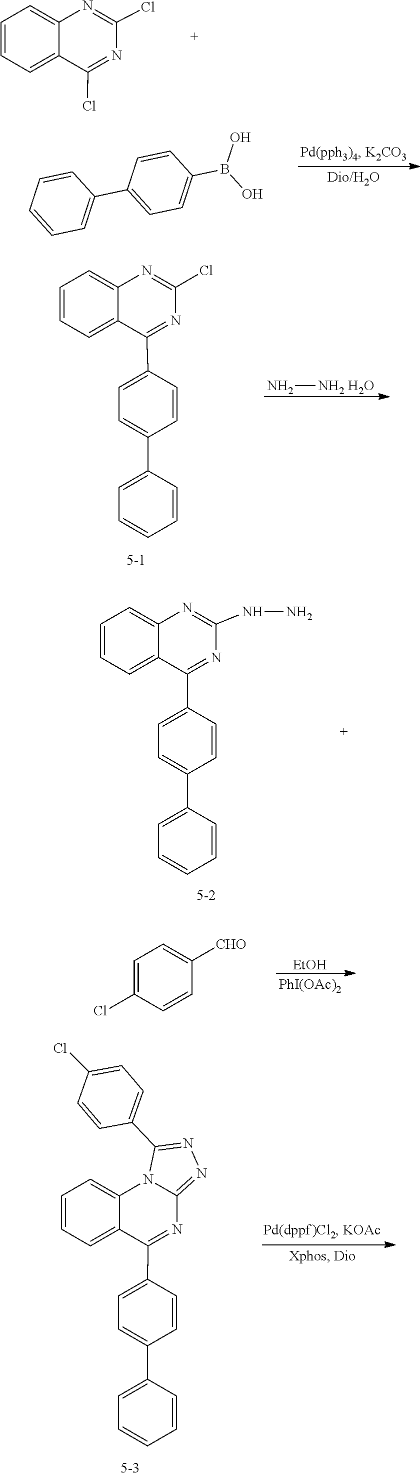

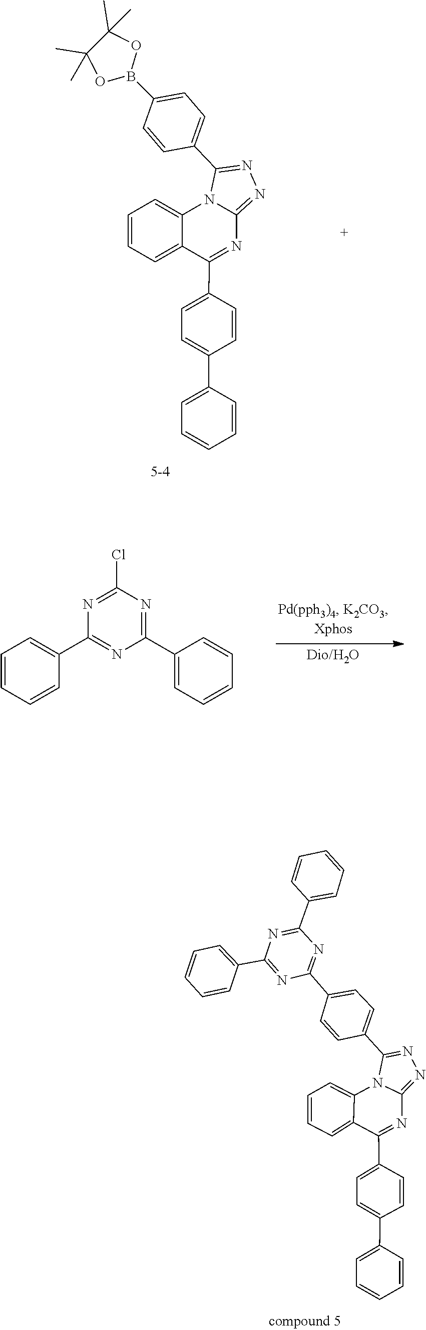 [SMILES: CC1(C)OB(c2ccc(-c3nnc4nc(-c5ccc(-c6ccccc6)cc5)c5ccccc5n34)cc2)OC1(C)C ; Clc1nc(-c2ccccc2)nc(-c2ccccc2)n1 ; c1ccc(-c2ccc(-c3nc4nnc(-c5ccc(-c6nc(-c7ccccc7)nc(-c7ccccc7)n6)cc5)n4c4ccccc34)cc2)cc1]

2,4-Dichloroquinazoline (12.0 g, 60 mmol), 4-biphenylboronic acid (12.5 g, 63 mmol), tetrakis(triphenylphosphine) palladium (0.7 g, 0.6 mmol) and potassium carbonate (12.4 g, 90 mmol) were added to a 500 mL three-necked flask, then 240 mL of a mixed solvent (1,4-dioxane:water=180 mL:60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was further purified by column chromatography (eluent: dichloromethane:petroleum ether=1:3) to yield about 17.1 g (yield: about 90%) of compound 5-1 (white solid). MS(ASAP)=316.8.

Compound 5-1 (10.1 g, 32 mmol) was dissolved in 800 mL of ethanol, hydrazine hydrate (6 g, 96 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 8.7 g (yield: about 87%) of compound 5-2 (off-white solid). MS(ASAP)=312.4.

Compound 5-2 (7.5 g, 24 mmol) was added to a flask with 600 mL of ethanol inside, then 4-chlorobenzaldehyde (3.7 g, 26.4 mmol) was added dropwise to the above mixture with stirring at room temperature. After 30 min, (diacetoxyiodo)benzene (8.4 g, 26.4 mmol) was added in batches, and the mixture was reacted for another 1.5 h. The precipitates formed during the reaction was filtrated, and washed with n-hexane. The dried crude product was further washed with a large amount of ethanol to yield about 6.9 g (yield: about 66%) of compound 5-3 (white solid). MS(ASAP)=432.9.

Compound 5-3 (6.5 g, 15 mmol), bis(pinacolato)diboron (4.2 g, 16.5 mmol), [1,1′-bis(diphenylphosphino)ferrocene]dichloropalladium (11 mg, 0.015 mmol), Xphos (14 mg, 0.03 mmol) and potassium carbonate (4.1 g, 30 mmol) were added to a 250 mL three-necked flask, then 120 mL of a mixed solvent (1,4-dioxane:water=90 mL:30 mL) was added to the above mixture. After repeating evacuate-refill cycle three times, the mixture was reacted at reflux for 20 h. After cooling down to room temperature, the mixture was extracted with 100 mL of dichloromethane. After the separation, the excess organic solvent was removed, the obtained crude product was further purified by column chromatography (eluent: dichloromethane:petroleum ether=1:2) to yield about 7.2 g (yield: about 92%) of compound 5-4 (white solid). MS(ASAP)=524.4.

Compound 5-4 (5.2 g, 10 mmol), 2-chloro-4,6-diphenyl-1,3,5-triazine (2.8 g, 10.5 mmol), tetrakis(triphenylphosphine) palladium (116 mg, 0.1 mmol), Xphos (95 mg, 0.2 mmol) and potassium carbonate (20.7 g, 15 mmol) were added to a 100 mL three-necked flask, then 40 mL of a mixed solvent (1,4-dioxane:water=30 mL:10 mL) was added to the above mixture. After repeating evacuate-refill cycle three times, the mixture was reacted at reflux for 20 h. After cooling down to room temperature, the mixture was extracted with 50 mL of dichloromethane. After the separation, the excess organic solvent was removed, the obtained crude product was further purified by column chromatography (eluent: dichloromethane:petroleum ether=1:1) to yield about 4.8 g (yield: about 76%) of compound 5 (white solid). MS(ASAP)=629.7.

### Synthesis of Compound 6

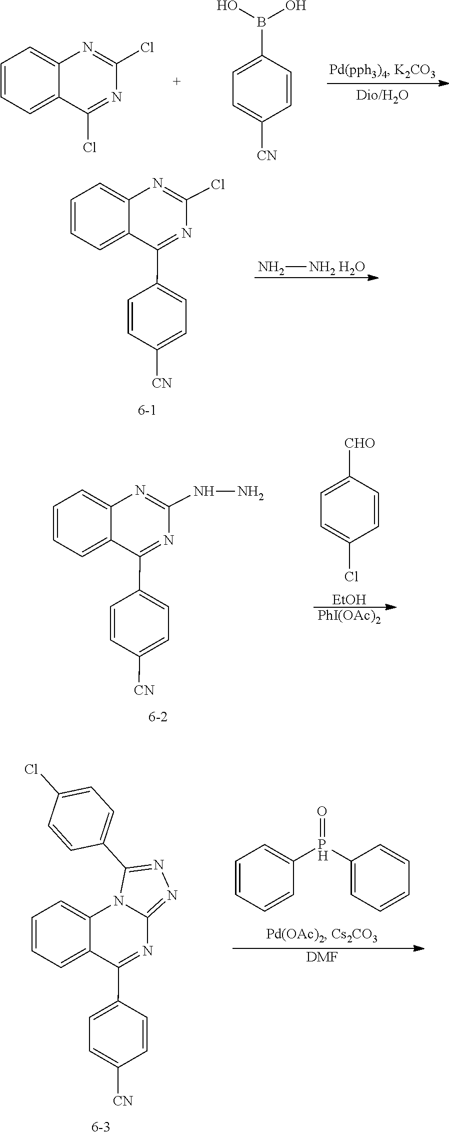

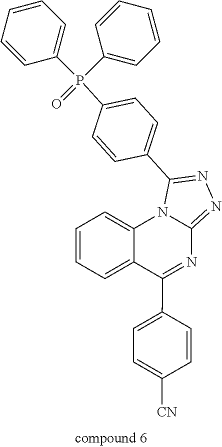 [SMILES: N#Cc1ccc(-c2nc3nnc(-c4ccc(P(=O)(c5ccccc5)c5ccccc5)cc4)n3c3ccccc23)cc1]

2,4-Dichloroquinazoline (12.0 g, 60 mmol), 4-cyanophenylboronic acid (9.3 g, 63 mmol), tetrakis(triphenylphosphine) palladium (0.7 g, 0.6 mmol) and potassium carbonate (12.4 g, 90 mmol) were added to a 500 mL three-necked flask, then 240 mL of a mixed solvent (1,4-dioxane:water=180 mL:60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was further purified by column chromatography (eluent: dichloromethane:petroleum ether=1:3) to yield about 14.3 g (yield: about 90%) of compound 6-1 (white solid). MS(ASAP)=265.7.

Compound 6-1 (8.5 g, 32 mmol) was dissolved in 800 mL of ethanol, hydrazine hydrate (6 g, 96 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 6.9 g (yield: about 82%) of compound 6-2 (off-white solid). MS(ASAP)=261.3.

Compound 6-2 (6.3 g, 24 mmol) was added to a flask with 600 mL of ethanol inside, then 4-chlorobenzaldehyde (3.7 g, 26.4 mmol) was added dropwise to the above mixture with stirring at room temperature. After 30 min, (diacetoxyiodo)benzene (8.4 g, 26.4 mmol) was added in batches, and the mixture was reacted for another 1.5 h. The precipitates formed during the reaction was filtrated, and washed with n-hexane. The dried crude product was further washed with a large amount of ethanol to yield about 5.6 g (yield: about 61%) of compound 6-3 (white solid). MS(ASAP)=381.8.

Compound 6-3 (3.8 g, 10 mmol), diphenylphosphine oxide (2.4 g, 12 mmol), palladium acetate (23 mg, 0.1 mmol) and cesium carbonate (4.9 g, 15 mmol) were added to a 100 mL three-necked flask, then 40 mL of DMF was added to dissolve the above mixture. After repeating evacuate-refill cycle three times, the mixture was reacted at reflux for 20 h. After cooling down to room temperature, the solvent and the excess diphenylphosphine oxide were removed by rotary evaporation, the obtained crude product was recrystallized in ethanol to yield about 4.7 g (yield: about 86%) of compound 6 (white solid). MS(ASAP)=547.6.

### Synthesis of Compound 7

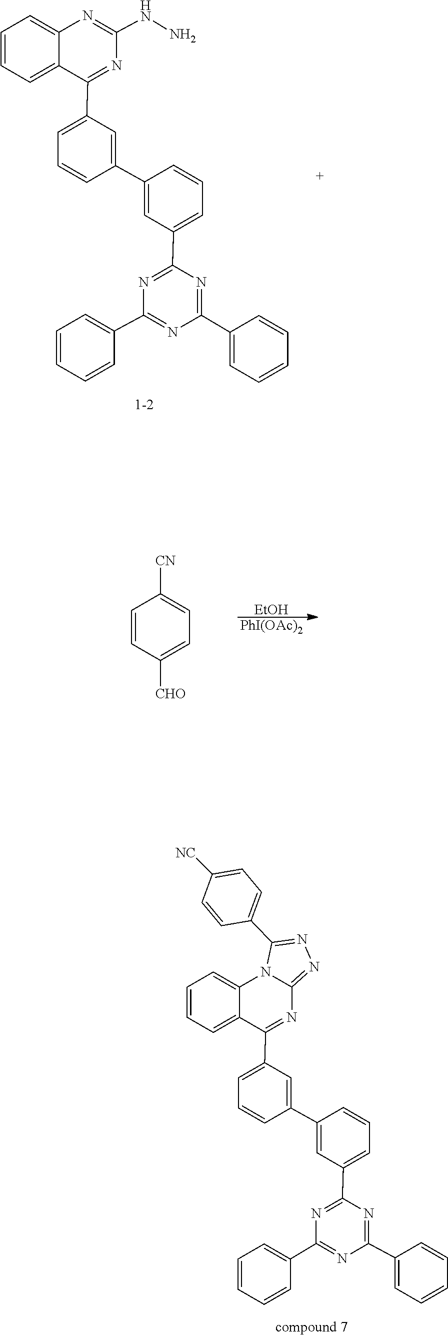 [SMILES: "EtOH" ; "PhI(OAc)2" ; NNc1nc(-c2cccc(-c3cccc(-c4nc(-c5ccccc5)nc(-c5ccccc5)n4)c3)c2)c2ccccc2n1 ; N#Cc1ccc(C=O)cc1 ; N#Cc1ccc(-c2nnc3nc(-c4cccc(-c5cccc(-c6nc(-c7ccccc7)nc(-c7ccccc7)n6)c5)c4)c4ccccc4n23)cc1]

Compound 1-2 (7.6 g, 14 mmol) was added to a flask with 500 mL of ethanol inside, then 4-cyanobenzaldehyde (2.0 g, 15.4 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 5.1 g (yield: about 56%) of compound 7 (pale yellow solid). MS(ASAP)=654.7.

### Synthesis of Compound 8

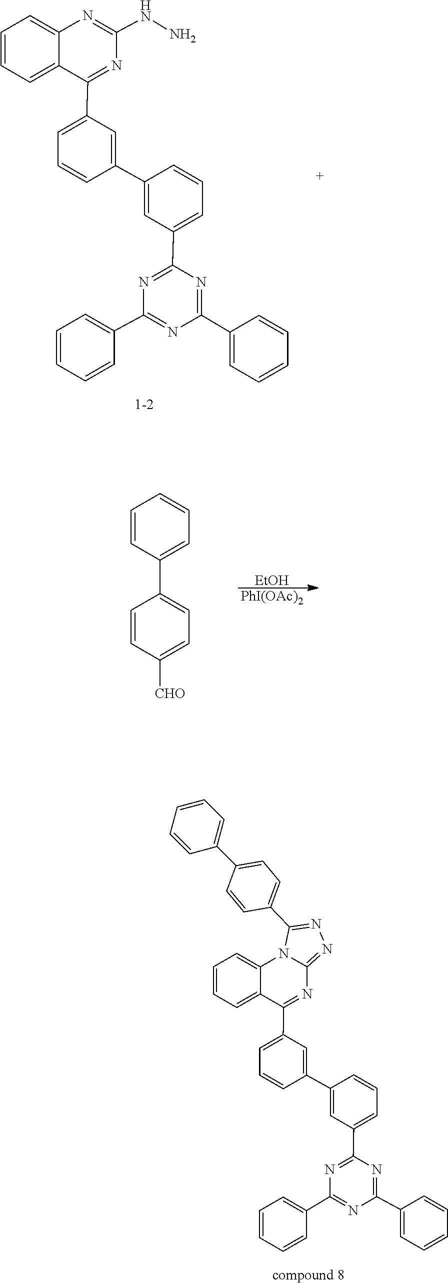 [SMILES: "EtOH" ; "PhI(OAc)2" ; NNc1nc(-c2cccc(-c3cccc(-c4nc(-c5ccccc5)nc(-c5ccccc5)n4)c3)c2)c2ccccc2n1 ; O=Cc1ccc(-c2ccccc2)cc1 ; c1ccc(-c2ccc(-c3nnc4nc(-c5cccc(-c6cccc(-c7nc(-c8ccccc8)nc(-c8ccccc8)n7)c6)c5)c5ccccc5n34)cc2)cc1]

Compound 1-2 (7.6 g, 14 mmol) was added to a flask with 500 mL of ethanol inside, then 4-biphenylcarboxaldehyde (2.8 g, 15.4 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 5.7 g (yield: about 58%) of compound 8 (pale yellow solid). MS(ASAP)=705.8.

### Synthesis of Compound 9

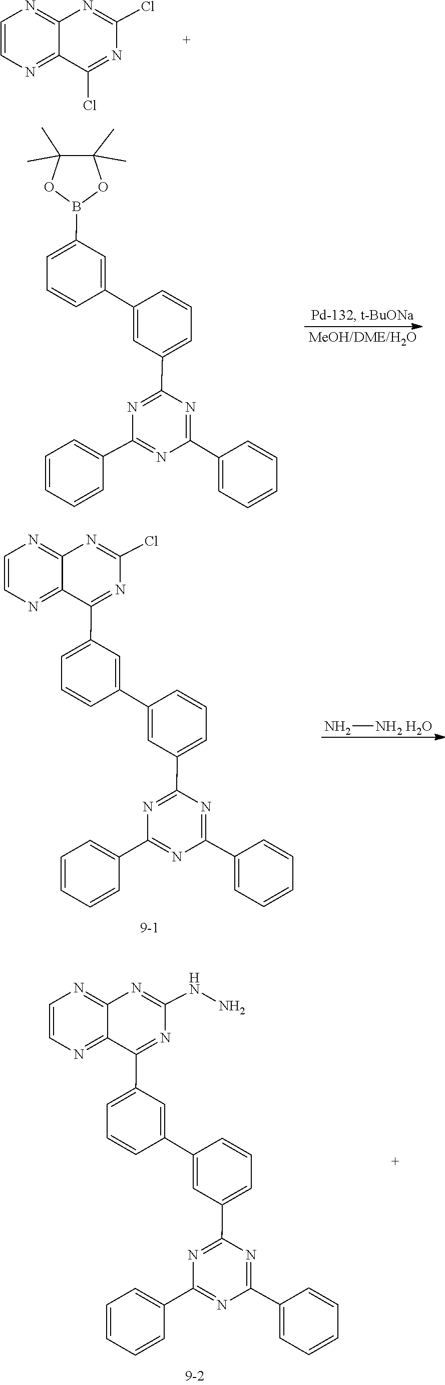

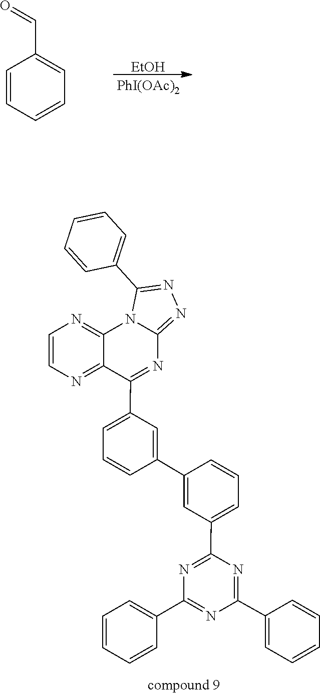 [SMILES: "EtOH" ; "PhI(OAc)2" ; O=Cc1ccccc1 ; c1ccc(-c2nc(-c3ccccc3)nc(-c3cccc(-c4cccc(-c5nc6nnc(-c7ccccc7)n6c6nccnc56)c4)c3)n2)cc1]

2,4-Dichloropteridine (6.0 g, 30 mmol), 2,4-diphenyl-6-(3-biphenyl-3-boronic acid pinacol ester)-1,3,5-triazine (16.1 g, 31.5 mmol), Pd-132 (1.6 g, 2.3 mmol), sodium tert-butoxide (7.21 g, 75 mmol) and S-Phos (1.28 g, 3 mmol) were added to a 500 mL three-necked flask, then 240 mL of a mixed solvent (toluene:1,2-dimethoxyethane:water=120 mL:60 mL:60 mL) was added to the above mixture. After repeating evacuate-refill cycle three times, the mixture was reacted at reflux for 20 h. After cooling down to room temperature, the mixture was extracted with 300 mL of dichloromethane. After the separation, the excess organic solvent was removed, the obtained crude product was recrystallized with N,N-dimethylformamide to yield about 9.2 g (yield: about 56%) of compound 9-1 (white solid). MS(ASAP)=550.0.

Compound 9-1 (8.8 g, 16 mmol) was dissolved in 500 mL of ethanol, hydrazine hydrate (3 g, 48 mmol, 80% aqueous solution) was added dropwise to the above mixture under stirring at 5° C., then the reaction temperature was kept below 10° C. during the addition. After the addition was completed, the resulting mixture was naturally heated to room temperature, reacted for 1 h. The precipitates formed during the reaction was filtrated, and washed with water and ethanol in sequence. The resulting sample was dried to yield about 8.0 g (yield: about 92%) of compound 9-2 (off-white solid). MS(ASAP)=545.6.

Compound 9-2 (7.6 g, 14 mmol) was added to a flask with 500 mL of ethanol inside, then benzaldehyde (1.7 g, 15.4 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 4.5 g (yield: about 51%) of compound 9 (pale yellow solid). MS(ASAP)-631.7.

### Synthesis of Compound 10

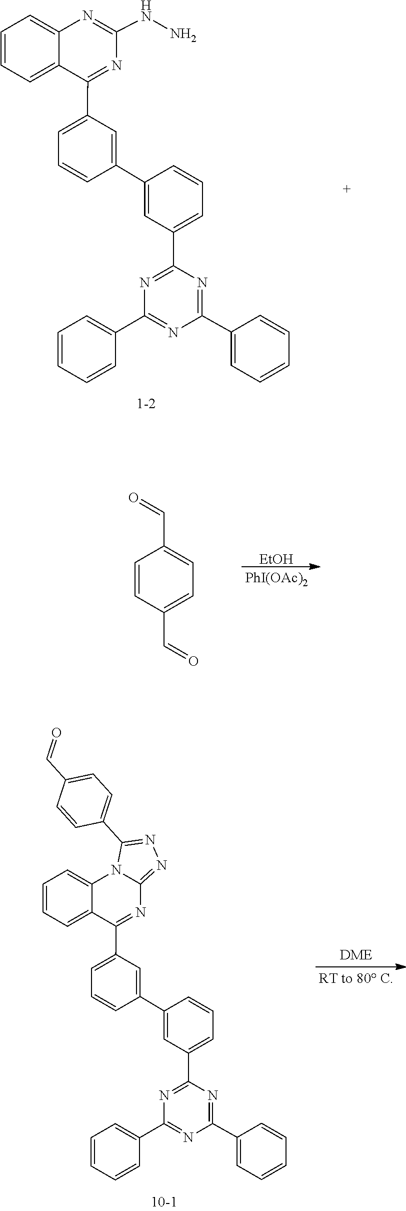 [SMILES: "EtOH" ; "PhI(OAc)2" ; NNc1nc(-c2cccc(-c3cccc(-c4nc(-c5ccccc5)nc(-c5ccccc5)n4)c3)c2)c2ccccc2n1 ; O=Cc1ccc(C=O)cc1 ; O=Cc1ccc(-c2nnc3nc(-c4cccc(-c5cccc(-c6nc(-c7ccccc7)nc(-c7ccccc7)n6)c5)c4)c4ccccc4n23)cc1]

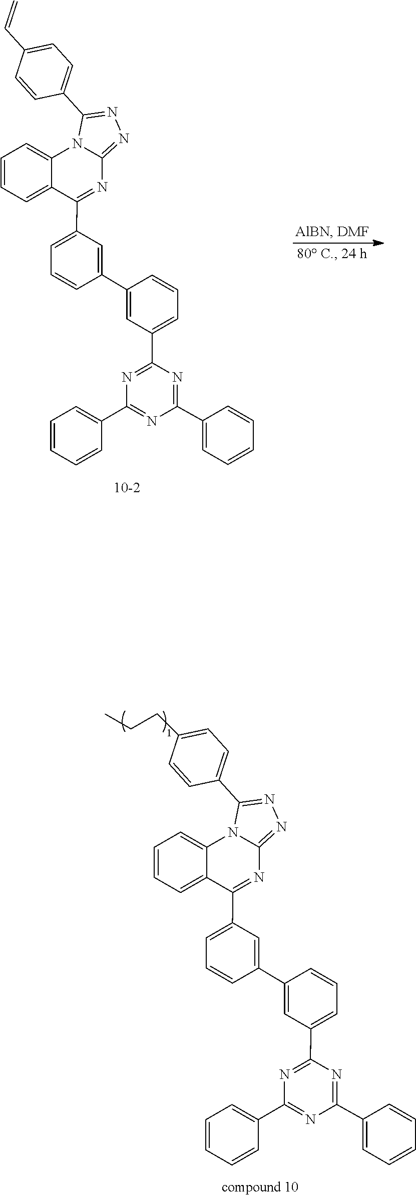

Compound 1-2 (7.6 g, 14 mmol) was added to a flask with 500 mL of ethanol inside, then 1,4-phthalaldehyde (1.88 g, 14 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 4.6 g (yield: about 50%) of compound 10-1 (pale yellow solid). MS(ASAP)=657.8.

To a solution of methyltriphenylphosphonium iodide (3.4 g, 8.4 mmol) in dry DME (20 mL), K₂CO₃ (1.45 g, 10.5 mmol) was added, and the stirring under argon was continued for 1 h. Then compound 10-1 (4.6 g, 7 mmol) was added and stirring was continued for overnight at 80° C. After cooling, 30 mL of diethyl ether was added to precipitate the insoluble salts. The mixture was collected by filtration, and the solvents were evaporated. The crude product was further recrystallized in DMF to obtain 4.4 g (yield: about 95%) of compound 10-2. MS(ASAP)=655.8.

Compound 10-2 (3.9 g, 6 mmol) and AIBN (9 mg, 0.06 mmol) was dissolved in dry DMF, and the resulting mixture was reacted at 80° C. under nitrogen atmosphere for 24 h. After the reaction, the mixture was added dropwise to ethanol to precipitate. After the filtration, the solid was filtrated, washed with ethanol for 3 times and further dried to yield 2.9 g (conversion: 74%) of compound 10. Mw=6.5×10⁴, PDI=2.1.

### Synthesis of Compound 11

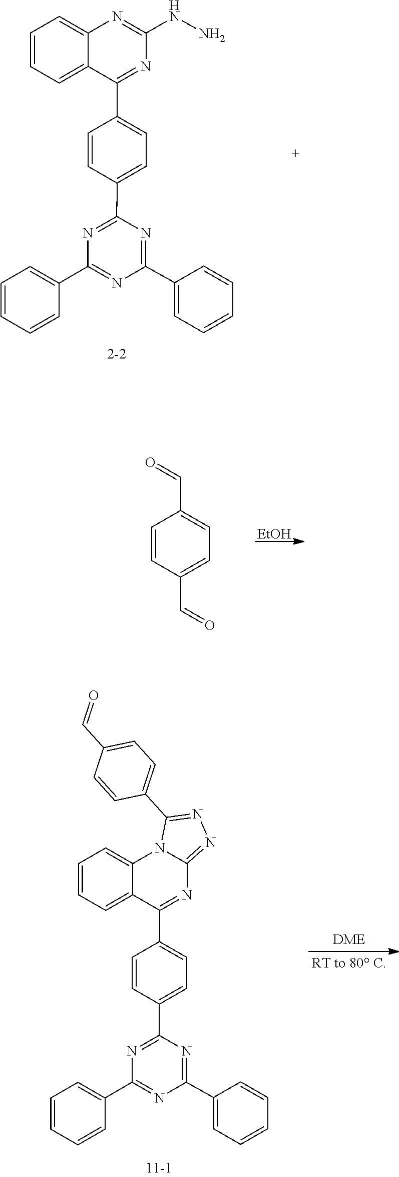 [SMILES: "EtOH" ; NNc1nc(-c2ccc(-c3nc(-c4ccccc4)nc(-c4ccccc4)n3)cc2)c2ccccc2n1 ; O=Cc1ccc(C=O)cc1 ; O=Cc1ccc(-c2nnc3nc(-c4ccc(-c5nc(-c6ccccc6)nc(-c6ccccc6)n5)cc4)c4ccccc4n23)cc1]

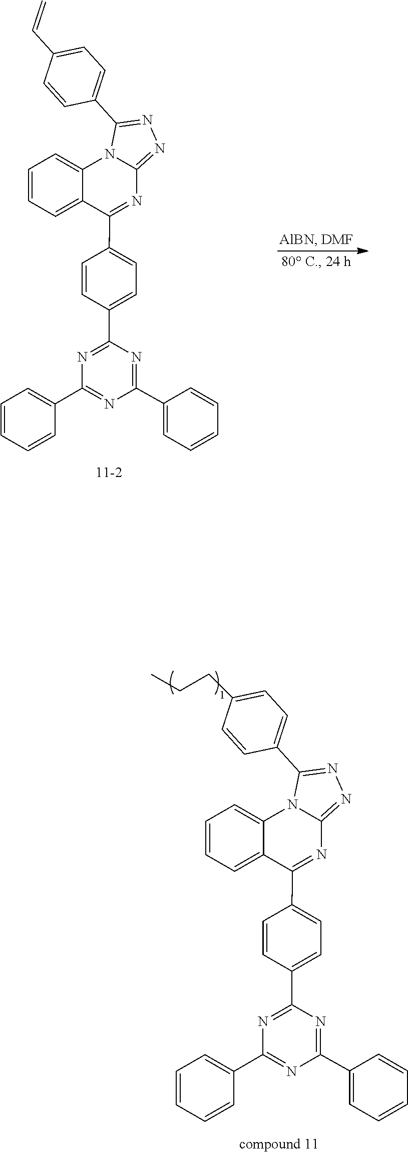

Compound 2-2 (6.5 g, 14 mmol) was added to a flask with 500 mL of ethanol inside, then 1,4-phthalaldehyde (1.88 g, 14 mmol) was added dropwise to the above mixture with stirring at room temperature. After 30 min, (diacetoxyiodo)benzene (4.9 g, 15.4 mmol) was added in batches, and the mixture was reacted for another 1.5 h. The precipitates formed during the reaction was filtrated, and washed with n-hexane. The dried crude product was further washed with a large amount of ethanol to yield about 4.2 g (yield: about 51%) of compound 11-1 (pale yellow solid). MS(ASAP)=581.6.

To a solution of methyltriphenylphosphonium iodide (3.4 g, 8.4 mmol) in dry DME (20 mL), K₂CO₃ (1.45 g, 10.5 mmol) was added, and the stirring under argon was continued for 1 h. Then compound 11-1 (4.1 g, 7 mmol) was added and stirring was continued for overnight at 80° C. After cooling, 30 mL of diethyl ether was added to precipitate the insoluble salts. The mixture was collected by filtration, and the solvents were evaporated. The crude product was further recrystallized in DMF to obtain 3.9 g (yield: about 95%) of compound 11-2. MS(ASAP)=579.7.

Compound 11-2 (3.5 g, 6 mmol) and AIBN (9 mg, 0.06 mmol) was dissolved in dry DMF, and the resulting mixture was reacted at 80° C. under nitrogen atmosphere for 24 h. After the reaction, the mixture was added dropwise to ethanol to precipitate. After the filtration, the solid was filtrated, washed with ethanol for 3 times and further dried to yield 2.8 g (conversion: 79%) of compound 11. Mw=6.1×10⁴, PDI=2.3.

### 2. Energy Structure of Organic Compounds

The energy level of the organic material can be calculated by quantum computation, for example, using TD-DFT (time-dependent density functional theory) by Gaussian 09W (Gaussian Inc.), the specific simulation methods of which can be found in WO2011141110. Firstly, the molecular geometry is optimized by semi-empirical method “Ground State/Semi-empirical/Default Spin/AM1” (Charge 0/Spin Singlet), then the energy structure of organic molecules is calculated by TD-DFT (time-dependent density functional theory) “TD-SCF/DFT/Default Spin/B3 PW91” and the basis set “6-31G (d)” (Charge 0/Spin Singlet). The HOMO and LUMO energy levels are calculated using the following calibration formula, where S1 and T1 are used directly.

$$HOMO ( eV ) = ( ( HOMO ( G ) \times 27.212 ) - 0.98 \; 99 ) / 1.1206$$

$$LUMO ( eV ) = ( ( LUMO ( G ) \times 27.212 ) - 2.00 \; 41 ) / 1.385$$

Where HOMO(G) and LUMO(G) are the direct calculation results of Gaussian 09W, in units of Hartree. The results are shown in Table 1 below:

TABLE 1

| | HOMO | LUMO | ΔHOMO | ΔLUMO | T1 | S1 |
|---|---|---|---|---|---|---|
| Materials | [eV] | [eV] | [eV] | [eV] | [eV] | [eV] |
| compound 1 | −6.30 | −2.92 | 0.35 | 0.03 | 2.44 | 3.41 |
| compound 2 | −6.32 | −3.09 | 0.62 | 0.18 | 2.35 | 3.26 |
| compound 3 | −6.36 | −2.96 | 0.61 | 0.70 | 2.42 | 3.39 |
| compound 4 | −6.14 | −2.90 | 0.40 | 0.01 | 2.44 | 3.31 |
| compound 5 | −6.38 | −3.06 | 0.56 | 0.11 | 2.51 | 3.37 |
| compound 6 | −6.69 | −3.25 | 0.51 | 0.53 | 2.44 | 3.39 |
| compound 7 | −6.62 | −3.07 | 0.15 | 0.15 | 2.54 | 3.48 |
| compound 8 | −6.19 | −2.90 | 0.45 | 0.03 | 2.41 | 3.28 |
| compound 9 | −6.40 | −3.13 | 0.35 | 0.04 | 2.39 | 3.30 |
| ET-A | −5.56 | −2.83 | 0.53 | 0.48 | 1.66 | 2.83 |
| ET-B | −6.25 | −2.95 | 0.72 | 0.02 | 2.63 | 3.47 |
| ET-C | −6.40 | −3.05 | 0.10 | 0.23 | 2.36 | 3.52 |
| ET-D | −6.32 | −3.03 | 0.36 | 0.11 | 2.63 | 3.44 |

### 3. Preparation and Characterization of OLEDs

The preparation process of the OLEDs will be described in detail with reference to specified examples below. The device structure is as follows: ITO(120 nm)/HI(30 nm)/HT-1(50 nm)/HT-2(10 nm)/BH:BD=100:3(25 nm)/ET:LiQ=50:50 (30 nm)/LiQ(1 nm)/Al(100 nm), where HI, HT, BH, BD, and ET are abbreviations for a hole-injection layer, a hole-transport layer, a blue host material, a blue dopant material, and an electron-transport layer, respectively. The following abbreviations have the same meaning as described herein.

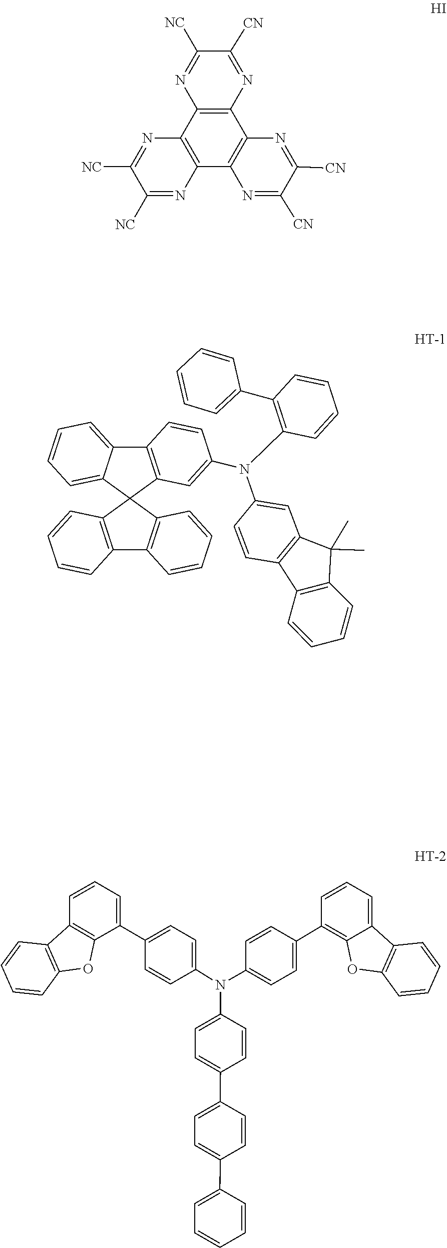 [SMILES: N#Cc1nc2c3nc(C#N)c(C#N)nc3c3nc(C#N)c(C#N)nc3c2nc1C#N ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

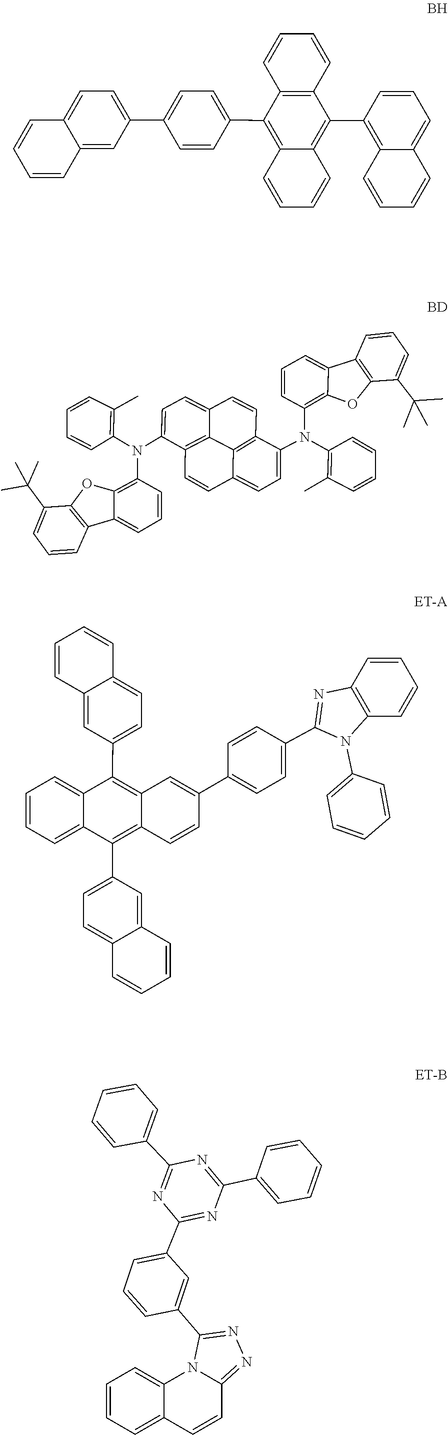

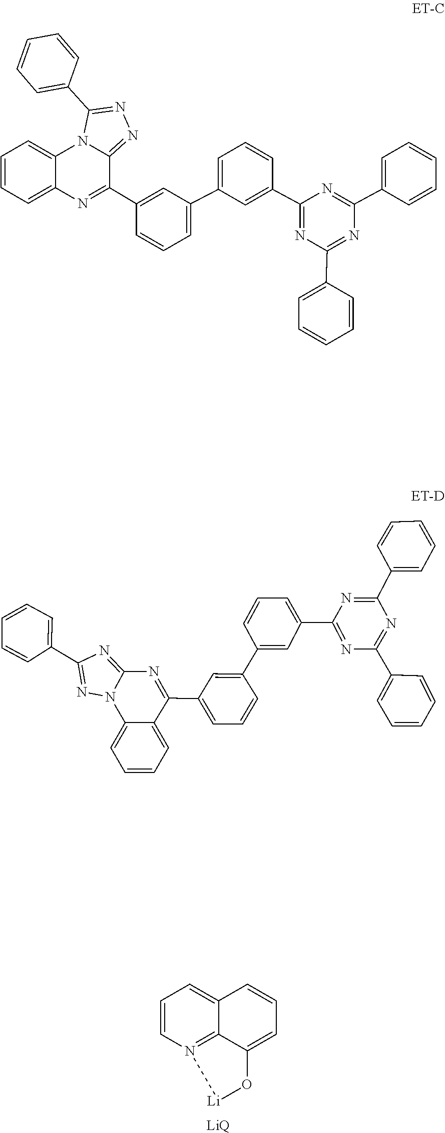

The above-mentioned organic electroluminescent materials are commonly used in this field, and those skilled in the art can perform self-preparation or commercial purchase based on well-known methods.
a. Cleaning of the ITO (Indium Tin Oxide) conductive glass substrate: the substrates are washed with various solvents (such as one or more of chloroform, ketone, or isopropyl alcohol), and then treated with UV and ozone.
b. Evaporation: the resultant ITO substrate was mounted on a vacuum deposition apparatus in high vacuum (1×10⁻⁶ mbar), and HI was then vacuum-deposited on the anode to form a hole-injection layer having a thickness of 30 nm, then two hole-transport layers, HT-1 (50 nm) and HT-2 (10 nm) were deposited on the HIL in vaccum deposition sequentially. Then BH and BD in two different evaportaion sources were deposited at a weight ratio of 100:3 to form a light-emitting layer having a thickness of 25 nm. Thereafter, the first electron-transport was evaporated, then compound ET and LiQ were placed in two evaporation units, and co-deposited at a weight ratio of 50:50 to form a second electron-transport layer having a thickness of 30 nm. LiQ was then deposited to form an electron-injection layer having a thickness of 1 nm, and Al was deposited on the electron-injection layer to form a cathode having a thickness of 100 nm.
c. Encapsulation: encapsulating the device in a nitrogen-regulated glove box with UV curable resin.

Device Example 2-Device Example 9, Comparative Example 1-Comparative Example 4 differ from Device Example 1 only by replacing compound 1 with other compounds. As shown in Table 2, the device performance of the device examples and the comparative examples was tested; where the driving voltage and the current efficiency were measured at a current density of 10 mA/cm²; T95 refers to the relative value of the time at which the luminance of the device examples decreases to 95% of the initial luminance at a constant current density of 20 mA/cm² compared with that of Comparative Example 1.

TABLE 2

| | Electron-Transport | Driving Voltage | Current Efficiency | |
|---|---|---|---|---|
| | Materials (ETM) | (V) | (cd/A) | T95 |
| Device Example 1 | compound 1 | 4.23 | 7.5 | 164% |
| Device Example 2 | compound 2 | 4.25 | 7.4 | 159% |
| Device Example 3 | compound 3 | 4.27 | 7.6 | 146% |
| Device Example 4 | compound 4 | 4.24 | 7.2 | 151% |
| Device Example 5 | compound 5 | 4.31 | 7.0 | 138% |
| Device Example 6 | compound 6 | 4.26 | 7.3 | 160% |
| Device Example 7 | compound 7 | 4.25 | 7.5 | 154% |
| Device Example 8 | compound 8 | 4.28 | 7.1 | 170% |
| Device Example 9 | compound 9 | 4.24 | 7.6 | 130% |
| Comparative | ET-A | 4.38 | 7.0 | 100% |
| Example 1 | | | | |
| Comparative | ET-B | 4.35 | 6.9 | 84% |
| Example 2 | | | | |
| Comparative | ET-C | 4.30 | 6.9 | 120% |
| Example 3 | | | | |
| Comparative | ET-D | 4.29 | 7.0 | 114% |
| Example 4 | | | | |

The current efficiency and lifetime of Device Example 1-Device Example 9 are obviously increased compared with those of Comparative Example 1-Comparative Example 4, illustrating that applying the compounds (contained in the organic electroluminescent device as described herein) to the OLED devices as electron-transport materials can improve the current efficiency and lifetime of the devices, as well as reducing the driving voltage of the devices.

What described above are several embodiments of the present disclosure, and they are specific and in detail, but not intended to limit the scope of the present disclosure. It will be understood that improvements can be made without departing from the concept of the present disclosure, and all these modifications and improvements are within the scope of the present disclosure. The scope of the present disclosure shall be subject to the appended claims.

What is claimed is:

1. An organic electroluminescent device, comprising a substrate, a first electrode, a second electrode, and at least one functional layer, wherein the at least one functional layer comprises a compound of formula (I): 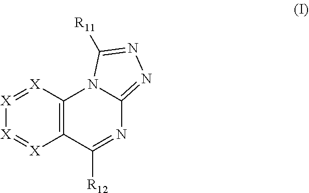
wherein:
each of R₁₁ and R₁₂ is a substituent and independently selected from −D, a substituted/unsubstituted C₁-C₂₀ linear alkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a substituted/unsubstituted C₁-C₂₀ ketone group, a substituted/unsubstituted C₂-C₂₀ alkoxycarbonyl group, a substituted/unsubstituted C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted C₅-C₆₀ aromatic or heteroaromatic group, a substituted/unsubstituted C₅-C₆₀ aryloxy or heteroaryloxy group, or any combination thereof, wherein one or more R₁₁-R₁₂ form a monocyclic or polycyclic aliphatic or aromatic ring system with each other and/or with the rings bonded thereto;
X at each occurrence is independently N or CR₁;
R₁ at each occurrence is independently selected from −H, −D, a halogen group, a substituted/unsubstituted C₁-C₂₀ linear alkyl group, a substituted/unsubstituted C₃-C₂₀ cycloalkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a C₁-C₂₀ ketone group, a C₂-C₂₀ alkoxycarbonyl group, a C₇-C₂₀ aryloxycarbonyl group, a carbamoyl group, a haloformyl group, a formyl group, an isocyano group, an isocyanate group, a thiocyanate group, an isothiocyanate group, a hydroxyl group, a cross-linkable group, a substituted/unsubstituted C₆-C₆₀ aryl group, a substituted/unsubstituted C₅-C₆₀ heteroaryl group, a substituted/unsubstituted C₅-C₆₀ aryloxy group, a substituted/unsubstituted C₅-C₆₀ heteroaryloxy group, a substituted/unsubstituted C₆-C₃₀ arylamino group, a substituted/unsubstituted C₅-C₃₀ heteroarylamino group, or any combination thereof.

2. The organic electroluminescent device according to claim 1, wherein R₁, R₁₁, and R₁₂ are each independently selected from a substituted/unsubstituted C₆-C₆₀ aryl group or a substituted/unsubstituted C₅-C₆₀ heteroaryl group.

3. The organic electroluminescent device according to claim 1, wherein R₁₁ and R₁₂ respectively correspond to the groups represented by formula (I-1) and formula (I-2): 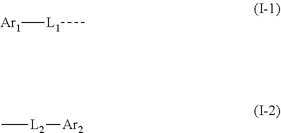
wherein:
L₁ and L₂ are each independently selected from any one of a single bond, a substituted/unsubstituted C₆-C₃₀ arylene group, or a substituted/unsubstituted C₅-C₃₀ heteroarylene group;
Ar₁ and Ar₂ are each independently selected from a substituted/unsubstituted C₆-C₃₀ aryl group or a substituted/unsubstituted C₅-C₃₀ heteroaryl group, and at least one of Ar₁ or Ar₂ is an electron-withdrawing group or is substituted with an electron-withdrawing group;
each dotted line independently represents a bonding position of a group.

4. The organic electroluminescent device according to claim 2, wherein R₁₁ and R₁₂ respectively correspond to the groups represented by formula (I-1) and formula (I-2): 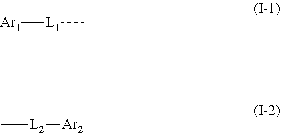
wherein:
L₁ and L₂ are each independently selected from any one of a single bond, a substituted/unsubstituted C₆-C₃₀ arylene group, or a substituted/unsubstituted C₅-C₃₀ heteroarylene group;
Ar₁ and Ar₂ are each independently selected from a substituted/unsubstituted C₆-C₃₀ aryl group or a substituted/unsubstituted C₅-C₃₀ heteroaryl group, and at least one of Ar₁ or Ar₂ is an electron-withdrawing group or is substituted with an electron-withdrawing group;
each dotted line independently represents a bonding position of a group.

5. The organic electroluminescent device according to claim 3, wherein the electron-withdrawing group is selected from F, a cyano group, or one of the following groups: 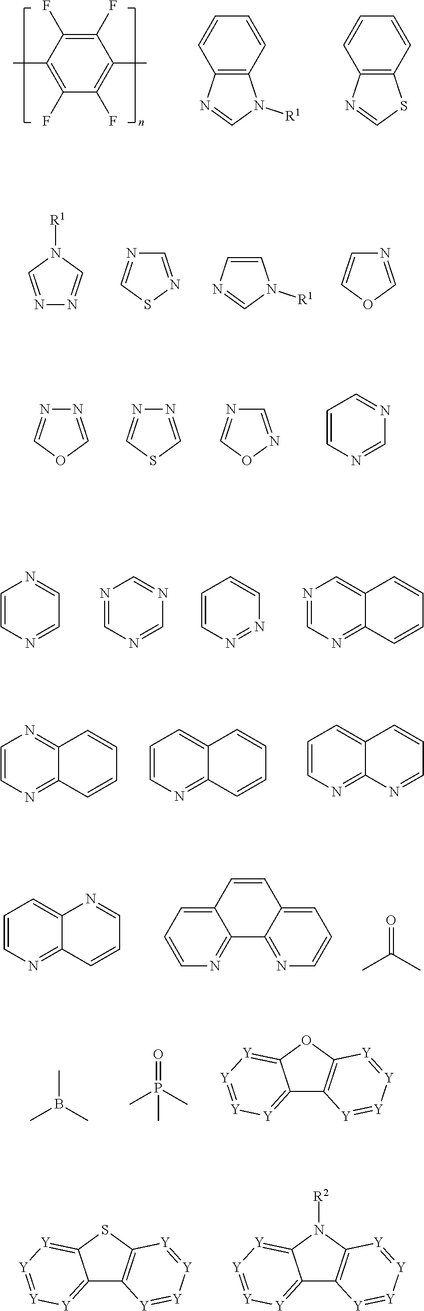 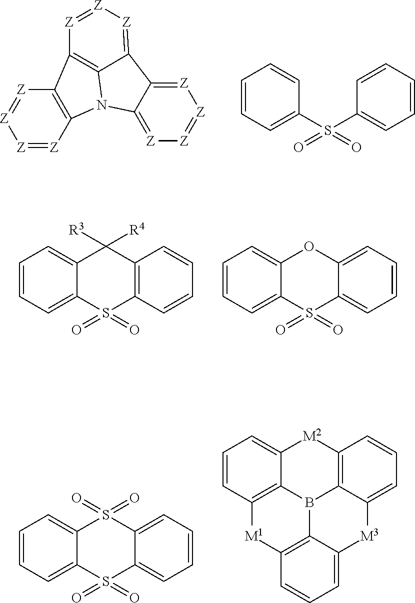
wherein:
n is an integer from 1 to 3;
Y at each occurrence is independently CR⁵ or N, and at least one of them is N;
Z at each occurrence is independently CR⁶ or N, and any two adjacent positions form a monocyclic or polycyclic aliphatic or aromatic ring system;
M¹, M², and M³ are each independently selected from NR⁷, CR⁸R⁹, SiR⁹R¹⁰, O, PR¹¹, P(═O)R¹², S, S═O, SO₂, or null;
each of R¹ to R¹² at each occurrence is independently selected from −H, −D, a halogen group, a substituted/unsubstituted C₁-C₂₀ linear alkyl group, a substituted/unsubstituted C₃-C₂₀ cycloalkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a C₁-C₂₀ ketone group, a C₂-C₂₀ alkoxycarbonyl group, a C₇-C₂₀ aryloxycarbonyl group, a carbamoyl group, a haloformyl group, a formyl group, an isocyano group, an isocyanate group, a thiocyanate group, an isothiocyanate group, a hydroxyl group, a cross-linkable group, a substituted/unsubstituted C₆-C₆₀ aryl group, a substituted/unsubstituted C₅-C₆₀ heteroaryl group, a substituted/unsubstituted C₅-C₆₀ aryloxy group, a substituted/unsubstituted C₅-C₆₀ heteroaryloxy group, a substituted/unsubstituted C₆-C₃₀ arylamino group, a substituted/unsubstituted C₅-C₃₀ heteroarylamino group, or any combination thereof.

6. The organic electroluminescent device according to claim 4, wherein the electron-withdrawing group is selected from F, a cyano group, or one of the following groups: 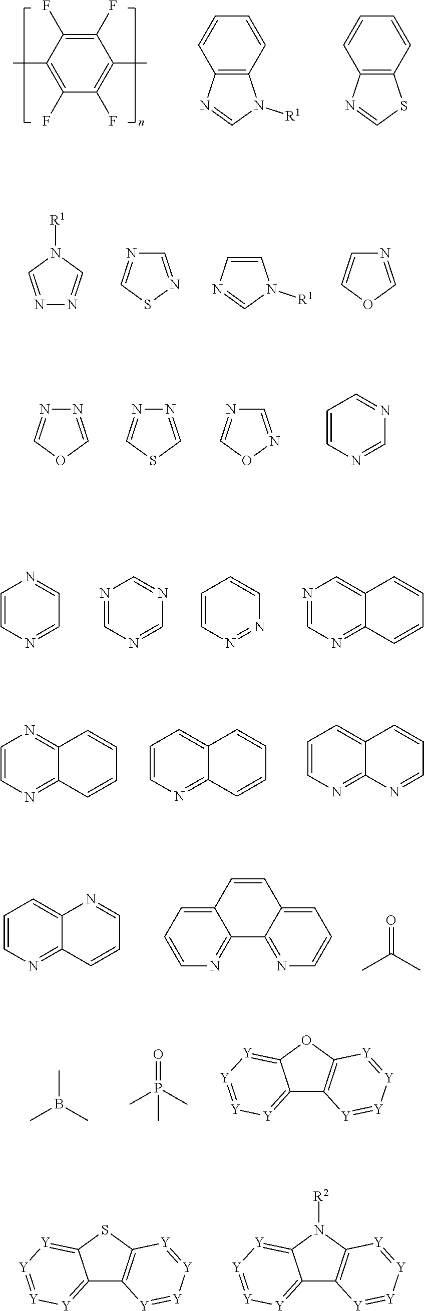 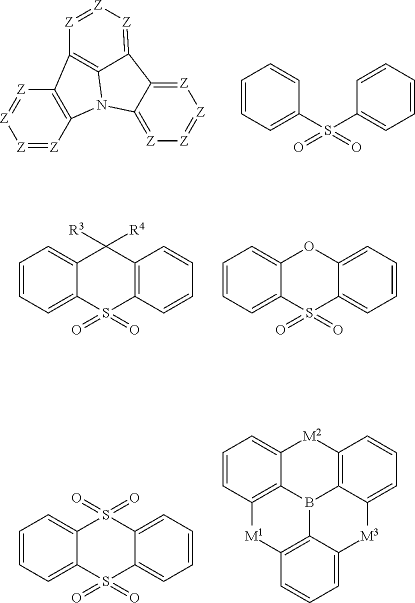
wherein:
n is an integer from 1 to 3;
Y at each occurrence is independently CR⁵ or N, and at least one of them is N;
Z at each occurrence is independently CR⁶ or N, and any two adjacent positions form a monocyclic or polycyclic aliphatic or aromatic ring system;
M¹, M², and M³ are each independently selected from NR⁷, CR⁸R⁹, SiR⁹R¹⁰, O, PR¹¹, P(═O)R¹², S, S═O, SO₂, or null;
each of R¹ to R¹² at each occurrence is independently selected from −H, −D, a halogen group, a substituted/unsubstituted C₁-C₂₀ linear alkyl group, a substituted/unsubstituted C₃-C₂₀ cycloalkyl group, a substituted/unsubstituted C₁-C₂₀ linear alkoxy group, a substituted/unsubstituted C₁-C₂₀ linear thioalkoxy group, a substituted/unsubstituted C₃-C₂₀ branched/cyclic alkyl group, a substituted/unsubstituted C₃-C₂₀ branched/cyclic alkoxy group, a substituted/unsubstituted C₃-C₂₀ branched/cyclic thioalkoxy group, a substituted/unsubstituted C₃-C₂₀ branched/cyclic silyl group, a C₁-C₂₀ ketone group, a C₂-C₂₀ alkoxycarbonyl group, a C₇-C₂₀ aryloxycarbonyl group, a carbamoyl group, a haloformyl group, a formyl group, an isocyano group, an isocyanate group, a thiocyanate group, an isothiocyanate group, a hydroxyl group, a cross-linkable group, a substituted/unsubstituted C₆-C₆₀ aryl group, a substituted/unsubstituted C₅-C₆₀ heteroaryl group, a substituted/unsubstituted C₅-C₆₀ aryloxy group, a substituted/unsubstituted C₅-C₆₀ heteroaryloxy group, a substituted/unsubstituted C₆-C₃₀ arylamino group, a substituted/unsubstituted C₅-C₃₀ heteroarylamino group, or any combination thereof.

7. The organic electroluminescent device according to claim 1, wherein the at least one functional layer is selected from an electron-transport layer, a hole-blocking layer, a light-emitting layer, or a charge generation layer.

8. The organic electroluminescent device according to claim 2, wherein the at least one functional layer is selected from an electron-transport layer, a hole-blocking layer, a light-emitting layer, or a charge generation layer.

9. The organic electroluminescent device according to claim 3, wherein the at least one functional layer is selected from an electron-transport layer, a hole-blocking layer, a light-emitting layer, or a charge generation layer.

10. The organic electroluminescent device according to claim 4, wherein the at least one functional layer is selected from an electron-transport layer, a hole-blocking layer, a light-emitting layer, or a charge generation layer.

11. The organic electroluminescent device according to claim 5, wherein the at least one functional layer is selected from an electron-transport layer, a hole-blocking layer, a light-emitting layer, or a charge generation layer.

12. The organic electroluminescent device according to claim 6, wherein the at least one functional layer is selected from an electron-transport layer, a hole-blocking layer, a light-emitting layer, or a charge generation layer.

13. The organic electroluminescent device according to claim 1, wherein the organic electroluminescent device is selected from an organic light-emitting diode, an organic light emitting electrochemical cell, or an organic light emitting field effect transistor.

14. A mixture, comprising the compound of formula (I), and at least one other organic functional material, wherein the at least one other organic functional material is selected from one or more of the following: a hole-injection material, a hole-transport material, an electron-transport material, an electron-injection material, an electron-blocking material, a hole-blocking material, a light-emitting material, a host material, an organic dye.

15. An organic compound, comprising a structure of formula (I), wherein R₁₁ and R₁₂ are each independently selected from a substituted/unsubstituted C₆-C₆₀ aryl group or a substituted/unsubstituted C₅-C₆₀ heteroaryl group, and at least one of R₁₁ or R₁₂ comprises an electron-withdrawing group.
